(19) United States
(12) Patent Application Publication
(10) Pub. No.: US 2024/0282793 A1
(43) Pub. Date: Aug. 22, 2024

(54) SOLID-STATE IMAGING DEVICE AND ELECTRONIC APPARATUS

(71) Applicant: SONY SEMICONDUCTOR SOLUTIONS CORPORATION, KANAGAWA (JP)

(72) Inventors: MIZUKI HOYANO, KANAGAWA (JP); HIROMASA SAITO, KANAGAWA (JP); SEIKI TAKAHASHI, KANAGAWA (JP); TAKASHI KOJIMA, KANAGAWA (JP)

(21) Appl. No.: 18/570,665

(22) PCT Filed: Jun. 15, 2022
(86) PCT No.: PCT/JP2022/023909

§ 371 Date: Dec. 15, 2023

(30) Foreign Application Priority Data
Jun. 23, 2021 (JP) 2021-103741
Feb. 16, 2022 (WO) PCT/JP2022/006058

(51) Int. Cl. H01L 27/146; H04N 23/84; H04N 25/11; H04N 25/705

(52) U.S. Cl. CPC H01L 27/14621; H01L 27/1463; H01L 27/14645; H04N 23/84; H04N 25/11; H04N 25/705

(57) ABSTRACT

The present technology relates to a solid-state imaging device and an electronic apparatus each capable of improving characteristics without causing processing damage. The solid-state imaging device includes a pixel array unit that includes a plurality of pixels. The pixel array unit includes a color filter layer that includes color filters, a photoelectric conversion layer that includes photoelectric conversion units, an oxide film layer formed between the color filter layer and the photoelectric conversion layer, and a low refractive index wall that includes a material having a lower refractive index than that of the color filters and that is formed between pixels from an end of the color filter layer on the side opposite to the oxide film layer to an intermediate position in the oxide film layer. The present technology is applicable to a CMOS image sensor.

### TECHNICAL FIELD

The present technology relates to a solid-state imaging device and an electronic apparatus, and particularly to a solid-state imaging device and an electronic apparatus each capable of improving characteristics without causing processing damage.

### BACKGROUND ART

A conventionally known image sensor has a color filter layer including color filters that is provided between on-chip lenses and a semiconductor substrate including photoelectric conversion units.

A technology proposed for that type of image sensor forms a low refractive index wall that penetrates the color filter layer and that comes into contact with a trench provided in the semiconductor substrate, so as to reduce color mixture between pixels and lowering of pixel sensitivity for improvement of sensor characteristics (for example, see PTL 1).

### CITATION LIST

### Patent Literature

### [PTL 1]

US Patent Application Publication No. 2020/0083268

### SUMMARY

### Technical Problems

Meanwhile, it is known that an incident angle of light entering a pixel increases at a position away from a center position of a light receiving surface of the image sensor, i.e., a position near an image height end, and that this increase in the incident angle reduces an amount of light entering the pixel and lowers pixel sensitivity. In other words, deterioration of sensor characteristics occurs. Accordingly, for correction reducing this lowering of pixel sensitivity, it is adopted in some cases to execute pupil correction which shifts each position of the on-chip lenses and the color filter layer with respect to the semiconductor substrate by a width corresponding to the image height.

According to the technology described above, however, execution of pupil correction may cause the low refractive index wall to come into contact with a region of the photoelectric conversion units of the semiconductor substrate at the position near the image height end during processing of the low refractive index wall, and may cause processing damage to the photoelectric conversion units. Such processing damage becomes a factor causing deterioration of sensor characteristics, such as an increase in dark current.

The present technology has been developed in consideration of the abovementioned circumstances, and achieves characteristic improvement without causing processing damage.

### Solution to Problems

A solid-state imaging device according to one aspect of the present technology includes a pixel array unit that includes a plurality of pixels. The pixel array unit includes a color filter layer that includes color filters, a photoelectric conversion layer that includes photoelectric conversion units, an oxide film layer formed between the color filter layer and the photoelectric conversion layer, and a low refractive index wall that includes a material having a lower refractive index than that of the color filters and that is formed between pixels from an end of the color filter layer on the side opposite to the oxide film layer to an intermediate position in the oxide film layer.

According to the one aspect of the present technology, the solid-state imaging device includes a pixel array unit that includes a plurality of pixels. The pixel array unit includes a color filter layer that includes color filters, a photoelectric conversion layer that includes photoelectric conversion units; an oxide film layer formed between the color filter layer and the photoelectric conversion layer, and a low refractive index wall that includes a material having a lower refractive index than that of the color filters and that is formed between pixels from an end of the color filter layer on the side opposite to the oxide film layer to an intermediate position in the oxide film layer.

### BRIEF DESCRIPTION OF DRAWINGS

FIG. 1 is a diagram depicting a configuration example of a CMOS image sensor.

FIG. 2 is a diagram explaining processing damage and formation of color mixture paths.

FIG. 3 is a diagram explaining processing damage and formation of color mixture paths.

FIG. 4 is a diagram explaining an image height center and a position near an image height end of a pixel array unit.

FIG. 5 is a diagram depicting a configuration example of the pixel array unit at the image height center.

FIG. 6 is a diagram depicting a configuration example of the pixel array unit on the image height end side.

FIG. 7 is a diagram explaining an image height and pupil correction.

FIG. 8 is a diagram explaining a method for manufacturing the pixel array unit.

FIG. 9 is a diagram explaining the method for manufacturing the pixel array unit.

FIG. 10 is a diagram depicting a configuration example of the pixel array unit.

FIG. 11 is a diagram depicting a configuration example of the pixel array unit.

FIG. 12 is a diagram depicting a configuration example of the pixel array unit.

FIG. 13 is a diagram depicting a configuration example of the pixel array unit.

FIG. 14 is a diagram depicting a configuration example of the pixel array unit.

FIG. 15 is a diagram depicting a configuration example of the pixel array unit.

FIG. 16 is a diagram depicting a configuration example of the pixel array unit.

FIG. 17 is a diagram depicting a configuration example of the pixel array unit.

FIG. 18 is a diagram depicting a configuration example of the pixel array unit.

FIG. 19 is a diagram depicting a configuration example of the pixel array unit.

FIG. 20 is a diagram depicting a configuration example of the pixel array unit.

FIG. 21 is a diagram depicting a configuration example of the pixel array unit.

FIG. 22 is a diagram depicting a configuration example of a ZAF pixel portion of the pixel array unit.

FIG. 23 is a diagram depicting a configuration example of the ZAF pixel portion of the pixel array unit.

FIG. 24 is a diagram depicting a configuration example of the ZAF pixel portion of the pixel array unit.

FIG. 25 is a diagram depicting a configuration example of the ZAF pixel portion of the pixel array unit.

FIG. 26 is a diagram depicting a combination example of an image height and a color filter.

FIG. 27 is a diagram depicting a combination example of an image height and a color filter.

FIG. 28 is a diagram depicting a combination example of an image height and a color filter.

FIG. 29 is a diagram depicting a selection example of the color filters corresponding to sensitivity of ZAF pixels.

FIG. 30 is a diagram depicting a selection example of the color filters corresponding to sensitivity of ZAF pixels.

FIG. 31 is a diagram depicting a selection example of the color filters corresponding to sensitivity of ZAF pixels.

FIG. 32 is a diagram depicting a variation example of a width of a low refractive index wall near the ZAF pixels.

FIG. 33 is a diagram depicting a variation example of the width of the low refractive index wall near the ZAF pixels.

FIG. 34 is a diagram depicting a variation example of the width of the low refractive index wall near the ZAF pixels.

FIG. 35 is a diagram depicting a configuration example of the pixel array unit.

FIG. 36 is a diagram depicting a configuration example of the pixel array unit.

FIG. 37 is a diagram depicting a configuration example of the pixel array unit.

FIG. 38 is a diagram depicting a configuration example of the pixel array unit.

FIG. 39 is a diagram depicting a configuration example of the pixel array unit.

FIG. 40 is a diagram depicting a configuration example of the pixel array unit.

FIG. 41 is a diagram depicting a configuration example of the pixel array unit.

FIG. 42 is a diagram depicting examples of forming on-chip lenses for pixels.

FIG. 43 is a diagram depicting a configuration example of the pixel array unit.

FIG. 44 is a diagram depicting a configuration example of the pixel array unit.

FIG. 45 is a diagram depicting a configuration example of the pixel array unit.

FIG. 46 is a diagram depicting a configuration example of the pixel array unit.

FIG. 47 is a diagram depicting a configuration example of the pixel array unit.

FIG. 48 is a diagram explaining reflection of entering light.

FIG. 49 is a diagram depicting a configuration example of the pixel array unit.

FIG. 50 is a diagram depicting a configuration example of the pixel array unit.

FIG. 51 is a diagram explaining pupil correction and the width of the low refractive index wall.

FIG. 52 is a diagram explaining pupil correction and the width of the low refractive index wall.

FIG. 53 is a diagram depicting a configuration example of an imaging device.

FIG. 54 is a diagram explaining use examples of the CMOS image sensor.

FIG. 55 is a block diagram depicting an example of schematic configuration of a vehicle control system.

FIG. 56 is a diagram of assistance in explaining an example of installation positions of an outside-vehicle information detecting section and an imaging section.

### DESCRIPTION OF EMBODIMENTS

Embodiments to which the present technology is applied will hereinafter be described with reference to the drawings.

### First Embodiment

### Configuration Example of CMOS Image Sensor

The present technology forms a low refractive index wall that penetrates a color filter layer and that is embedded up to an intermediate position in an oxide film layer formed between the color filter layer and a photoelectric conversion layer of a semiconductor substrate, to improve sensor characteristics without causing processing damage. The present technology prevents direct contact between the low refractive index wall and photoelectric conversion units included in the semiconductor substrate even in a case of execution of pupil correction, thereby achieving reduction of processing damage.

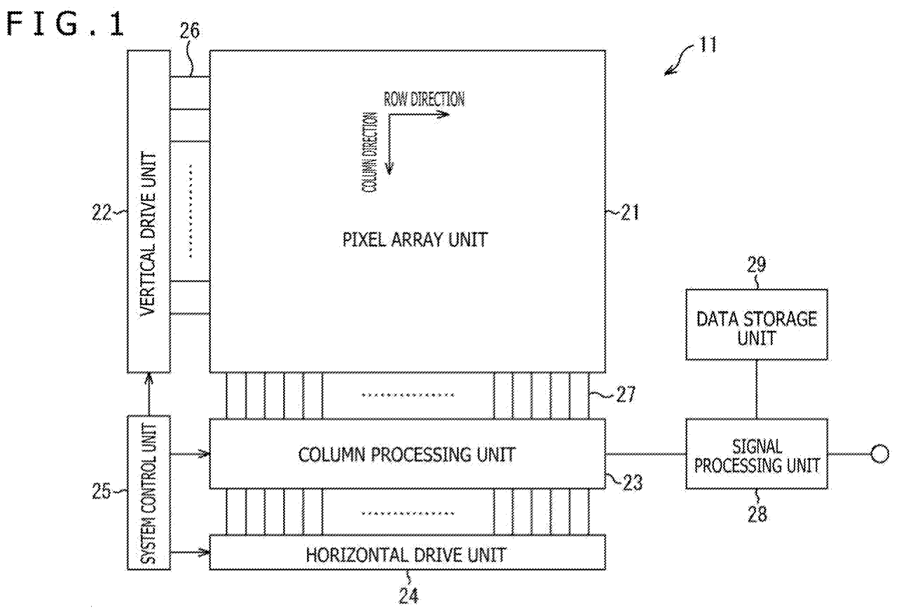

FIG. 1 is a diagram depicting a configuration example of a CMOS (Complementary Metal Oxide Semiconductor) image sensor which is a solid-state imaging device to which the present technology is applied.

For example, a CMOS image sensor 11 is a back-illuminated solid-state imaging device (solid-state imaging element), and includes a pixel array unit 21 provided on an unillustrated semiconductor substrate (chip) and a peripheral circuit unit integrated on the semiconductor substrate where the pixel array unit 21 is provided.

For example, the peripheral circuit unit has a vertical drive unit 22, a column processing unit 23, a horizontal drive unit 24, and a system control unit 25.

The CMOS image sensor 11 further has a signal processing unit 28 and a data storage unit 29. The signal processing unit 28 and the data storage unit 29 may be provided on the semiconductor substrate constituting the CMOS image sensor 11, or may be provided on a substrate different from the semiconductor substrate constituting the CMOS image sensor 11.

The pixel array unit 21 includes a plurality of unit pixels (hereinafter also simply referred to as pixels in some cases) that each have a photoelectric conversion unit for generating and accumulating charge corresponding to an amount of received light and are arranged in a row direction and a column direction, i.e., two-dimensionally arranged in a matrix shape.

Here, the row direction corresponds to a pixel arrangement direction of pixel rows (horizontal direction), i.e., a horizontal direction in the figure, while the column direction corresponds to a pixel arrangement direction of pixel columns (vertical direction), i.e., a vertical direction in the figure.

In the pixel array unit 21, a pixel drive line 26 is wired in the row direction for each of the pixel rows, and a vertical signal line 27 is wired in the column direction for each of the pixel columns in the pixel arrangement having the matrix form. The pixel drive line 26 is a signal line through which drive signals (control signals) for driving the pixels, such as driving signals at the time of readout of signals from the pixels, are supplied. One end of each of the pixel drive lines 26 is connected to an output end of a corresponding row of the vertical drive unit 22.

While one pixel drive line 26 is provided for one pixel row here for easy visual recognition of the figure, a plurality of pixel drive lines 26 are wired for one pixel row in an actual situation.

The vertical drive unit 22 includes a shift register, an address decoder, and the like, for example, and drives the pixels of the pixel array unit 21 all simultaneously, or for each row or the like.

For example, the vertical drive unit 22 has a configuration which includes two scanning systems, i.e., a read scanning system and a sweep scanning system.

The read scanning system sequentially selects and scans the unit pixels of the pixel array unit 21 for each row to read signals from the unit pixels.

The sweep scanning system performs sweep scanning at a predetermined timing for a reading row which is a target of read scanning by the read scanning system. The photoelectric conversion units of the unit pixels of the reading row are reset by unnecessary charge being swept from the photoelectric conversion units by the sweep scanning achieved by the sweep scanning system.

Signals output from the respective unit pixels of the pixel row selectively scanned by the vertical drive unit 22 are input to the column processing unit 23 via the vertical signal lines 27 for each of the pixel columns.

The column processing unit 23 performs predetermined signal processing for signals supplied from the respective pixels of the selected row via the vertical signal lines 27 for each of the pixel rows of the pixel array unit 21, and temporarily retains the processed pixel signals.

For example, the column processing unit 23 performs signal processing such as noise removal processing, CDS (Correlated Double Sampling) processing, and AD (Analog to Digital) conversion processing. For example, CDS processing removes reset noise and fixed pattern noise unique to the pixels, such as threshold variations of amplification transistors in the pixels.

The horizontal drive unit 24 includes a shift register, an address decoder, and the like, and sequentially selects unit circuits corresponding to the pixel columns of column processing unit 23. Pixel signals processed by the column processing unit 23 for each of the unit circuits are sequentially output to the signal processing unit 28 by the selective scanning performed by the horizontal drive unit 24.

The system control unit 25 includes a timing generator for generating various types of timing signals, for example, and performs drive control of the vertical drive unit 22, the column processing unit 23, the horizontal drive unit 24, and other units in reference to the generated timing signals.

The signal processing unit 28 has at least an arithmetic processing function, and performs various types of signal processing, such as arithmetic processing, for pixel signals output from the column processing unit 23. The data storage unit 29 temporarily stores data necessary for signal processing performed by the signal processing unit 28 at the time of this processing.

### Configuration Example of Pixel Array Unit

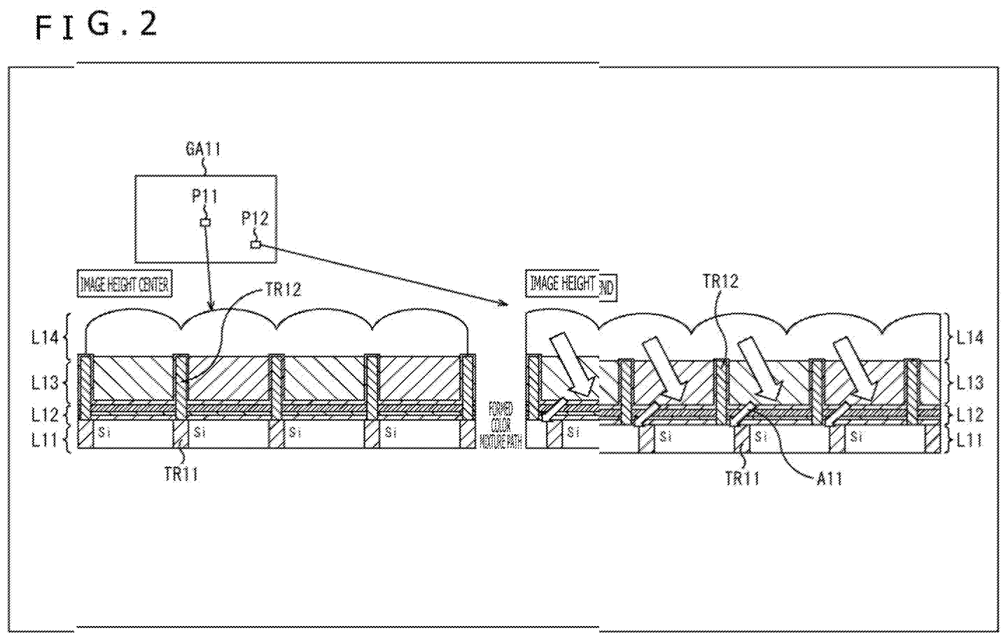

Meanwhile, a configuration depicted in FIG. 2 may be applicable to a pixel array unit that is included in an image sensor and that has a plurality of pixels.

Depicted in an upper part of FIG. 2 is a diagram of a pixel array unit GA11 viewed in a direction perpendicular to a surface of the pixel array unit GA11, while depicted in a lower part of FIG. 2 is a diagram of the pixel array unit GA11 viewed in a direction parallel to the surface of the pixel array unit GA11, i.e., a cross section of the pixel array unit GA11.

In addition, the pixel array unit GA11 has a photoelectric conversion layer L11 including a semiconductor substrate and having photoelectric conversion units formed therein, an oxide film layer L12 including an oxide film, a color filter layer L13 including color filters, and a micro-lens layer L14 including on-chip lenses.

In this example, for reducing color mixture and the like, a trench TR11 is formed in the photoelectric conversion layer L11, and a low refractive index wall TR12 is formed in the color filter layer L13 and the oxide film layer L12 as a wall penetrating the color filter layer L13 and the oxide film layer L12.

Moreover, pupil correction is performed for improvement of sensor characteristics in this example.

As illustrated in a lower left part of the figure, centers of the on-chip lens, the color filter, and the photoelectric conversion unit are aligned with each other at a center position of the pixel array unit GA11, i.e., at a position P11 of an image height center. Accordingly, the low refractive index wall TR12 is positioned immediately above the trench TR11, and comes into contact with the trench TR11.

On the other hand, as illustrated in a lower right part of the figure, the on-chip lens and the color filter are arranged such that centers of the on-chip lens and the color filter are shifted from the center of the photoelectric conversion unit at a position away from the center position of the pixel array unit GA11, i.e., at a position P12 near an image height end.

Particularly at the position P12, light coming from an unillustrated imaging lens disposed before the pixel array unit GA11 diagonally travels toward the lower right in the figure, and enters each of the photoelectric conversion units from the on-chip lens via the color filter. Accordingly, each of the on-chip lenses and the color filters is disposed at a position shifted to the left with respect to the photoelectric conversion unit in the figure.

As a result, the low refractive index wall TR12 is positioned not immediately above the trench TR11 but immediately above the photoelectric conversion units, and comes into contact with the photoelectric conversion units.

Such pupil correction allows a larger amount of light to enter also the photoelectric conversion unit of each of the pixels located on the image height end side, and thus achieves improvement of image sensitivity.

However, according to the pixel array unit GA11, the low refractive index wall TR12 penetrates the color filter layer L13 and the oxide film layer L12, and reaches the position of the trench TR11, i.e., an end of the photoelectric conversion layer L11. Accordingly, the low refractive index wall TR12 comes into contact with the photoelectric conversion units at a position near the image height end, and hence may cause processing damage to the photoelectric conversion units during processing (formation) of the low refractive index wall TR12. Such processing damage becomes a factor causing deterioration of sensor characteristics.

Moreover, pupil correction produces clearances between the low refractive index wall TR12 and the trench TR11 at the position near the image height end. Accordingly, as indicated by arrows A11, for example, each light entering predetermined pixels comes into the photoelectric conversion unit of the adjacent pixel through the clearance between the low refractive index wall TR12 and the trench TR11, and causes color mixture. In other words, pupil correction forms color mixture paths, and deteriorates sensor characteristics.

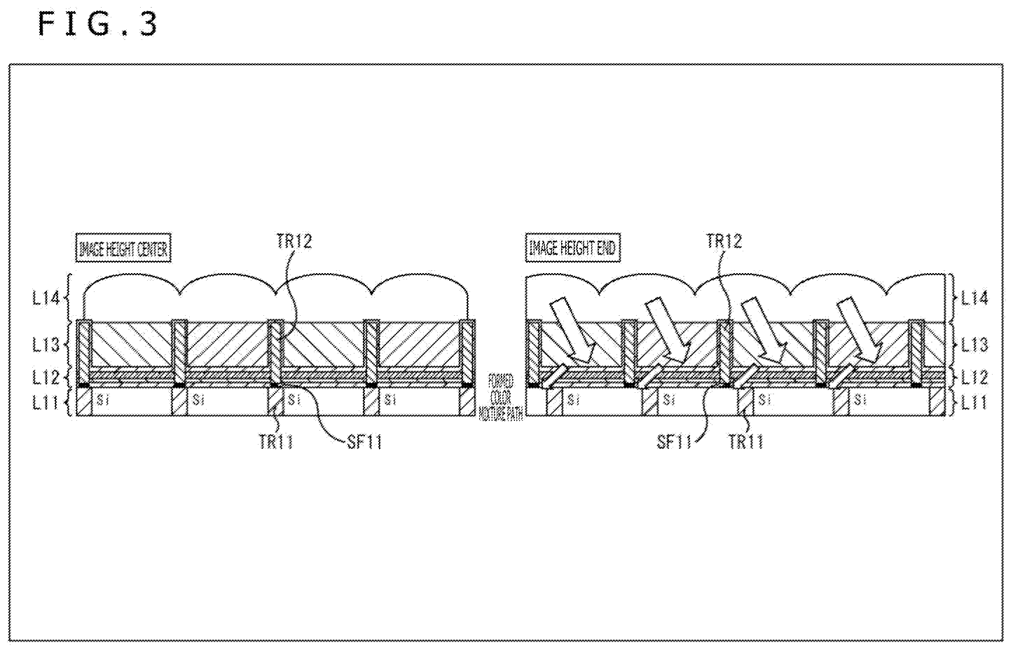

Such processing damage and color mixture paths are similarly produced even in a case where a metal film SF11 is provided adjacent to the low refractive index wall TR12 as depicted in FIG. 3, for example.

Note that depicted in a left part of FIG. 3 is a cross section of the pixel array unit GA11 at an image height center corresponding to the position P11 in FIG. 2 and depicted in a right part of FIG. 3 is a cross section of the pixel array unit GA11 on the image height end side corresponding to the position P12 in FIG. 2.

According to this example, the metal film SF11 functioning as a light shielding film is positioned between the low refractive index wall TR12 and the trench TR11 at the image height center. In contrast, the metal film SF11 is positioned immediately below the low refractive index wall TR12 on the image height end side, and comes into contact with the photoelectric conversion units. Moreover, clearances are produced between the trench TR11 and the metal film SF11 located immediately below the low refractive index wall TR12.

In this case, processing damage and color mixture paths are produced on the image height end side in the example of FIG. 3, as in the example of FIG. 2.

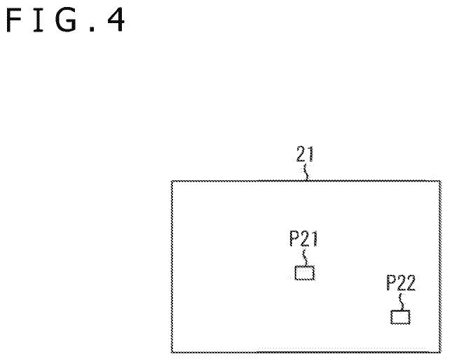

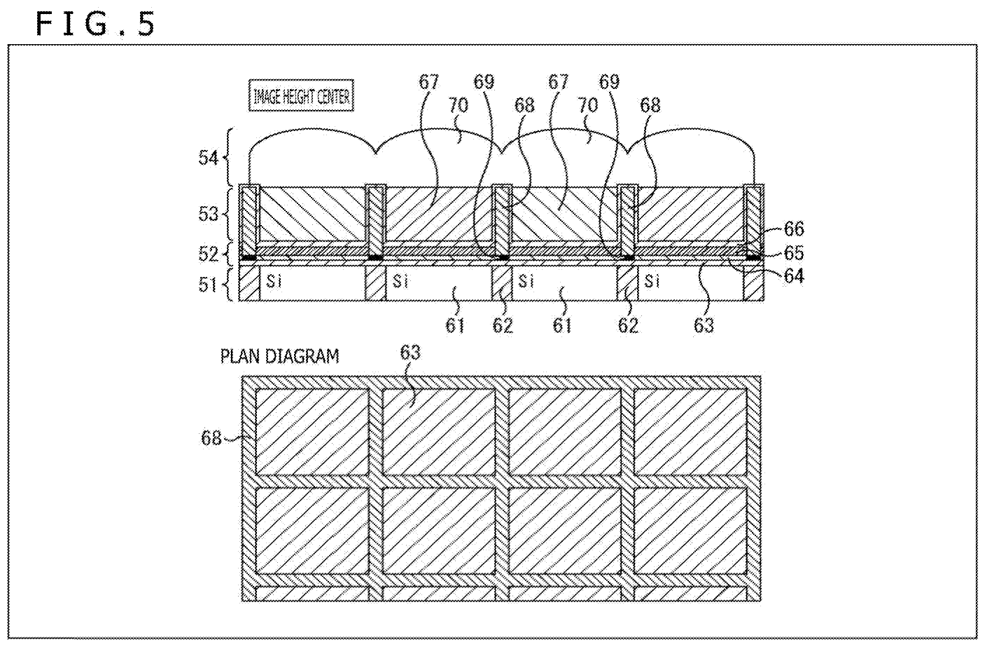

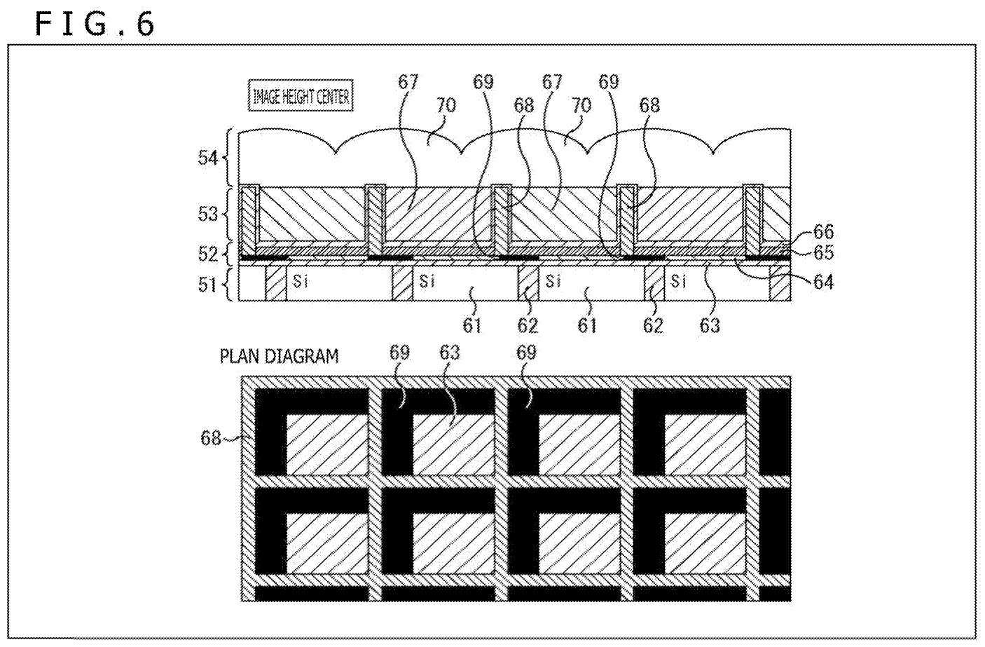

Accordingly, the CMOS image sensor 11 of the present technology is structured as depicted in FIGS. 4 to 6 to reduce processing damage and formation of color mixture paths, and achieves improvement of sensor characteristics. Note that parts corresponding to each other in FIGS. 5 and 6 are given identical reference signs, and explanation of these parts will not be repeated.

FIG. 4 is a plan diagram of the pixel array unit 21 having a plurality of pixels as viewed in a direction perpendicular to a surface of the semiconductor substrate constituting the pixel array unit 21, i.e., a light receiving surface of the pixel array unit 21 (hereinafter also referred to as an optical axis direction).

A position P21 of the pixel array unit 21 in FIG. 4 corresponds to a center position of the light receiving surface of the pixel array unit 21, i.e., a position at an image height center. In addition, a position P22 located on the lower right side of the position P21 in the figure corresponds to a position located near an image height end but away from the image height center, i.e., a position near an end of the light receiving surface of the pixel array unit 21.

For example, the pixel array unit 21 has a cross section depicted in FIG. 5 at the position P21 (image height center).

Note that an upper part of FIG. 5 is a cross-sectional diagram of the pixel array unit 21 viewed in a direction perpendicular to the optical axis direction, while a lower part of the figure is a plan diagram of a portion corresponding to an oxide film layer of the pixel array unit 21 viewed in the optical axis direction.

As depicted in the upper part of the figure, the pixel array unit 21 has a photoelectric conversion layer 51, an oxide film layer 52, a color filter layer 53, and a micro-lens layer 54.

The photoelectric conversion layer 51 includes a semiconductor substrate, and has photoelectric conversion units 61 provided one for each of pixels and a trench 62 provided between the photoelectric conversion units 61 of the pixels adjacent to each other (between pixels).

Specifically, each of the photoelectric conversion units 61 of the respective pixels is surrounded by the trench 62 as viewed in the optical axis direction. In other words, a portion corresponding to the photoelectric conversion unit 61 in each of the pixels is separated by the trench 62.

Moreover, the oxide film layer 52 including an oxide film functioning as an anti-reflection film is formed adjacently to one end of the photoelectric conversion layer 51, while an unillustrated wiring layer including such components as transistors for driving the pixels is formed at an end of the photoelectric conversion layer 51 on the side opposite to the oxide film layer 52.

The oxide film layer 52 includes an oxide film 63 including AlO, an oxide film 64 including HfO, an oxide film 65 including SiO, and an oxide film 66 including AlO, sequentially disposed in this order from the photoelectric conversion layer 51 side to the color filter layer 53. Note that the oxide films 63 to 66 are not required to include the materials presented in this example, and may include any other materials.

Moreover, the color filter layer 53 is provided on the oxide film layer 52 on the side opposite to the photoelectric conversion layer 51. In other words, the oxide film layer 52 is formed between the photoelectric conversion layer 51 and the color filter layer 53.

The color filter layer 53 includes color filters 67 of respective colors, such as R (red), G (green), and B (blue), one for each of the pixels. A low refractive index wall 68 for reducing color mixture and lowering of pixel sensitivity is formed between the color filters 67 provided for each of the pixels, i.e., between the pixels.

In other words, a region of the color filter 67 provided for each of the pixels is surrounded and separated by the low refractive index wall 68 in the color filter layer 53 when viewed in the optical axis direction.

The low refractive index wall 68 penetrates the entire color filter layer 53, and is embedded up to an intermediate position in the oxide film layer 52. Specifically, the low refractive index wall 68 is formed from an end of the color filter layer 53 on the micro-lens layer 54 side (an end opposite to the oxide film layer 52 side) to a position at an end of the oxide film 65 in the oxide film layer 52. Accordingly, the low refractive index wall 68 is embedded in portions corresponding to the oxide film 65 and the oxide film 66 in the oxide film layer 52.

In addition, a metal film 69 functioning as a light shielding film is embedded (formed) in a portion of the oxide film 64 in the oxide film layer 52 and located immediately below the low refractive index wall 68, i.e., adjacent to a portion of a lower side end (lower end) of the low refractive index wall 68 in the figure. Moreover, the micro-lens layer 54 includes on-chip lenses 70 one for each of the pixels.

For example, the low refractive index wall 68 here includes such a material as SiN, SiO₂, SiON, a styrene-based resin material, an acryl-based resin material, a styrene-acryl copolymerization-based resin material, a siloxane-based resin material, the atmosphere, and a vacuum. Particularly, the low refractive index wall 68 includes an insulator material (low refractive index material) having a lower refractive index than that of the color filters 67.

Further, for example, the metal film 69 includes such metal as Ti, W, Cu, or Al, or an oxide film including any of these kinds of metal.

Center positions of the on-chip lens 70, the color filter 67, and the photoelectric conversion unit 61 are aligned with each other (located at the same position) at the position P21 (image height center) as viewed in the optical axis direction.

Accordingly, as depicted in the lower part of the figure, the low refractive index wall 68 and the trench 62 are so positioned as to overlap with each other as viewed in the optical axis direction. Moreover, as depicted in the upper part of the figure, the low refractive index wall 68 and the trench 62 are also aligned with each other in the horizontal direction of the figure as viewed in the direction perpendicular to the optical axis direction. However, the metal film 69 and the oxide film 63 are provided between the low refractive index wall 68 and the trench 62. Accordingly, the low refractive index wall 68 does not come into contact with the photoelectric conversion layer 51 (the trench 62 or the photoelectric conversion units 61).

According to the pixel array unit 21 thus configured, light coming from an object is collected by the on-chip lenses 70, and then enters the photoelectric conversion units 61 via the color filters 67 and the oxide film layer 52. Each of the photoelectric conversion units 61 photoelectrically converts the light entering from the outside, to output a signal corresponding to an amount of the light having entered to the vertical signal line 27, as a pixel signal.

In addition, the pixel array unit 21 has a cross section depicted in FIG. 6 at the position P22 (the position near the image height end) depicted in FIG. 4.

Note that an upper part of FIG. 6 is a cross-sectional diagram of the pixel array unit 21 viewed in a direction perpendicular to the optical axis direction, while a lower part of the figure is a plan diagram of a portion corresponding to the oxide film layer 52 in the pixel array unit 21 viewed in the optical axis direction.

As described with reference to FIG. 5, the pixel array unit 21 has the photoelectric conversion layer 51, the oxide film layer 52, the color filter layer 53, and the micro-lens layer 54.

However, as depicted in the upper part of the figure, center positions of the on-chip lens 70 and the color filter 67 of each of the pixels are not aligned with a center position of the photoelectric conversion unit 61 (located at different positions) at the position near the image height end as viewed in the direction perpendicular to the optical axis direction.

Specifically, the on-chip lens 70, the color filter 67, and the low refractive index wall 68 adjacent to the pixels (located between the pixels) are shifted toward the center of the pixel array unit 21 with respect to the photoelectric conversion unit 61 and the trench 62.

Such correction which shifts the arrangement positions of the on-chip lens 70, the color filter 67, and the low refractive index wall 68 of each of the pixels by a distance corresponding to the image height, i.e., the pixel position in the pixel array unit 21, is called pupil correction. Execution of pupil correction allows a larger amount of light to enter the pixels, and thus achieves improvement of pixel sensitivity.

Specifically, the center position of the color filter 67 is located on the left side, i.e., at a position closer to the center of the pixel array unit 21, in the figure as viewed from the center position of the photoelectric conversion unit 61 of the same pixel. The position of the low refractive index wall 68 is also changed in line with correction of the arrangement position of the color filter 67.

Moreover, the center position of the on-chip lens 70 is located on the left side, i.e., at a position closer to the center of the pixel array unit 21 in the figure as viewed from the center position of the color filter 67 of the same pixel.

A shift amount of the center position of each of the on-chip lens 70 and the color filter 67 from the center position of the photoelectric conversion unit 61 within the same pixel, i.e., a shift distance of the arrangement position, will be referred to as a correction amount of pupil correction here. The correction amount of the on-chip lens 70 is larger than the correction amount of the color filter 67. Note that the correction amount of the low refractive index wall 68 is equal to the correction amount of the color filter 67.

As illustrated in the upper part of FIG. 6, at the position P22, light coming from an unillustrated imaging lens disposed before the pixel array unit 21 enters the pixels from the upper left toward the lower right in the figure. Accordingly, pupil correction executed with a correction amount corresponding to an incident angle of the light coming from the imaging lens allows a larger amount of light to enter each of the photoelectric conversion units 61, and thus improves pixel sensitivity. In other words, sensor characteristics are allowed to improve.

Moreover, the low refractive index wall 68 does not penetrate the trench 62, and is embedded up to an intermediate position in the oxide film layer 52.

The metal film 69 is formed immediately below the low refractive index wall 68. The oxide film 63 is always present between the photoelectric conversion layer 51, i.e., the photoelectric conversion unit 61 and the trench 62, and the low refractive index wall 68 and the metal film 69 for any correction amount of pupil correction.

In other words, each of the low refractive index wall 68 and the metal film 69 has a structure not in contact with the photoelectric conversion layer 51 (the trench 62 or the photoelectric conversion unit 61) for any correction amount of pupil correction.

In this case, no processing damage to the photoelectric conversion unit 61 is caused during a manufacturing process of the CMOS image sensor 11. Accordingly, sensor characteristics are not deteriorated by processing damage.

Moreover, a line width of the metal film 69 functioning as a light shielding film in the pixel array unit 21 also changes according to the image height (the distance from the center of the pixel array unit 21 to the pixel), i.e., the correction amount of pupil correction.

According to this example, a line width of the metal film 69 at the position P22, i.e., a width in the direction perpendicular to the optical axis direction, is longer (larger) than a line width of the metal film 69 at the position P21.

Particularly in this example, as depicted in the upper part of FIG. 6, the metal film 69 within each of the pixels is formed from the end of the low refractive index wall 68 on the side opposite to the trench 62 to the end of the trench 62 on the side opposite to the low refractive index wall 68 as viewed in the direction perpendicular to the optical axis direction. Accordingly, as depicted in the lower part of the figure, the metal film 69 is protruded (projected) toward the inside of the pixel from the low refractive index wall 68 as viewed in the optical axis direction.

Changing the line width of the metal film 69 according to the correction amount of pupil correction in the manner described above allows the region of the metal film 69 to contain (overlap with) not only the entire low refractive index wall 68 and the entire trench 62, but also the region between the low refractive index wall 68 and the trench 62 as viewed in the optical axis direction.

Specifically, the metal film 69 is present without clearance between the low refractive index wall 68 and the trench 62 located at the same end of each of the pixels as viewed in the optical axis direction. In other words, the clearance produced between the low refractive index wall 68 and the trench 62 is closed by the metal film 69 having a light shielding function, as viewed in the optical axis direction.

In this case, the color mixture paths described with reference to FIGS. 2 and 3 are not formed in the pixel array unit 21. Accordingly, deterioration of sensor characteristics caused by color mixture can be reduced. In other words, sensor characteristics are allowed to further improve.

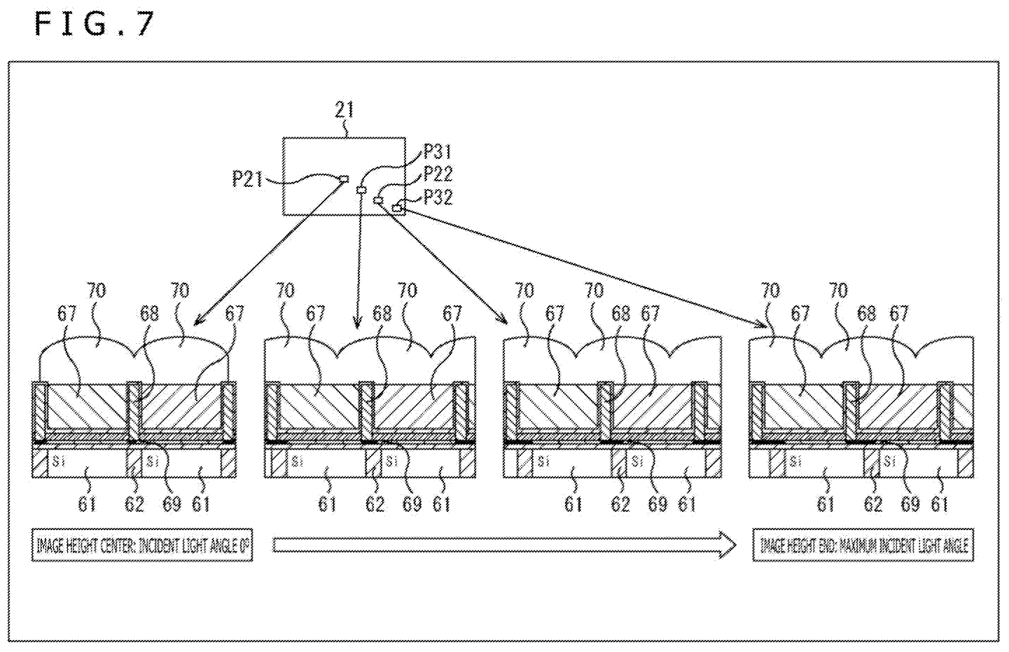

Examples of the correction amount of pupil correction and the line width of the metal film 69 provided according to the image height will be described here with reference to FIG. 7.

Depicted in an upper part of FIG. 7 is a diagram of the pixel array unit 21 viewed in the optical axis direction. The position P21 of the pixel array unit 21 corresponds to a center position of the pixel array unit 21, i.e., a position at an image height center.

In addition, a position P32 corresponds to an image height end, i.e., a position at an end of the pixel array unit 21. A position P31 and the position P22 are positions between the position P21 and the position P31. Particularly concerning the positions P31 and P22, the position P31 is closer to the position P21 (image height center) than the position P22.

An unillustrated imaging lens is disposed on a front surface of the pixel array unit 21. An incident light angle which is an incident angle of light entering each of the pixels from the imaging lens increases as the image height increases, i.e., as the pixel is located farther from the center of the pixel array unit 21.

For example, the incident light angle has 0 degrees at the position P21 located at the image height center, and has a maximum value at the position P32 located at the image height end.

According to the pixel array unit 21, as depicted in a lower part of the figure, for example, pupil correction is achieved with a correction amount corresponding to the value of the incident light angle in such a manner that the correction amount increases as the image height increases, i.e., the incident light angle increases. Moreover, the metal film 69 is formed in line with the correction amount of pupil correction in such a manner that the line width of the metal film 69 also increases as the correction amount of pupil correction increases.

Depicted in a lower part of the figure are cross-sectional diagrams of the pixel array unit 21 at the respective positions of the position P21, the position P31, the position P22, and the position P32 as viewed in the direction perpendicular to the optical axis direction.

The leftmost diagram in the lower part of the figure is a cross-sectional diagram at the position P21 corresponding to the image height center. The correction amount of the pupil correction is 0 at the position P21 as depicted in FIG. 5. Specifically, centers of the on-chip lens 70, the color filter 67, and the photoelectric conversion unit 61 are aligned with each other. Moreover, the line width of the metal film 69 (the width in the horizontal direction in the figure) is equal to the width of the low refractive index wall 68.

The second diagram from the left in the lower part of the figure is a cross-sectional diagram at the position P31. The center positions of the on-chip lens 70 and the color filter 67 are located on the image height center side with respect to the center position of the photoelectric conversion unit 61 at the position P31. Moreover, the line width of the metal film 69 is also larger than the width of the low refractive index wall 68.

The third diagram from the left in the lower part of the figure is a cross-sectional diagram at the position P22. The center positions of the on-chip lens 70 and the color filter 67 are further shifted toward the image height center from the center position of the photoelectric conversion unit 61 at the position P22 in comparison with the case of the position P31. Moreover, the line width of the metal film 69 is also further larger than that width of the case at the position P31 so as to prevent formation of color mixture paths between the low refractive index wall 68 and the trench 62.

The rightmost diagram in the lower part of the figure is a cross-sectional diagram at the position P32. The center positions of the on-chip lens 70 and the color filter 67 are further shifted toward the image height center from the center of the photoelectric conversion unit 61 at the position P32 in comparison with the case of the position P22. Moreover, the line width of the metal film 69 is also further larger than that width of the case at the position P22 so as to prevent formation of color mixture paths between the low refractive index wall 68 and the trench 62.

As described above, pupil correction is achieved in the pixel array unit 21 in such a manner that the correction amount increases as the pixel is located at a longer distance (farther) from the center of the pixel array unit 21, and the metal film 69 is formed such that the line width of the metal film 69 increases in proportion to the correction amount of the pupil correction.

### <Manufacture of Pixel Array Unit>

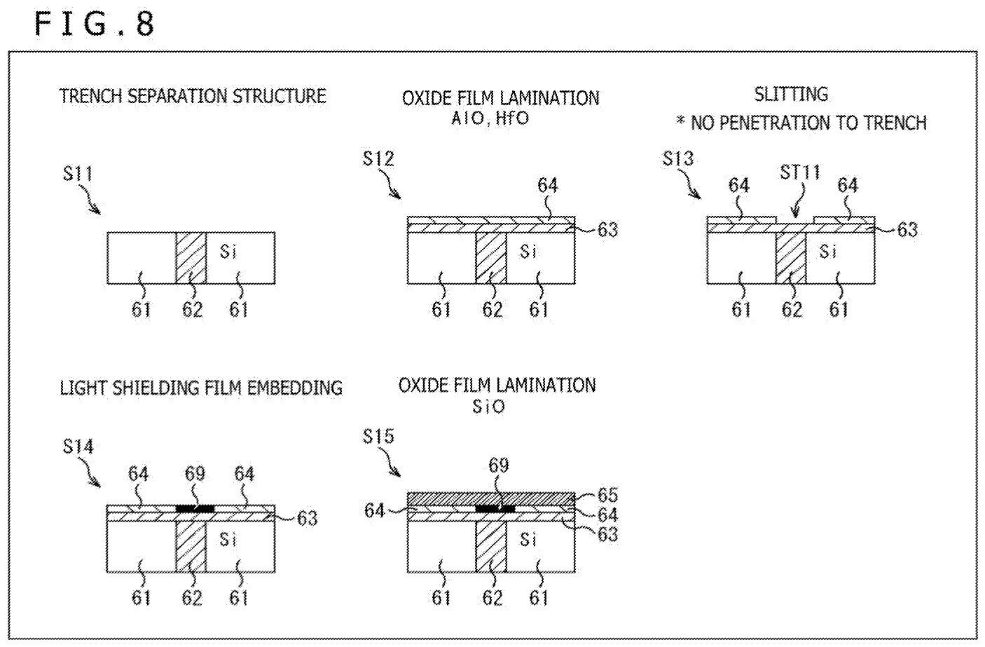

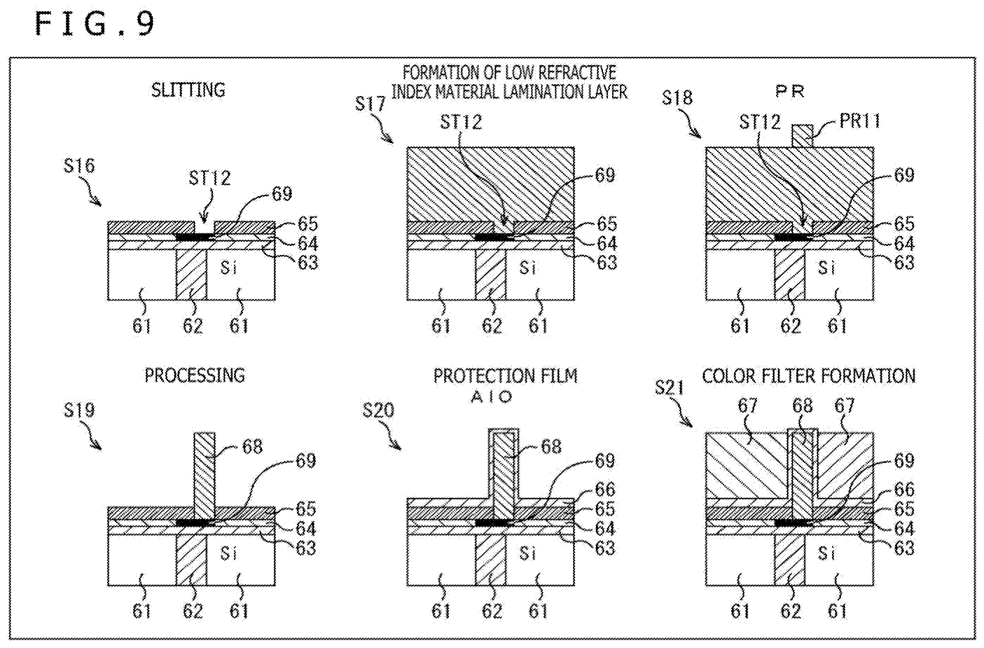

A manufacturing method (manufacturing process) of the pixel array unit 21 will next be described with reference to FIGS. 8 and 9.

At the time of manufacture of the pixel array unit 21, as indicated by an arrow S11 in FIG. 8, a trench separation structure that includes polysilicon and that is provided for separating the pixels is initially formed in a region including Si in a semiconductor substrate, i.e., a region corresponding to the photoelectric conversion units 61. In other words, the trench 62 is formed using polysilicon.

Subsequently, as indicated by an arrow S12, the oxide film 63 including AlO is laminated on upper surfaces of the photoelectric conversion units 61 and the trench 62 in the semiconductor substrate. Moreover, the oxide film 64 including HfO is laminated on the oxide film 63.

Thereafter, as indicated by an arrow S13, a slit ST11 is formed in a portion of the oxide film 64 by slitting. At this time, the slit ST11 is so formed as not to penetrate the trench 62, i.e., not to expose the trench 62.

Moreover, as indicated by an arrow 514, the light shielding film, i.e., the metal film 69, is embedded in the slit ST11. Further, as indicated by an arrow 515, the oxide film 65 including SiO is laminated on the upper side of the oxide film 64 and the metal film 69.

Thereafter, as indicated by an arrow S16 in FIG. 9, a slit ST12 is formed by slitting in a portion included in the oxide film 65 and located immediately above the metal film 69. As indicated by an arrow 517, a low refractive index material is laminated on the oxide film 65. In other words, a film is formed using the low refractive index material.

After lamination of the low refractive index material, as indicated by an arrow S18, a photoresist PR11 is formed on the laminated low refractive index material above the slit ST12, i.e., at a position where the low refractive index wall 68 is to be formed.

Thereafter, as indicated by an arrow 519, processing is performed in such a manner as to remove a portion of the laminated low refractive index material other than a portion immediately below the photoresist PR11 and further remove the photoresist PR11. In this manner, a portion of the low refractive index material consequently remaining after the removal is designated as the low refractive index wall 68. In other words, the low refractive index wall 68 is formed by processing for removing a part of the low refractive index material.

In addition, as indicated by an arrow 520, film formation for covering surfaces of the oxide film 65 and the low refractive index wall 68 with a protection film including AlO is carried out to form the oxide film 66. Accordingly, the corresponding area, more specifically, the low refractive index wall 68, is covered with the protection film including AlO, i.e., the oxide film 66, also in the examples depicted in FIGS. 5 and 6.

Finally, as indicated by an arrow S21, each of the color filters 67 is formed on a portion surrounded by the low refractive index wall 68 and located above the oxide film 66, and the on-chip lens 70 is provided on an upper portion of each of the color filters 67 to complete the pixel array unit 21.

### Modification of First Embodiment

### Different Configuration Example of Pixel Array Unit

Note that the depth of the low refractive index wall 68 (depth of embedding) to be formed, the thickness and the line width of the metal film 69, and the like in the pixel array unit 21 described above may be varied in any manner.

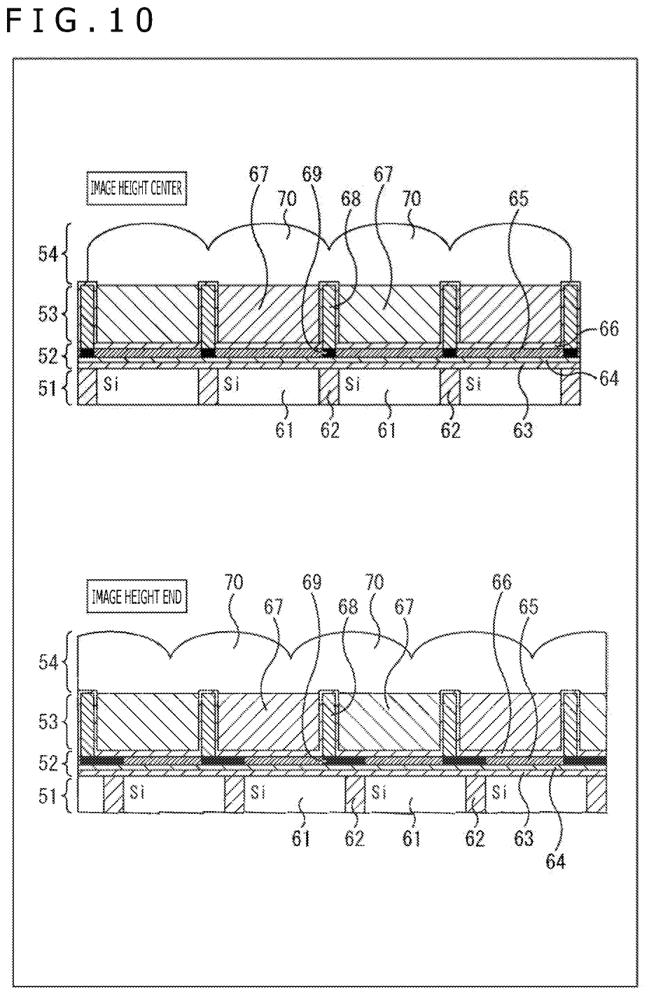

Different configuration examples of the pixel array unit 21 will hereinafter be described with reference to FIGS. 10 to 21. Note that parts in FIGS. 10 to 21 identical to the corresponding parts in FIGS. 5 and 6 are given identical reference signs, and the same explanation of these parts will not be repeated where appropriate. Moreover, parts corresponding to each other in FIGS. 10 to 21 are given identical reference signs, and the same explanation of these parts will not be repeated where appropriate.

For example, according to the pixel array unit 21, the low refractive index wall 68 may be embedded up to the oxide film 66 in the oxide film layer 52, and the metal film 69 may be embedded in a portion included in the oxide film 65 and located immediately below the low refractive index wall 68 as depicted in FIG. 10.

Depicted in an upper part of FIG. 10 is a cross section of the portion located at the position P21 depicted in FIG. 4 as viewed in the direction perpendicular to the optical direction, while depicted in a lower part of the figure is a cross section of the portion at the position P22 depicted in FIG. 4 as viewed in the direction perpendicular to the optical axis direction.

In the example depicted in the upper part of the figure, a correction amount of pupil correction at the position P21 is 0 as in the case in FIG. 5. Moreover, the metal film 69 is formed within the oxide film 65. Accordingly, the distance from the low refractive index wall 68 to the trench 62 is longer than the corresponding distance in the case of FIG. 5.

In the example depicted in a lower part of the figure, the on-chip lenses 70 and the color filters 67 are shifted by pupil correction by a correction amount corresponding to an image height, as in the case in FIG. 6. Moreover, the metal film 69 formed here also has a line width corresponding to the correction amount of the pupil correction, and formation of color mixture paths is reduced.

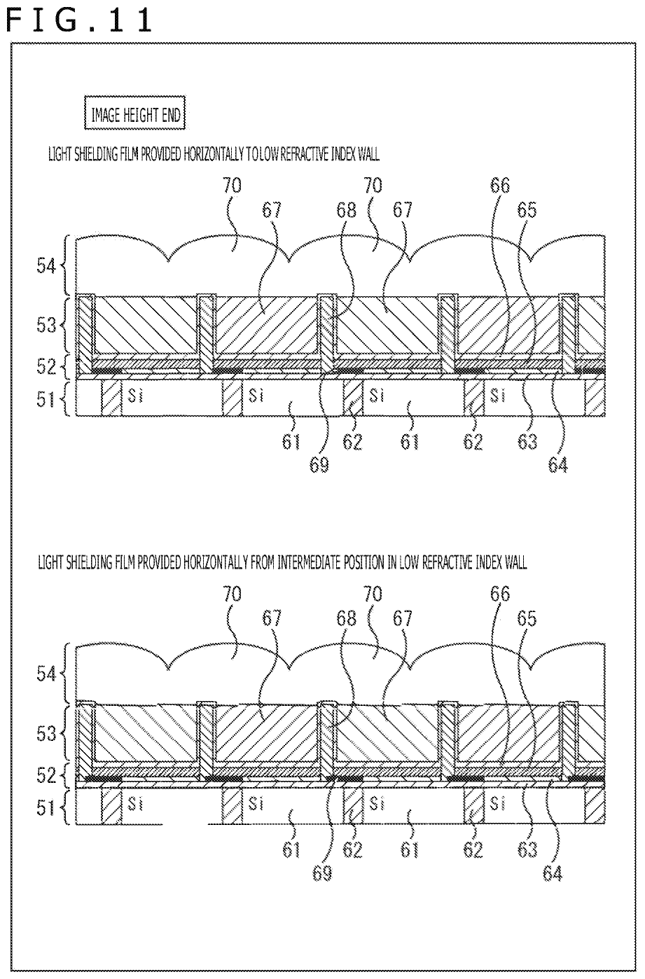

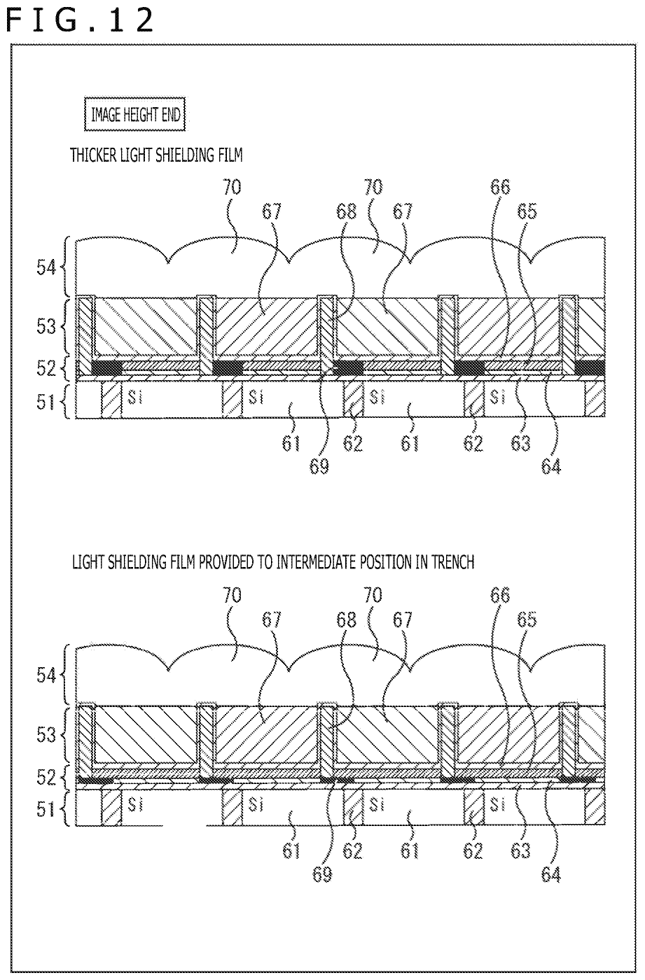

Further, in a case where the metal film 69 is formed in the oxide film 64, for example, the configuration depicted in FIG. 5 may be applied to the position P21. For the position P22, the line width and the thickness of the metal film 69 may be changed to any width and thickness while pupil correction similar to the pupil correction of the case in FIG. 6 is carried out as depicted in FIGS. 11 and 12. Note that each of FIGS. 11 and 12 depicts a cross section of the portion of the pixel array unit 21 at the position P22 as viewed in the direction perpendicular to the optical axis direction.

According to an example depicted in an upper part of FIG. 11, the low refractive index wall 68 penetrates the oxide film 64 and is embedded up to an end of the oxide film 63, while the metal film 69 is formed from the trench 62 side end of the low refractive index wall 68 up to the end of the trench 62 on the side opposite to the low refractive index wall 68. In other words, the metal film 69 is provided adjacently to a side surface of the low refractive index wall 68 on the trench 62 side.

In this example as well, the metal film 69 is present without clearance between the low refractive index wall 68 and the trench 62 located at the same end side of the same pixel as viewed in the optical axis direction. Accordingly, color mixture paths are not formed.

Meanwhile, according to an example depicted in a lower part of FIG. 11, the metal film 69 is formed from a central (intermediate) position in the low refractive index wall 68 to the end of the trench 62 on the side opposite to the low refractive index wall 68, thus reducing formation of color mixture paths. In other words, a part of the metal film 69 is embedded in the low refractive index wall 68. According to this example, a part of the low refractive index wall 68 is embedded up to an end portion of the metal film 69 embedded in the oxide film 64, while a remaining part of the low refractive index wall 68 is embedded up to the end of the oxide film 63.

According to an example depicted in an upper part of FIG. 12, the low refractive index wall 68 penetrates the oxide film 64, and is embedded up to the end of the oxide film 63, while the metal film 69 is embedded not only in a portion in the oxide film 64, but also in a portion in the oxide film 65. Specifically, the metal film 69 extending over the oxide film 64 and the oxide film 65 is embedded in the portions corresponding to these oxide films. Accordingly, the metal film 69 has a larger thickness in the optical axis direction than in the example depicted in FIG. 6.

According to this example, the metal film 69 is disposed adjacently to the side surface of the low refractive index wall 68, and formed from the end of the low refractive index wall 68 on the trench 62 side to the end of the trench 62 on the side opposite to the low refractive index wall 68, thus reducing formation of color mixture paths.

According to an example depicted in a lower part of FIG. 12, the low refractive index wall 68 is embedded up to the oxide film 65. The metal film 69 is formed from the end of the low refractive index wall 68 on the side opposite to the trench 62 to a central (intermediate) position in the trench 62, thus reducing formation of color mixture paths. In this example, the low refractive index wall 68 is disposed immediately above the metal film 69.

According to the respective examples described above with reference to FIGS. 11 and 12, the line width of the metal film 69 also changes according to the correction amount of pupil correction.

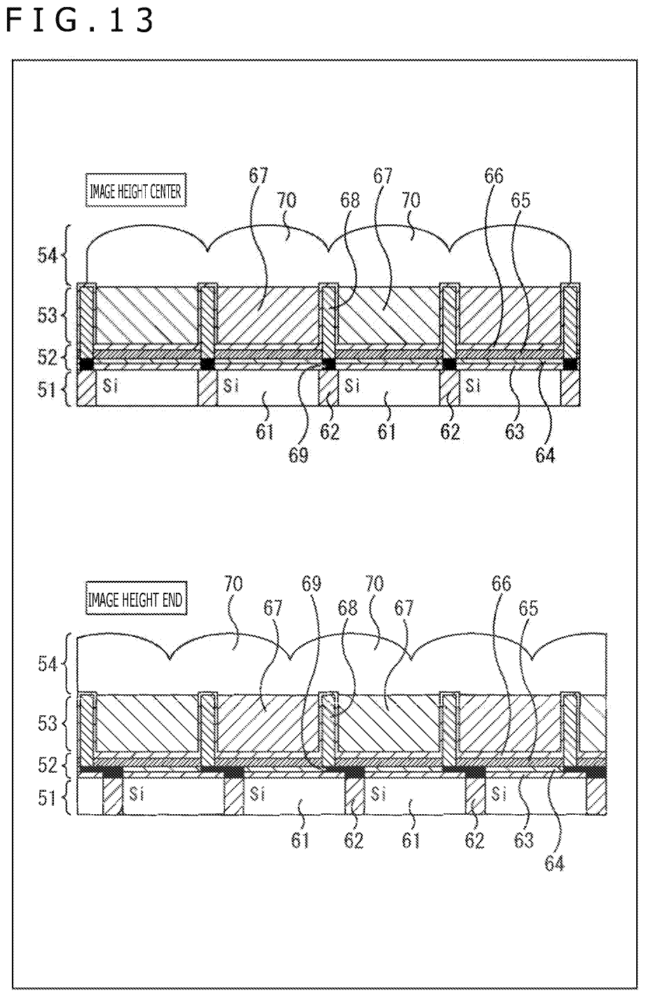

In addition, as depicted in FIG. 13, the metal film 69 may be formed between the low refractive index wall 68 and the trench 62.

Depicted in an upper part of FIG. 13 is a cross section of the portion of the pixel array unit 21 at the position P21 (image height center) as viewed in the direction perpendicular to the optical axis direction.

The correction amount of pupil correction is 0 at the position P21, and the metal film 69 is formed in portions corresponding to the oxide film 63 and the oxide film 64. Accordingly, only the metal film 69 is formed between the low refractive index wall 68 and the trench 62. Specifically, the low refractive index wall 68 is formed immediately above the metal film 69, while the trench 62 is formed immediately below the metal film 69.

In addition, depicted in a lower part of the figure is a cross section of the portion of the pixel array unit 21 at the position P22 (image height end side) as viewed in the direction perpendicular to the optical axis direction.

The correction amount of pupil correction is a correction amount corresponding to the image height at the position P22. Moreover, the metal film 69 is formed in portions corresponding to the oxide film 63 and the oxide film 64.

Specifically, the metal film 69 in the oxide film 63 is formed only in a portion immediately above the trench 62. However, the metal film 69 in the oxide film 64 is formed from the end of the low refractive index wall 68 on the side opposite to the trench 62 to the end of the trench 62 on the side opposite to the low refractive index wall 68.

In this case, the space between the trench 62 and the low refractive index wall 68 is closed by the metal film 69 having a light shielding function. Accordingly, color mixture paths are not formed.

In the example depicted in FIG. 13, the line width of the portion of the metal film 69 at the embedded position in the oxide film 64 changes according to the correction amount of pupil correction, i.e., the image height. Accordingly, it is considered that a metal film that is formed immediately above the trench 62 and that has a constant line width and a metal film that is formed immediately below the low refractive index wall 68 and that has a changeable line width according to the image height are connected to form one metal film functioning as the metal film 69.

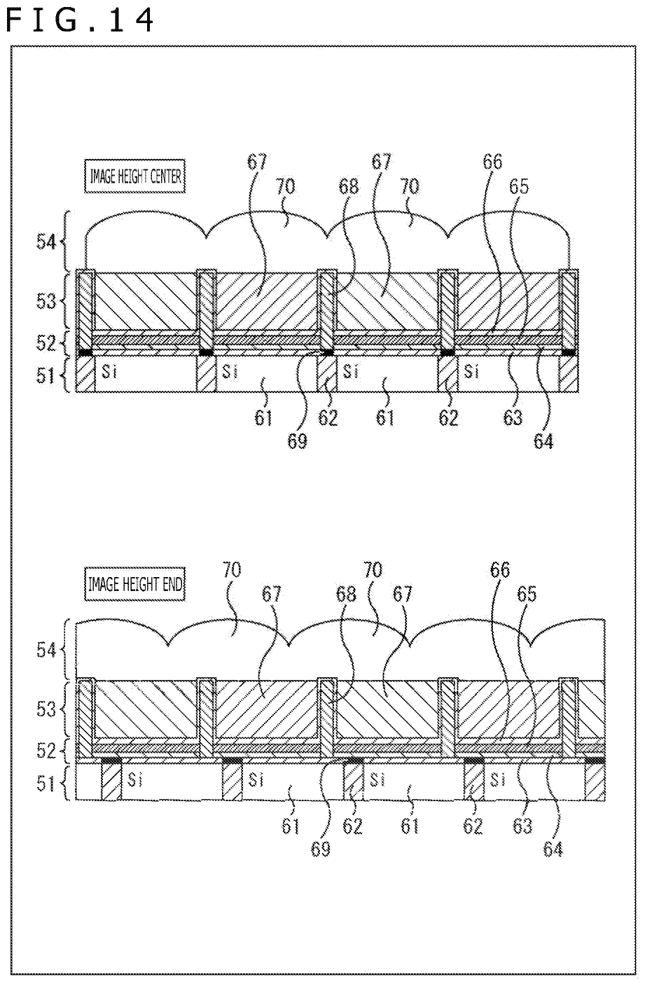

Moreover, as depicted in FIG. 14, the metal film 69 may be formed immediately above the trench 62, i.e., adjacently to an upper side end (upper end) of the trench 62, in the figure.

Depicted in an upper part of FIG. 14 is a cross section of the portion of the pixel array unit 21 at the position P21 (image height center) as viewed in the direction perpendicular to the optical axis direction.

The correction amount of the pupil correction is 0 at the position P21, and the metal film 69 is formed in a part of the oxide film 63. Moreover, the low refractive index wall 68 is embedded up to the oxide film 64.

Accordingly, only the metal film 69 is formed between the low refractive index wall 68 and the trench 62. Specifically, the low refractive index wall 68 is formed immediately above the metal film 69, while the trench 62 is formed immediately below the metal film 69.

In addition, depicted in a lower part of the figure is a cross section of the portion of the pixel array unit 21 at the position P22 (image height end side) as viewed in the direction perpendicular to the optical axis direction.

The correction amount of pupil correction is a correction amount corresponding to the image height at the position P22. Moreover, the metal film 69 is formed only at a portion immediately above the trench 62 in the oxide film 63.

In this case, slight clearances are produced between the metal film 69 immediately above the trench 62 and the low refractive index wall 68. However, these clearances are small, and the metal film 69 having a light shielding function is disposed immediately above the trench 62. Accordingly, more reduction of color mixture is achievable than in the case depicted in FIG. 2.

According to the example depicted in FIG. 14, the line width of the metal film 69 has a constant width, i.e., the same width as the trench 62, for any correction amount of the pupil correction.

While the metal film 69 is formed immediately above the trench 62 in the foregoing respective examples depicted in FIGS. 13 and 14, the oxide film 63 is always present immediately above the photoelectric conversion units 61 even if pupil correction is carried out. In this case, the low refractive index wall 68 and the metal film 69 do not come into contact with the photoelectric conversion units 61. Accordingly, processing damage is not caused.

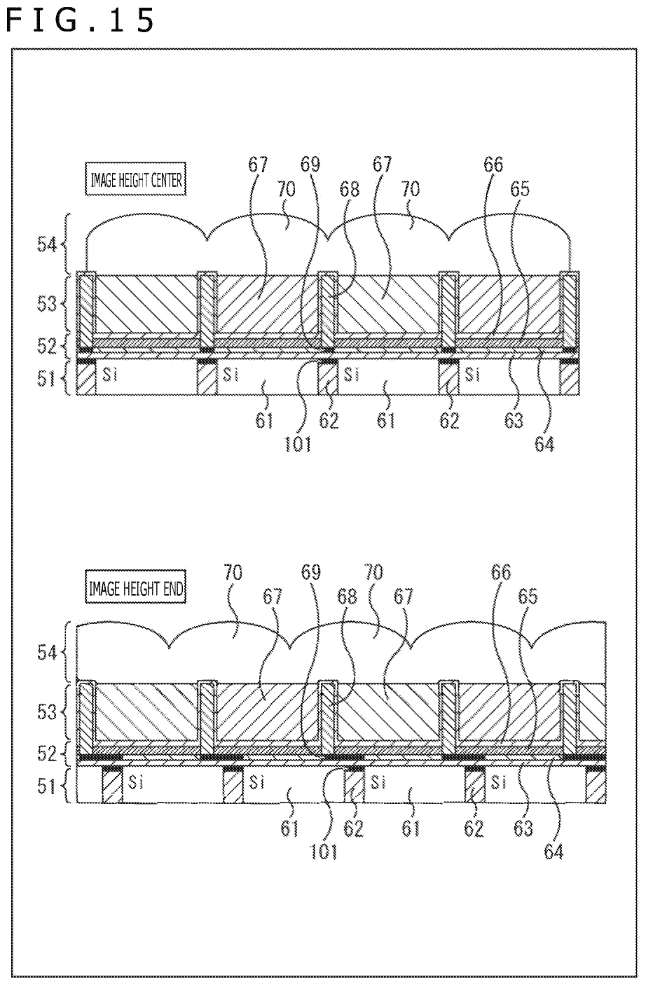

In addition, as depicted in FIG. 15, for example, a metal film 101 having a light shielding function may be formed immediately above the trench 62 in addition to the metal film formed immediately below the low refractive index wall 68.

Depicted in an upper part of FIG. 15 is a cross section of the portion of the pixel array unit 21 at the position P21 (image height center) as viewed in the direction perpendicular to the optical axis direction.

The correction amount of pupil correction is 0 at the position P21. Moreover, the low refractive index wall 68 is embedded up to the oxide film 65. The metal film 69 is formed in a portion that is included in the oxide film 64 and that is located immediately below the low refractive index wall 68.

Further, the metal film 101 having the same width as the trench 62 is formed in a portion that is included in the photoelectric conversion layer 51 and that is located immediately above the trench 62, i.e., an upper side end (upper end) portion of the trench 62, in the figure.

For example, similarly to the metal film 69, the metal film 101 includes such metal as Ti, W, Cu, or Al, or an oxide film including any one of these metals.

According to this example, the metal film 69, the oxide film 63, and the metal film 101 are formed between the low refractive index wall 68 and the trench 62.

In addition, depicted in a lower part of the figure is a cross section of the portion of the pixel array unit 21 at the position P22 (image height end side) as viewed in the direction perpendicular to the optical axis direction.

The correction amount of pupil correction is a correction amount corresponding to the image height at the position P22. Moreover, the metal film 69 is formed in a portion of the oxide film 64.

Specifically, the metal film 69 is formed from the end of the low refractive index wall 68 on the side opposite to the trench 62 to the end position of the trench 62 on the side opposite to the low refractive index wall 68. The line width (the width in the horizontal direction in the figure) of the metal film 69 changes according to the correction amount of pupil correction.

As in the case at the image height center, the metal film 101 having the same width as the trench 62 is formed in a portion that is included in the photoelectric conversion layer 51 and that is located immediately above the trench 62, i.e., at the low refractive index wall 68 side end portion of the trench 62. The metal film 101 constantly has the same line width as the trench 62 (fixed width) for any correction amount of pupil correction.

According to this example, the metal film 69 and the metal film 101 each having a light shielding function are formed between the trench 62 and the low refractive index wall 68. Accordingly, color mixture paths are not formed.

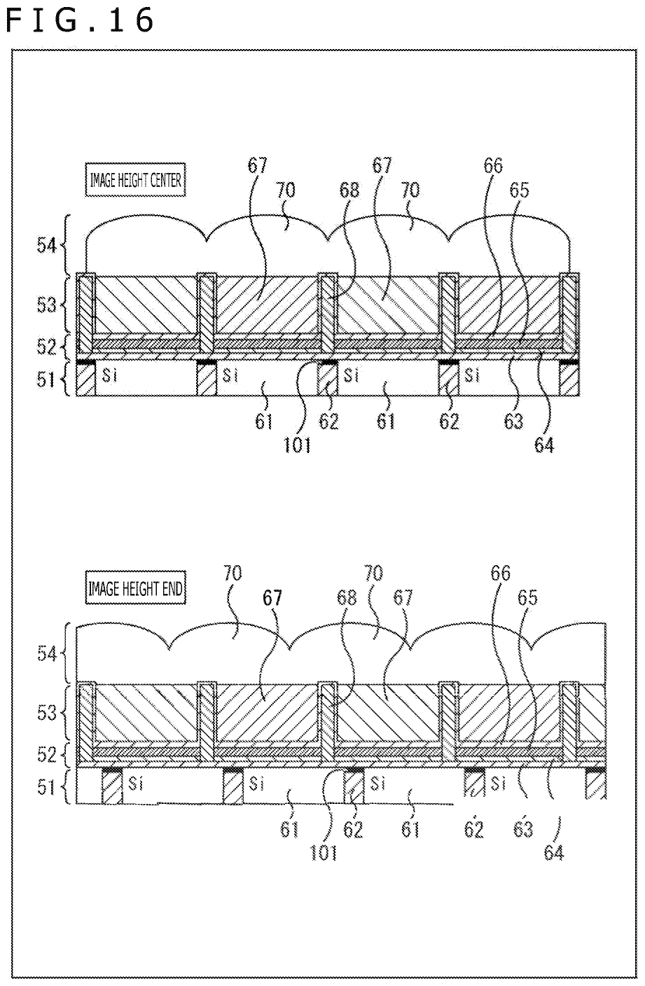

In addition, for example, a configuration eliminating the metal film 69 may be adopted as depicted in FIG. 16.

Depicted in an upper part of FIG. 16 is a cross section of the portion of the pixel array unit 21 at the position P21 (image height center) as viewed in the direction perpendicular to the optical axis direction.

The correction amount of pupil correction is 0 at the position P21, and the low refractive index wall 68 is embedded up to the oxide film 64.

As in the case of FIG. 15, the metal film 101 having the same width as the trench 62 is formed in a portion included in the photoelectric conversion layer 51 and located immediately above the trench 62. However, unlike in the case of FIG. 15, the metal film 69 is not formed between the low refractive index wall 68 and the trench 62 (metal film 101) in this example. In other words, the metal film 69 is eliminated in this example.

In addition, depicted in a lower part of the figure is a cross section of the portion of the pixel array unit 21 at the position P22 (image height end side) as viewed in the direction perpendicular to the optical axis direction.

The correction amount of pupil correction is a correction amount corresponding to the image height at the position P22.

Moreover, as in the case at the image height center, the metal film 101 having the same width as the trench 62 is formed in a portion that is included in the photoelectric conversion layer 51 and that is located immediately above the trench 62. However, the metal film 69 is not formed between the low refractive index wall 68 and the trench 62 (metal film 101). As in the case of FIG. 15, the metal film 101 constantly has the same line width as the trench 62 for any correction amount of the pupil correction.

According to this example, slight clearances are produced between the metal film 101 immediately above the trench 62 and the low refractive index wall 68. However, the metal film 101 having a light shielding function is disposed immediately above the trench 62. Accordingly, more reduction of color mixture is achievable than in the case depicted in FIG. 2.

According to the foregoing respective examples depicted in FIGS. 15 and 16, the oxide film 63 is always present immediately above the photoelectric conversion units 61 even at the time of execution of pupil correction. In this case, the low refractive index wall 68 and the metal film 69 do not come into contact with the photoelectric conversion units 61. Accordingly, processing damage is not caused.

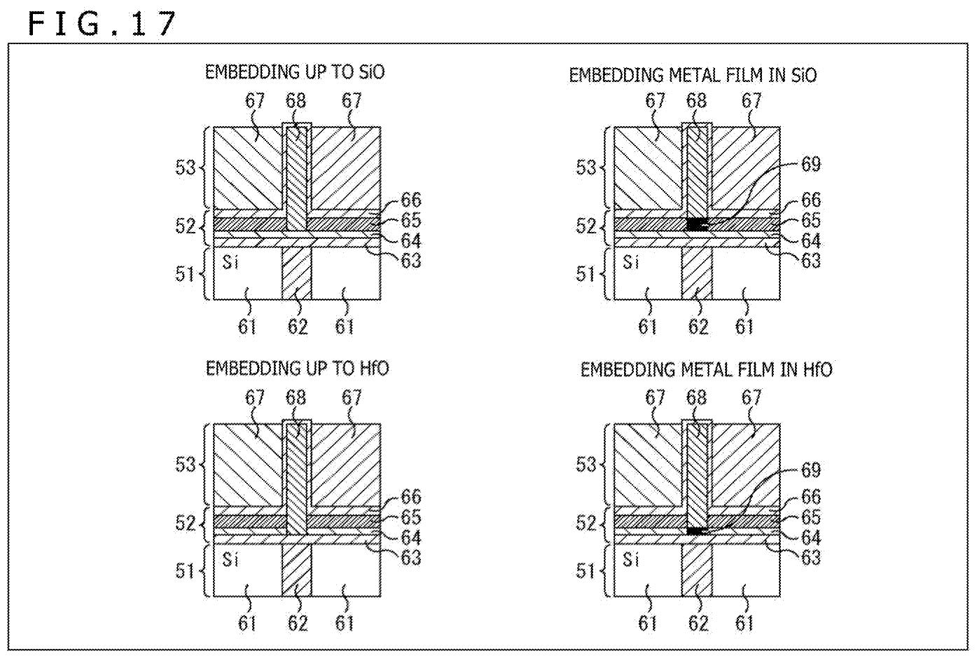

Moreover, as described with reference to FIGS. 5 and 6, in a case where pupil correction is executed according to the image height, the photoelectric conversion layer 51, the oxide film layer 52, and the color filter layer 53 at a portion between the pixels may have the configurations depicted in FIGS. 17, 18, and 19, for example.

Note that each of FIGS. 17 to 19 depicts a cross section at the position P21 depicted in FIG. 4 in the direction perpendicular to the optical axis direction.

According to an example depicted in an upper left part of FIG. 17, for example, the low refractive index wall 68 is embedded up to the oxide film 65 including SiO, such that the low refractive index wall 68 and the trench 62 face each other.

Further, the metal film 69 is not formed in this example, and the oxide film 63 and the oxide film 64 are formed between the low refractive index wall 68 and the trench 62.

In this case, the color filter 67 and the low refractive index wall 68 at the position P22 are shifted toward the image height center from the trench 62 by a distance corresponding to a correction amount of pupil correction.

According to the example described above, the low refractive index wall 68 does not penetrate the oxide film layer 52, and the oxide film 63 and the oxide film 64 are formed between the low refractive index wall 68 and the trench 62. In this case, the low refractive index wall 68 does not come into contact with the photoelectric conversion units 61 for any pupil correction. Accordingly, processing damage to the photoelectric conversion units 61 is not caused.

Moreover, according to an example depicted in an upper right part of FIG. 17, for example, the low refractive index wall 68 is embedded up to the oxide film 66 including AlO, and the metal film 69 having the same width as the low refractive index wall 68 is formed immediately below the low refractive index wall 68. In other words, the metal film 69 is embedded in the oxide film 65 including SiO. The metal film 69 constantly has the same width as the low refractive index wall 68 for any correction amount of pupil correction.

The correction amount of pupil correction is 0 at the position P21. Accordingly, the metal film 69 located immediately below the low refractive index wall 68 and the trench 62 face each other. Further, the oxide film 63 and the oxide film 64 are formed between the low refractive index wall 68 and the trench 62 in this example.

In this case, the color filter 67, the low refractive index wall 68, and the metal film 69 at the position P22 are shifted toward the image height center from the trench 62 by a distance corresponding to the correction amount of the pupil correction. However, as described above, the metal film 69 constantly has the same width as the low refractive index wall 68.

According to the example described above, the oxide film 63 and the oxide film 64 are formed between the metal film 69 located immediately below the low refractive index wall 68 and the trench 62. In this case, the low refractive index wall 68 and the metal film 69 do not come into contact with the photoelectric conversion units 61 for any pupil correction. Accordingly, processing damage to the photoelectric conversion units 61 is not caused.

Moreover, according to an example depicted in a lower left part of FIG. 17, for example, the low refractive index wall 68 is embedded up to the oxide film 64 including HfO, such that the low refractive index wall 68 and the trench 62 face each other.

According to this example, the metal film 69 is not formed, and the oxide film 63 is formed between the low refractive index wall 68 and the trench 62.

In this case, the color filter 67 and the low refractive index wall 68 at the position P22 are shifted toward the image height center from the trench 62 by a distance corresponding to the correction amount of pupil correction.

According to the example described above, the low refractive index wall 68 does not penetrate the oxide film layer 52, and the oxide film 63 is formed between the low refractive index wall 68 and the trench 62. In this case, the low refractive index wall 68 does not come into contact with the photoelectric conversion units 61 for any pupil correction. Accordingly, processing damage to the photoelectric conversion units 61 is not caused.

Further, according to an example depicted in a lower right part of FIG. 17, for example, the low refractive index wall 68 is embedded up to the oxide film 65 including SiO, and the metal film 69 having the same width as the low refractive index wall 68 is formed immediately below the low refractive index wall 68. In other words, the metal film 69 is embedded in the oxide film 64 including HfO. The metal film 69 here constantly has the same width as the low refractive index wall 68 for any correction amount of pupil correction.

The correction amount of pupil correction is 0 at the position P21. Accordingly, the metal film 69 located immediately below the low refractive index wall 68 and the trench 62 face each other. In addition, the oxide film 63 is formed between the metal film 69 and the trench 62 in this example.

In this case, the color filter 67, the low refractive index wall 68, and the metal film 69 at the position P22 are shifted toward the image height center from the trench 62 by a distance corresponding to the correction amount of the pupil correction. However, as described above, the metal film 69 constantly has the same width as the low refractive index wall 68.

According to the example described above, the oxide film 63 is formed between the metal film 69 located immediately below the low refractive index wall 68 and the trench 62. In this case, the low refractive index wall 68 and the metal film 69 do not come into contact with the photoelectric conversion units 61 for any pupil correction. Accordingly, processing damage to the photoelectric conversion units 61 is not caused.

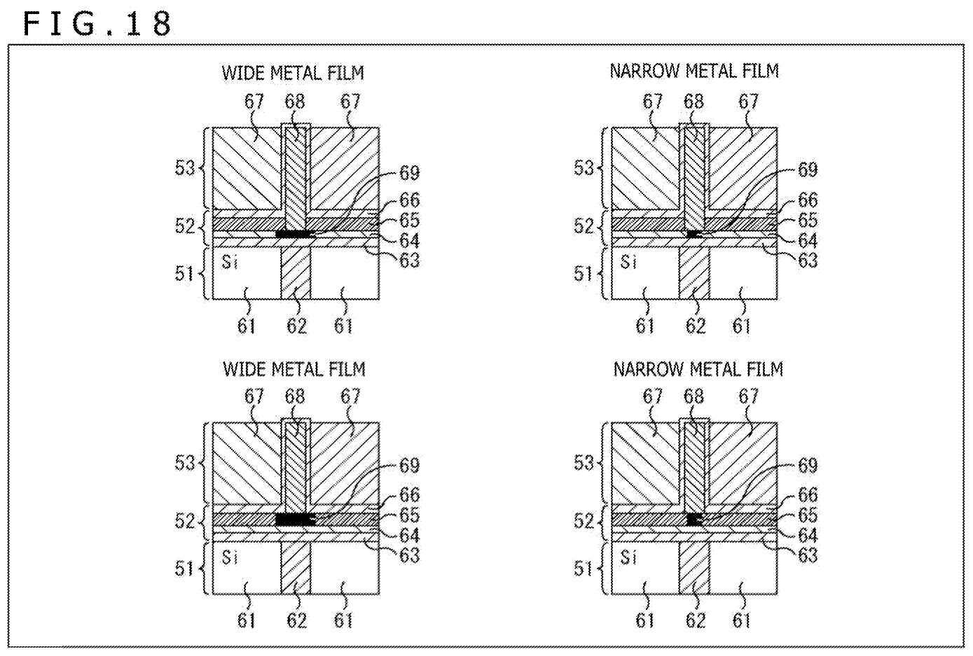

According to an example depicted in an upper left part of FIG. 18, the low refractive index wall 68 is embedded up to the oxide film 65 including SiO, and the metal film 69 having a larger width than the low refractive index wall 68 is formed immediately below the low refractive index wall 68. In other words, the metal film 69 is embedded in the oxide film 64 including HfO.

The metal film 69 here constantly has a fixed width for any correction amount of pupil correction. The horizontal width (line width) of the metal film 69 in the figure is longer (larger) than each of the width of the low refractive index wall 68 and the width of the trench 62.

The correction amount of pupil correction is 0 at the position P21. Accordingly, the metal film 69 located immediately below the low refractive index wall 68 and the trench 62 face each other. In addition, the oxide film 63 is formed between the metal film 69 and the trench 62 in this example.

In this case, the color filter 67, the low refractive index wall 68, and the metal film 69 at the position P22 are shifted toward the image height center from the trench 62 by a distance corresponding to the correction amount of the pupil correction. However, as described above, the metal film 69 constantly has the same width.

According to the example described above, the oxide film 63 is formed between the metal film 69 located immediately below the low refractive index wall 68 and the trench 62. In this case, the low refractive index wall 68 and the metal film 69 do not come into contact with the photoelectric conversion units 61 for any pupil correction. Accordingly, processing damage to the photoelectric conversion units 61 is not caused.

Moreover, according to an example depicted in an upper right part of FIG. 18, the horizontal width (line width) of the metal film 69 in the example depicted in the upper left part of FIG. 18 is shorter (smaller) than each of the width of the low refractive index wall 68 and the width of the trench 62. In this case, the metal film 69 constantly has a fixed width for any correction amount of pupil correction, as in the above-described case.

In addition, the color filter 67, the low refractive index wall 68, and the metal film 69 at the position P22 are shifted toward the image height center from the trench 62 by a distance corresponding to the correction amount of pupil correction.

According to the example described above, the low refractive index wall 68 and the metal film 69 do not come into contact with the photoelectric conversion units 61 for any pupil correction, as in the case of the upper left part of FIG. 18. Accordingly, processing damage to the photoelectric conversion units 61 is not caused.

According to an example depicted in a lower left part of FIG. 18, the low refractive index wall 68 is embedded up to the oxide film 66 including AlO, and the metal film 69 having a larger width than the low refractive index wall 68 is formed immediately below the low refractive index wall 68. In other words, the metal film 69 is embedded in the oxide film 65 including SiO.

The metal film 69 here constantly has a fixed width for any correction amount of pupil correction. The horizontal width (line width) of the metal film 69 in the figure is longer (larger) than the width of the low refractive index wall 68 and the width of the trench 62.

The correction amount of pupil correction is 0 at the position P21. Accordingly, the metal film 69 located immediately below the low refractive index wall 68 and the trench 62 face each other. Further, the oxide film 63 and the oxide film 64 are formed between the metal film 69 and the trench 62 in this example.

In this case, the color filter 67, the low refractive index wall 68, and the metal film 69 at the position P22 are shifted toward the image height center from the trench 62 by a distance corresponding to the correction amount of the pupil correction. However, as described above, the metal film 69 constantly has the same width.

According to the example described above, the oxide film 63 and the oxide film 64 are formed between the metal film 69 located immediately below the low refractive index wall 68 and the trench 62. In this case, the low refractive index wall 68 and the metal film 69 do not come into contact with the photoelectric conversion units 61 for any pupil correction. Accordingly, processing damage to the photoelectric conversion units 61 is not caused.

Moreover, according to an example depicted in a lower right part of FIG. 18, the horizontal width (line width) of the metal film 69 in the example depicted in the lower left part of FIG. 18 is shorter (smaller) than each of the width of the low refractive index wall 68 and the width of the trench 62. In this case, the metal film 69 constantly has a fixed width for any correction amount of pupil correction, as in the above-described case.

In addition, the color filter 67, the low refractive index wall 68, and the metal film 69 at the position P22 are shifted toward the image height center from the trench 62 by a distance corresponding to the correction amount of pupil correction.

According to the example described above, the low refractive index wall 68 and the metal film 69 do not come into contact with the photoelectric conversion units 61 for any pupil correction, as in the case of the lower left part of FIG. 18. Accordingly, processing damage to the photoelectric conversion units 61 is not caused.

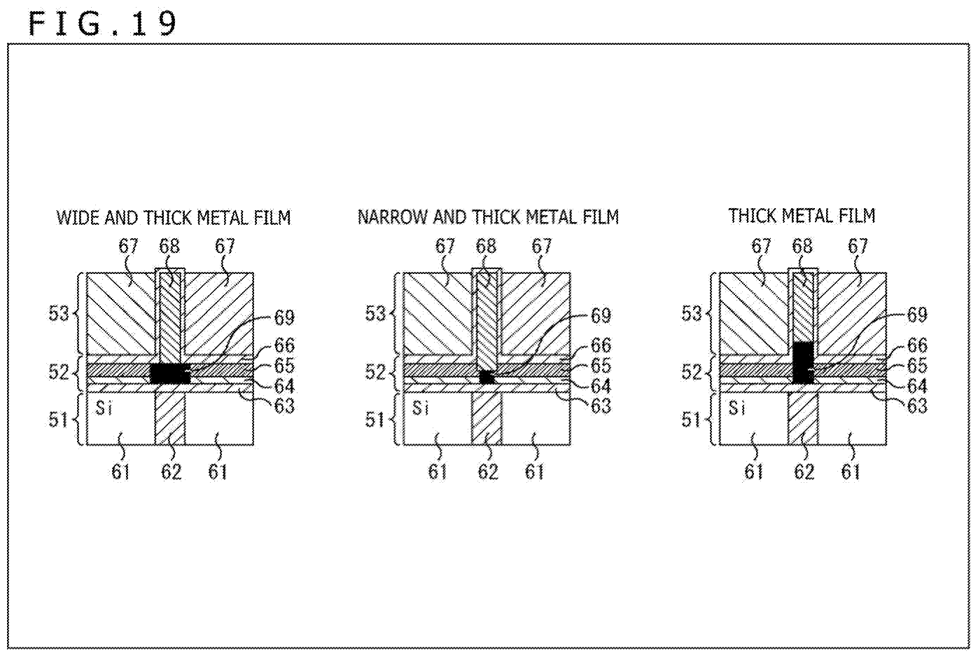

According to an example depicted in a left part of FIG. 19, the low refractive index wall 68 is embedded up to the oxide film 66 including AlO, and the metal film 69 having a larger width than the low refractive index wall 68 is formed immediately below the low refractive index wall 68. In other words, the metal film 69 is embedded in portions corresponding to the oxide film 65 including SiO and the oxide film 64 including HfO. Accordingly, this example is an example which changes only the thickness of the metal film 69 of the example depicted in the lower left part of FIG. 18.

The metal film 69 constantly has a fixed width for any correction amount of pupil correction. The horizontal width (line width) of the metal film 69 in the figure is longer (larger) than each of the width of the low refractive index wall 68 and the width of the trench 62.

The correction amount of pupil correction is 0 at the position P21. Accordingly, the metal film 69 located immediately below the low refractive index wall 68 and the trench 62 face each other. In addition, the oxide film 63 is formed between the metal film 69 and the trench 62 in this example.

In this case, the color filter 67, the low refractive index wall 68, and the metal film 69 at the position P22 are shifted toward the image height center from the trench 62 by a distance corresponding to the correction amount of the pupil correction. However, as described above, the metal film 69 constantly has the same width.

According to the example described above, the oxide film 63 is formed between the metal film 69 located immediately below the low refractive index wall 68 and the trench 62. In this case, the low refractive index wall 68 and the metal film 69 do not come into contact with the photoelectric conversion units 61 for any pupil correction. Accordingly, processing damage to the photoelectric conversion units 61 is not caused.

Moreover, according to an example depicted in a central part of FIG. 19, the thickness of the metal film 69 in the optical axis direction is larger than that width in the example depicted in the upper right part of FIG. 18.

In this example, the low refractive index wall 68 is embedded up to an intermediate position in the oxide film 65 including SiO, and the metal film 69 having a smaller line width than each of the low refractive index wall 68 and the trench 62 is formed immediately below the low refractive index wall 68. Specifically, the metal film 69 is embedded in a portion corresponding to a part of the oxide film 65 and the entire oxide film 64 in such a manner as to penetrate an area from an intermediate position in the oxide film 65 to the entire oxide film 64. In this case, the metal film 69 constantly has a fixed width for any correction amount of pupil correction, as in the above-described case.

In addition, the color filter 67, the low refractive index wall 68, and the metal film 69 at the position P22 are shifted toward the image height center from the trench 62 by a distance corresponding to the correction amount of pupil correction.

According to the respective examples described above, the low refractive index wall 68 and the metal film 69 do not come into contact with the photoelectric conversion units 61 for any pupil correction, as in the case of the upper right part of FIG. 18. Accordingly, processing damage to the photoelectric conversion units 61 is not caused.

Further, according to an example depicted in a right part of FIG. 19, the metal film 69 has a larger thickness in the optical axis direction than that thickness of the example depicted in the upper right part of FIG. 17.

In this example, the low refractive index wall 68 does not penetrate the color filter layer 53, but is embedded up to an intermediate position in the color filter layer 53. Specifically, a low refractive index material is embedded in a portion from the micro-lens layer 54 side end of the color filter layer 53 to the intermediate position in the color filter layer 53 to constitute the low refractive index wall 68.

Moreover, the metal film 69 having the same line width as the low refractive index wall 68 is formed immediately below the low refractive index wall 68. The metal film 69 is formed from an intermediate position in the color filter layer 53 to an end portion of the oxide film 64. Specifically, the metal film 69 is embedded in a part of the color filter layer 53 and a portion ranging from the oxide film 64 to the oxide film 66.

In this case, the metal film 69 constantly has a fixed width for any correction amount of pupil correction, as in the above-described case. Moreover, the color filter 67, the low refractive index wall 68, and the metal film 69 at the position P22 are shifted toward the image height center from the trench 62 by a distance corresponding to the correction amount of pupil correction.

According to the example described above, the low refractive index wall 68 and the metal film 69 do not come into contact with the photoelectric conversion units 61 for any pupil correction, as in the case of the upper right part of FIG. 17. Accordingly, processing damage to the photoelectric conversion units 61 is not caused.

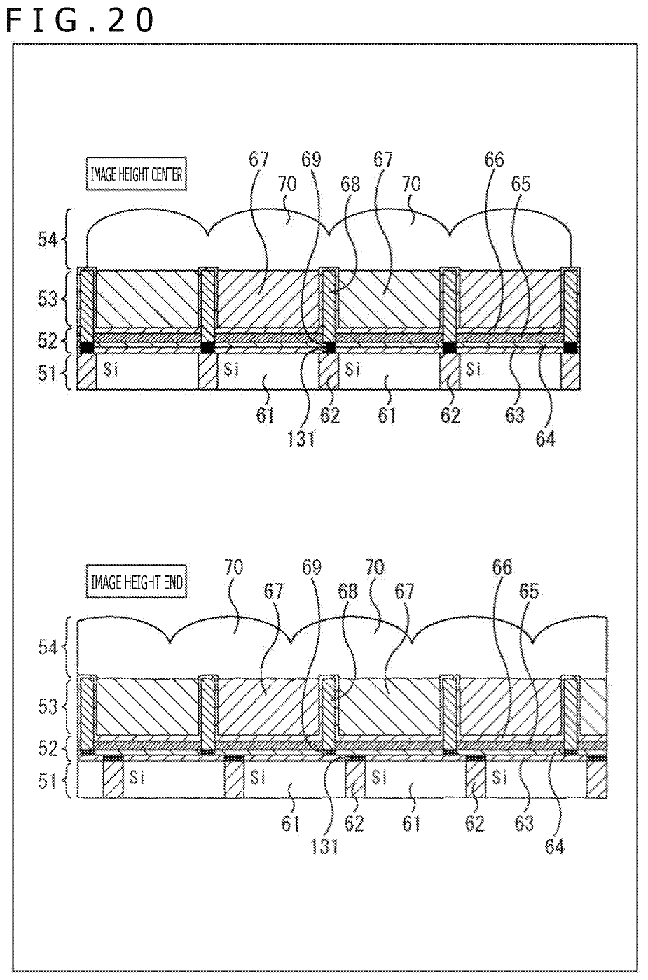

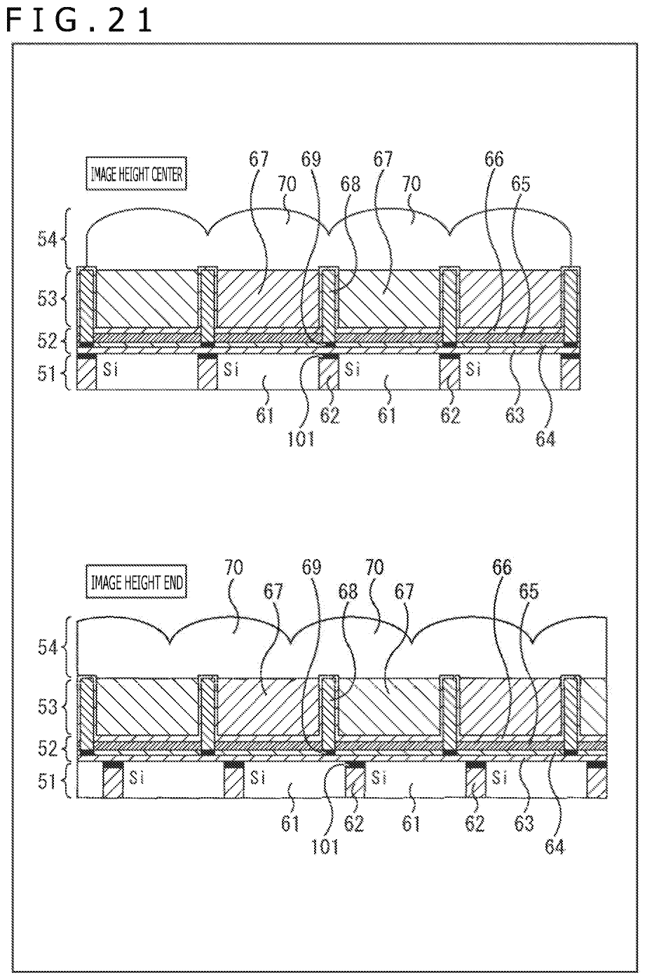

In addition, as depicted in FIGS. 20 and 21, a metal film having a light shielding function may be formed for each of a portion immediately below the low refractive index wall 68 and a portion immediately above the trench 62 even in a case where the line width of each of the metal films is fixed, for any correction amount of pupil correction.

For example, depicted in an upper part of FIG. 20 is a cross section of the portion of the pixel array unit 21 at the position P21 (image height center) as viewed in the direction perpendicular to the optical axis direction.

The correction amount of pupil correction is 0 at the position P21. Moreover, the low refractive index wall 68 is embedded up to the oxide film 65. The metal film 69 is formed immediately below the low refractive index wall 68.

Further, a metal film 131 having substantially the same width as the trench 62 is formed in a portion that is included in the oxide film 63 and that is located immediately above the trench 62. The metal film 131 and the metal film 69 are connected to each other. According to this example, therefore, the metal film 69 and the metal film 131 are formed between the low refractive index wall 68 and the trench 62.

For example, similarly to the metal film 69, the metal film 131 includes such metal as Ti, W, Cu, or Al, or an oxide film including any one of these metals.

In addition, depicted in a lower part of the figure is a cross section of the portion of the pixel array unit 21 at the position P22 (image height end side) as viewed in the direction perpendicular to the optical axis direction.

The correction amount of pupil correction is a correction amount corresponding to the image height at the position P22.

Accordingly, the on-chip lens 70, the color filter 67, the low refractive index wall 68, and the metal film 69 are shifted toward the image height center from the trench 62 by a distance corresponding to the correction amount of pupil correction. In addition, the metal film 131 is formed immediately above the trench 62.

According to this example, each of the metal film 69 and the metal film 131 constantly has a fixed width for any correction amount of pupil correction. In this case, clearances are produced between the metal film 69 located immediately below the low refractive index wall 68 and the metal film 131 located immediately above the trench 62, when pupil correction is carried out. However, the metal film 69 and the metal film 131 each having a light shielding function can achieve more reduction of color mixture than in the example depicted in FIG. 2.

The example depicted in FIG. 21 is an example where the metal film 69 of the example depicted in FIG. 15 constantly has a fixed line width.

Depicted in an upper part of FIG. 21 is a cross section of the portion of the pixel array unit 21 at the position P21 (image height center) as viewed in the direction perpendicular to the optical axis direction. In this case, the pixel array unit 21 has the same cross section as the cross section depicted in the upper part of FIG. 15.

Specifically, the correction amount of the pupil correction is 0 at the position P21. Moreover, the low refractive index wall 68 is embedded up to the oxide film 65. The metal film 69 is formed immediately below the low refractive index wall 68. In addition, the metal film 101 is formed immediately above the trench 62 within the photoelectric conversion layer 51.

Particularly in this example, each of the metal film 69 and the metal film 101 each functioning as a light shielding film constantly has a fixed width for any correction amount of pupil correction. For example, line width of the metal film 69 is the same as the width of the low refractive index wall 68, while line width of the metal film 101 is the same as the width of the trench 62.

In addition, depicted in a lower part of the figure is a cross section of the portion of the pixel array unit 21 at the position P22 (image height end side) as viewed in the direction perpendicular to the optical axis direction.

The correction amount of pupil correction is a correction amount corresponding to the image height at the position P22.

Accordingly, the on-chip lens 70, the color filter 67, the low refractive index wall 68, and the metal film 69 are shifted toward the image height center from the trench 62 by a distance corresponding to the correction amount of pupil correction. In addition, the metal film 101 is formed immediately above the trench 62.

As described above, each of the metal film 69 and the metal film 101 constantly has a fixed width for any correction amount of pupil correction. In this case, clearances are produced between the metal film 69 located immediately below the low refractive index wall 68 and the metal film 101 located immediately above the trench 62 when pupil correction is carried out. However, because the metal film 69 and the metal film 101 each having a light shielding function are provided, more reduction of color mixture than in the case depicted in FIG. 2 is achievable.

According to the foregoing respective examples depicted in FIGS. 20 and 21, the oxide film 63 is always present immediately above the photoelectric conversion units 61 even at the time of execution of pupil correction. In this case, the low refractive index wall 68 and the metal film 69 do not come into contact with the photoelectric conversion units 61. Accordingly, processing damage is not caused.

### Second Embodiment

### Different Configuration Example of Pixel Array Unit

Meanwhile, the pixel array unit 21 of a certain configuration includes not only ordinary pixels used for capturing images (hereinafter also referred to as imaging pixels), but also pixels used for purposes different from the purpose of the imaging pixels, such as distance measuring pixels which are pixels used for measuring distances for AF (Autofocus).

If the configuration depicted in FIG. 2 is adopted even for a case of the pixel array unit including a mixture of the imaging pixels and the distance measuring pixels, for example, processing damage is caused by execution of pupil correction. In this case, deterioration of sensor characteristics such as an increase in dark current is caused.

Accordingly, in a second embodiment of the present technology, the low refractive index wall is embedded up to an intermediate position in the oxide film layer, as in the case of the first embodiment. In this manner, sensor characteristics are allowed to improve without processing damage being caused, even in the case where the pixel array unit 21 has a mixture of a plurality of imaging pixels and distance measuring pixels.

Described hereinafter will be an example where the pixel array unit 21 includes a mixture of a plurality of imaging pixels and pixels for image plane phase-difference detection AF (hereinafter also referred to as ZAF pixels) as distance measuring pixels, i.e., an example where ZAF pixels are included in a plurality of pixels provided on the pixel array unit 21.

The pixel array unit 21 includes the low refractive index wall 68 described above, which is formed between the imaging pixels adjacent to each other and between the imaging pixels and the ZAF pixels in the color filter layer 53 and the oxide film layer 52 to reduce color mixture and lowering of pixel sensitivity. Accordingly, pupil correction is not performed in this embodiment.

Particularly, the low refractive index wall 68 penetrates the entire color filter layer 53, and is embedded up to an intermediate position in the oxide film layer 52 to constitute such a structure where the low refractive index wall 68 does not come into contact with the photoelectric conversion layer 51 (photoelectric conversion units 61). In this manner, deterioration of sensor characteristics caused by processing damage is avoided.

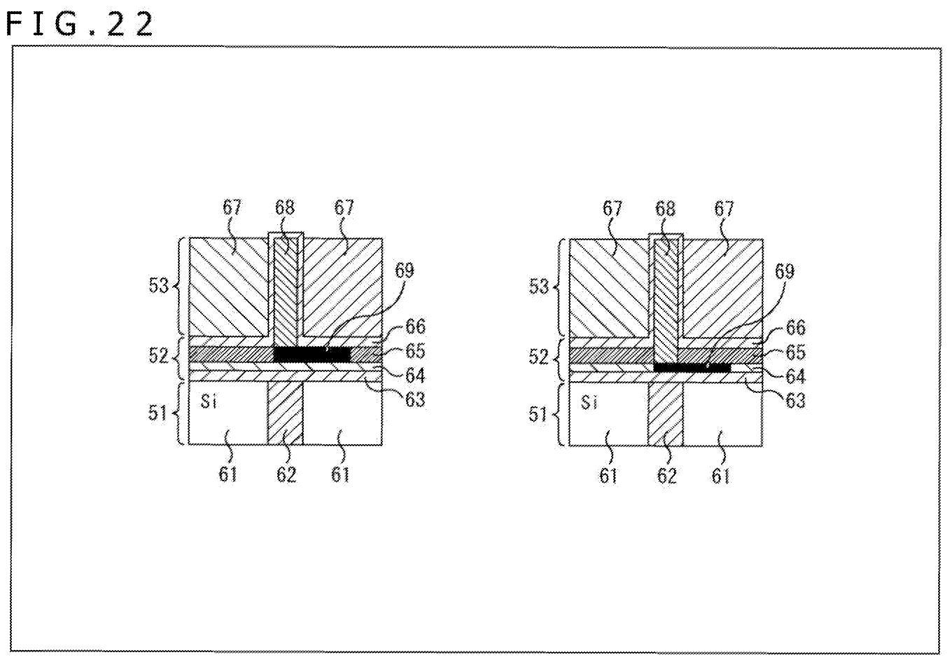

Specifically, each of portions between the imaging pixels and the ZAF pixels in the pixel array unit 21 has any one of configurations depicted in FIGS. 22 to 25, for example. Note that parts in FIGS. 22 to 25 identical to the corresponding parts in FIG. 5 are given identical reference signs, and the same explanation of these parts will not be repeated where appropriate.

Each of FIGS. 22 to 25 depicts an enlarged part of the photoelectric conversion layer 51, the oxide film layer 52, and the color filter layer 53 in a cross section of the pixel array unit 21 as viewed in the direction perpendicular to the optical axis direction.

According to an example depicted in a left part of FIG. 22, the low refractive index wall 68 penetrates the entire color filter layer 53, and reaches an end position of the oxide film 66 in the oxide film layer 52. Accordingly, the low refractive index wall 68 is embedded in a portion corresponding to the oxide film 66 in the oxide film layer 52.

In this example, a left region with respect to the low refractive index wall 68 in the figure corresponds to a region of the imaging pixel, while a right region with respect to the low refractive index wall 68 corresponds to a region of the ZAF pixel. In other words, the region of the imaging pixel and the region of the ZAF pixel are separated from each other by the low refractive index wall 68 and the trench 62.

Moreover, the metal film 69 functioning as a light shielding film is embedded (formed) in a portion included in the oxide film 65 including SiO and is located immediately below the low refractive index wall 68 in the oxide film layer 52. For example, the metal film 69 includes such metal as Ti, W, Cu, or Al, or an oxide film including any one of these metals.

Particularly in this example, the metal film 69 protrudes (projects) toward the ZAF pixel side (to the inside of the ZAF pixel). A portion corresponding to the metal film 69 within the ZAF pixel also functions as a light shielding film of the ZAF pixel for shielding light entering the photoelectric conversion unit 61 within the ZAF pixel from the outside.

Specifically, for example, a half of a region (photoelectric conversion unit 61) of the ZAF pixel is covered with the metal film 69 as viewed in the optical axis direction. This configuration allows the corresponding pixel to function as a ZAF pixel.

A left end position of the metal film 69 in the figure is aligned with a left end position of the low refractive index wall 68 in the figure, i.e., a position of the imaging pixel side end of the low refractive index wall 68, as viewed in the direction perpendicular to the optical axis direction. Accordingly, the metal film 69 is not projected into the imaging pixel.

Meanwhile, a right end position of the metal film 69 in the figure is projected toward the ZAF pixel side from a right end position of the low refractive index wall 68 in the figure as viewed in the direction perpendicular to the optical axis direction. Specifically, the right end position of the metal film 69 in the figure is located at a substantially half (center) position of the region of the ZAF pixel.

Moreover, according to an example depicted in a right part of FIG. 22, the low refractive index wall 68 penetrates the entire color filter layer 53, and reaches an end position of the oxide film 65 within the oxide film layer 52. Accordingly, the low refractive index wall 68 is embedded in portions corresponding to the oxide film 65 and the oxide film 66 in the oxide film layer 52.

In this example, as in the above-described case, a left region with respect to the low refractive index wall 68 in the figure corresponds to a region of the imaging pixel, while a right region with respect to the low refractive index wall 68 corresponds to a region of the ZAF pixel.

Moreover, the metal film 69 is embedded in a portion included in the oxide film 64 including HfO and is located immediately below the low refractive index wall 68 in the oxide film layer 52.

In this example, the metal film 69 is similarly projected toward the ZAF pixel side, and a half of a region (photoelectric conversion unit 61) of the ZAF pixel is covered with the metal film 69 as viewed in the optical axis direction, for example. This configuration allows the portion of the metal film 69 to function as a light shielding film for a ZAF pixel, and hence allows the pixel to function as a ZAF pixel.

A left end position of the metal film 69 in the figure is aligned with a position of the imaging pixel side end of the low refractive index wall 68 as viewed in the direction perpendicular to the optical axis direction. Meanwhile, a right end position of the metal film 69 in the figure is projected toward the ZAF pixel side from a right end position of the low refractive index wall 68 in the figure. Specifically, the right end position of the metal film 69 in the figure is located at a substantially half (center) position of the region of the ZAF pixel.

According to the respective examples depicted in FIG. 22, the oxide film 63 is always present immediately above the photoelectric conversion units 61. In other words, an oxide film such as the oxide film 63 is formed between the metal film 69 in the oxide film layer 52 and the photoelectric conversion layer 51. In this case, the low refractive index wall 68 and the metal film 69 do not come into contact with the photoelectric conversion units 61. Accordingly, processing damage to the photoelectric conversion units 61 is not caused. Moreover, the metal film 69 is provided between the low refractive index wall 68 and the trench 62. Accordingly, formation of color mixture paths is also prevented.

As can be understood from these points, sensor characteristics are allowed to improve without processing damage being caused, even in the case of the configurations depicted in FIG. 22, as in the case of the first embodiment.

Note that the metal film 69 formed between the imaging pixels adjacent to each other and disposed immediately below the low refractive index wall 68 has the same width as the low refractive index wall 68 as viewed in the direction perpendicular to the optical axis direction in the respective examples depicted in FIG. 22.

However, because pupil correction is not performed in this example, the low refractive index wall 68 and the trench 62 are disposed at the same arrangement position in the direction perpendicular to the optical axis direction (the left-right direction in the figure), i.e., without deviation between arrangement positions of the low refractive index wall 68 and the trench 62. In this case, color mixture can be reduced. Accordingly, sensor characteristics are allowed to improve also between imaging pixels without processing damage being caused.

Moreover, in a different configuration, a part or the whole of a portion included in the low refractive index wall 68 and provided within the oxide film layer 52 may be projected to the inside of the ZAF pixel.

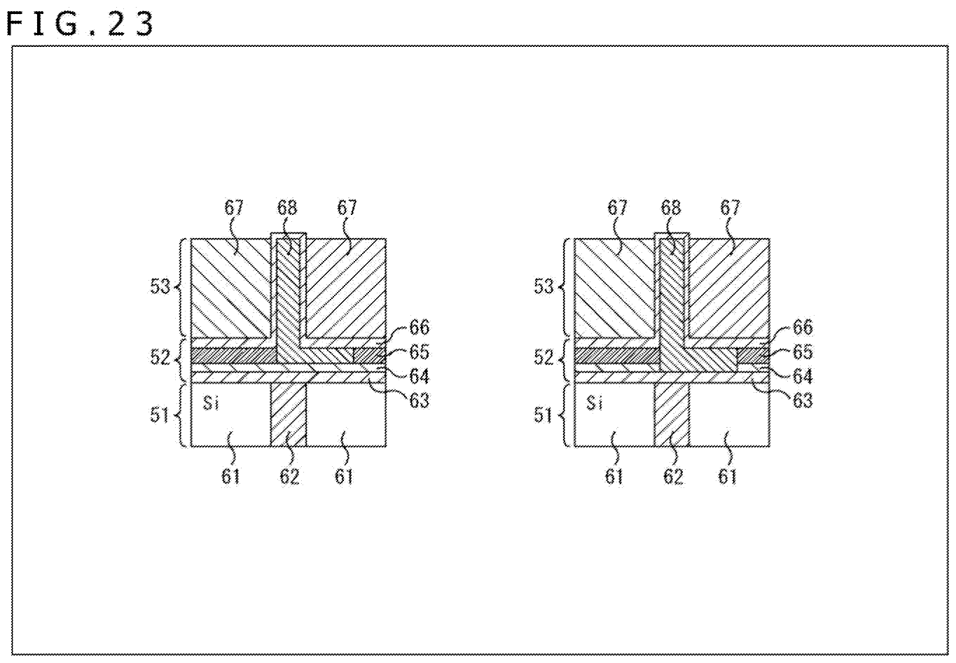

For example, according to an example depicted in a left part of FIG. 23, the low refractive index wall 68 penetrates the entire color filter layer 53, and further penetrates the oxide film 66 including AlO and the oxide film 65 including SiO within the oxide film layer 52. Accordingly, the low refractive index wall 68 is embedded in portions corresponding to the oxide film 65 and the oxide film 66 in the oxide film layer 52.

In this example, a left region with respect to the low refractive index wall 68 in the figure corresponds to a region of the imaging pixel, while a right region with respect to the low refractive index wall 68 corresponds to a region of the ZAF pixel.

Moreover, a part included in the low refractive index wall 68 and located within the oxide film layer 52, specifically, a portion corresponding to the oxide film 65, protrudes (projects) toward the ZAF pixel side, i.e., to the inside of the ZAF pixel. In this case, the low refractive index wall 68 has an L shape as a whole.

The low refractive index wall 68 has a light shielding function. Accordingly, the projected portion of the low refractive index wall 68 in the ZAF pixel functions as a light shielding film of the ZAF pixel. Specifically, for example, a half of a region (photoelectric conversion unit 61) of the ZAF pixel is covered with the low refractive index wall 68 as viewed in the optical axis direction. This configuration allows this pixel to function as a ZAF pixel.

A left end position of the low refractive index wall 68 in the figure is aligned with a left end position of the trench 62 in the figure as viewed in the direction perpendicular to the optical axis direction. Accordingly, the low refractive index wall 68 is not projected into the imaging pixel.

Meanwhile, a right end position of the low refractive index wall 68 in the figure is located closer to the ZAF pixel than a right end position of the trench 62 in the figure as viewed in the direction perpendicular to the optical axis direction. Specifically, the right end position of the low refractive index wall 68 in the figure is located at a substantially half (center) position of the region of the ZAF pixel.

In addition, an example depicted in a right part of FIG. 23 is an example of the low refractive index wall 68 having a larger thickness than that in the example depicted in the left part of FIG. 23. Other points are the same as the corresponding points of the example depicted in the left part of FIG. 23.

According to the example depicted in the right part of FIG. 23, the low refractive index wall 68 penetrates the entire color filter layer 53, and further penetrates the oxide film 66 including AlO, the oxide film 65 including SiO, and the oxide film 64 including HfO within the oxide film layer 52. Accordingly, the low refractive index wall 68 is embedded in portions corresponding to the oxide film 64 to the oxide film 66 in the oxide film layer 52.

Moreover, a portion that is included in the low refractive index wall 68 and that corresponds to the oxide film 64 and the oxide film 65 within the oxide film layer 52 is projected toward the ZAF pixel. In this case, the low refractive index wall 68 has an L shape as a whole.

Particularly, for example, a half of a region (photoelectric conversion unit 61) of the ZAF pixel is covered with the low refractive index wall 68 as viewed in the optical axis direction. This configuration allows the portion of the low refractive index wall 68 to also function as a light shielding film for a ZAF pixel, and hence allows the pixel to function as a ZAF pixel.

A left end position of the low refractive index wall 68 in the figure is aligned with a left end position of the trench 62 in the figure as viewed in the direction perpendicular to the optical axis direction. Meanwhile, a right end position of the low refractive index wall 68 in the figure is located closer to the ZAF pixel than a right end position of the trench 62 in the figure as viewed in the direction perpendicular to the optical axis direction. Specifically, the right end position of the low refractive index wall 68 in the figure is located at a substantially half (center) position of the region of the ZAF pixel.

According to the respective examples depicted in FIG. 23, the oxide film 63 is always present immediately above the photoelectric conversion units 61 as in the above-described case. In this case, the low refractive index wall 68 does not come into contact with the photoelectric conversion units 61. Accordingly, processing damage to the photoelectric conversion units 61 is not caused. Moreover, the low refractive index wall 68 is disposed above the entire trench 62 in the figure. Accordingly, color mixture paths are not formed. As can be understood from these points, sensor characteristics are allowed to improve without processing damage being caused, even in the case of the configurations depicted in FIG. 23, as in the case of the first embodiment.

Note that the low refractive index wall 68 formed between the imaging pixels adjacent to each other has substantially the same width as the trench 62 as viewed in the direction perpendicular to the optical axis direction in the respective examples depicted in FIG. 23.

Because pupil correction is not performed in this example, the low refractive index wall 68 and the trench 62 are disposed at the same arrangement position in the direction perpendicular to the optical axis direction (the left-right direction in the figure). Accordingly, reduction of color mixture is achievable. Sensor characteristics are thus allowed to improve also between imaging pixels without processing damage being caused.

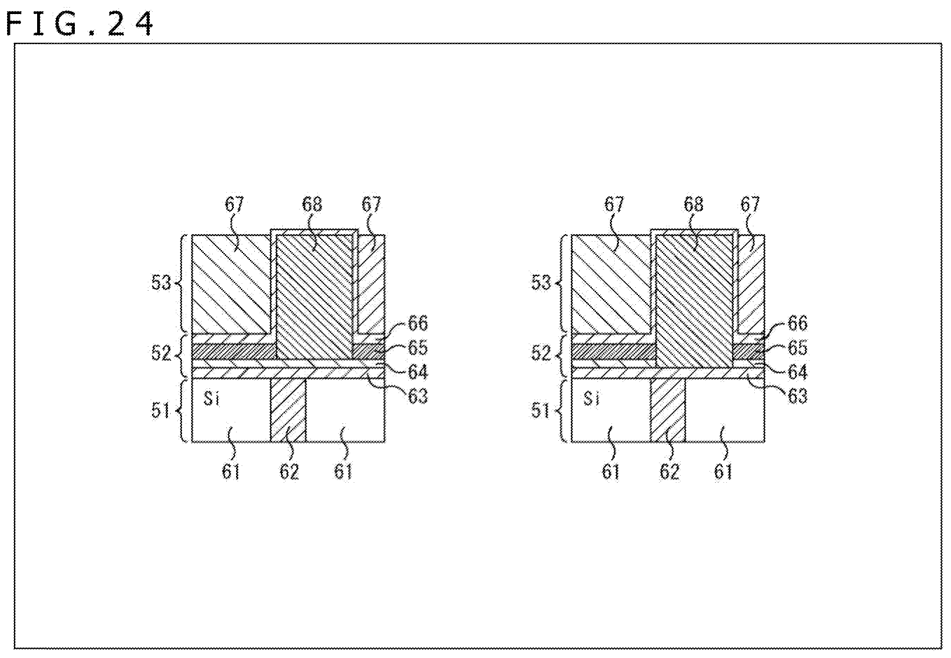

According to an example depicted in a left part of FIG. 24, the low refractive index wall 68 penetrates the entire color filter layer 53, and further penetrates the oxide film 66 including AlO and the oxide film 65 including SiO within the oxide film layer 52. Accordingly, the low refractive index wall 68 is embedded in portions corresponding to the oxide film 65 and the oxide film 66 in the oxide film layer 52.

In this example, a left region with respect to the trench 62 in the figure corresponds to a region of the imaging pixel, while a right region with respect to the trench 62 corresponds to a region of the ZAF pixel.

Moreover, the entire low refractive index wall 68 formed between the color filter layer 53 and the oxide film layer 52 projects toward the ZAF pixel (to the inside of the ZAF pixel) as viewed from a boundary portion between the imaging pixel and the ZAF pixel adjacent to each other.

The low refractive index wall 68 has a light shielding function. Accordingly, the projected portion of the low refractive index wall 68 in the ZAF pixel functions as a light shielding film of the ZAF pixel. Specifically, for example, a half of a region (photoelectric conversion unit 61) of the ZAF pixel is covered with the low refractive index wall 68 as viewed in the optical axis direction. This configuration allows the corresponding pixel to function as a ZAF pixel.

A left end position of the low refractive index wall 68 in the figure is aligned with a left end position of the trench 62 in the figure as viewed in the direction perpendicular to the optical axis direction. Accordingly, the low refractive index wall 68 is not projected into the imaging pixel.

Meanwhile, a right end position of the low refractive index wall 68 in the figure is located closer to the ZAF pixel than a right end position of the trench 62 in the figure as viewed in the direction perpendicular to the optical axis direction. Specifically, the right end position of the low refractive index wall 68 in the figure is located at a substantially half (center) position of the region of the ZAF pixel.

In addition, an example depicted in a right part of FIG. 24 is an example of the low refractive index wall 68 having a larger thickness than that in the example depicted in the left part of FIG. 24. Other points are the same as the corresponding points of the example depicted in the left part of FIG. 24.

According to the example depicted in the right part of FIG. 24, the low refractive index wall 68 penetrates the entire color filter layer 53, and further penetrates the oxide film 66 including AlO, the oxide film 65 including SiO, and the oxide film 64 including HfO within the oxide film layer 52. Accordingly, the low refractive index wall 68 is embedded in portions corresponding to the oxide film 64 to the oxide film 66 in the oxide film layer 52.

According to the respective examples depicted in FIG. 24, processing required for forming the low refractive index wall 68 is performed only once. In this case, the low refractive index wall 68 can be formed more easily than in the examples depicted in FIG. 23. In other words, the pixel array unit 21 can be completed by a smaller number of steps.

According to the foregoing respective examples depicted FIG. 24, the oxide film 63 is always present immediately above the photoelectric conversion units 61, as in the above-described case. In this case, the low refractive index wall 68 does not come into contact with the photoelectric conversion units 61. Accordingly, processing damage to the photoelectric conversion units 61 is not caused. Moreover, the low refractive index wall 68 is disposed above the entire trench 62 in the figure. Accordingly, color mixture paths are not formed. As can be understood from these points, sensor characteristics are allowed to improve without processing damage being caused, even in the case of the configurations depicted in FIG. 24, as in the case of the first embodiment.

Note that the low refractive index wall 68 provided between the imaging pixels and the ZAF pixels in the respective examples depicted in FIG. 24 has a longer (larger) width than the low refractive index wall 68 provided between the imaging pixels. Particularly, the low refractive index wall 68 formed between the imaging pixels adjacent to each other has the same width as the trench 62 as viewed in the direction perpendicular to the optical axis direction.

Because pupil correction is not performed in this example, the low refractive index wall 68 and the trench 62 are disposed at the same arrangement position in the direction perpendicular to the optical axis direction (the left-right direction in the figure). Accordingly, reduction of color mixture is achievable. Sensor characteristics are thus allowed to improve also between imaging pixels without processing damage being caused.

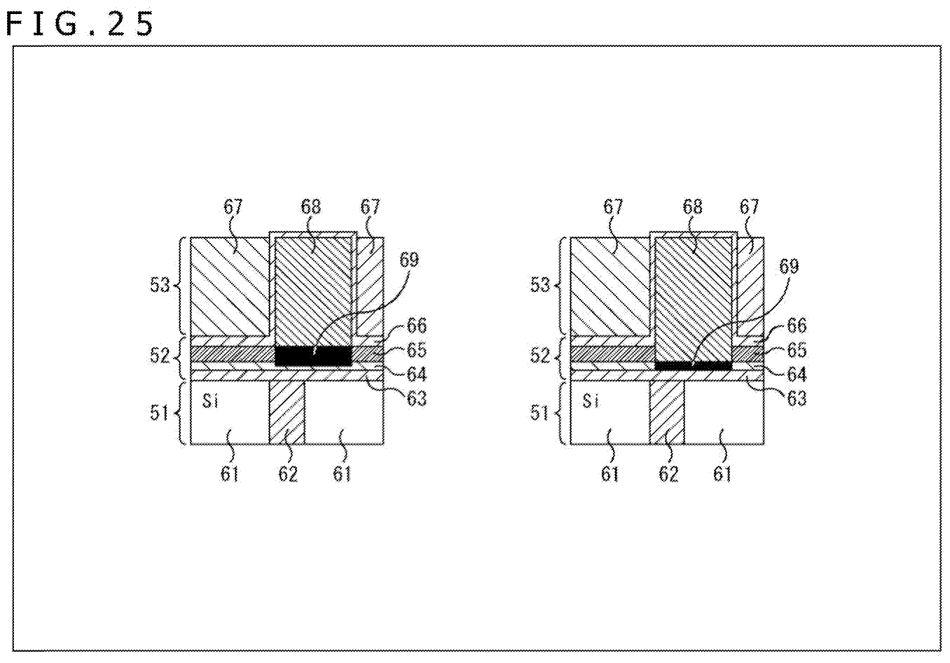

FIG. 25 depicts examples of the metal film 69 formed immediately below the low refractive index wall 68 in a case where the entire low refractive index wall 68 is projected toward the ZAF pixel as viewed from a boundary portion between the imaging pixel and the ZAF pixel adjacent to each other, to function as a light shielding film for the ZAF pixel, as in the case depicted in FIG. 24.

In addition, in the respective examples depicted in FIG. 25, a left region with respect to the trench 62 in the figure corresponds to a region of the imaging pixel, while a right region with respect to the trench 62 corresponds to a region of the ZAF pixel.

According to the example depicted in a left part of FIG. 25, the low refractive index wall 68 penetrates the entire color filter layer 53, and further penetrates the oxide film 66 including AlO within the oxide film layer 52. Accordingly, the low refractive index wall 68 is embedded in a portion corresponding to the oxide film 66 in the oxide film layer 52.

The metal film 69 having the same width as the low refractive index wall 68 is formed immediately below the low refractive index wall 68. The left and right ends of the low refractive index wall 68 are aligned with the left and right ends of the metal film 69 in the figure, respectively. Moreover, the metal film 69 is embedded in the entire oxide film 65 and a part of the oxide film 64 in the oxide film layer 52.

According to the example depicted in a right part of FIG. 25, the low refractive index wall 68 penetrates the entire color filter layer 53, and further penetrates the oxide film 66 including AlO and the oxide film 65 including SiO within the oxide film layer 52. Accordingly, the low refractive index wall 68 is embedded in portions corresponding to the oxide film 66 and the oxide film 65 in the oxide film layer 52.

The metal film 69 having the same width as the low refractive index wall 68 is formed immediately below the low refractive index wall 68. The left and right ends of the low refractive index wall 68 are aligned with the left and right ends of the metal film 69 in the figure, respectively. Moreover, the metal film 69 is embedded in a portion corresponding to the oxide film 64 in the oxide film layer 52.

According to the respective examples depicted in FIG. 25, processing required for forming the low refractive index wall 68 is performed only once, as in the examples depicted in FIG. 24. Accordingly, the low refractive index wall 68 can be formed more easily.

The oxide film 63 is always present immediately above the photoelectric conversion units 61, and thus the low refractive index wall 68 and the metal film 69 do not come into contact with the photoelectric conversion units 61. In this case, processing damage to the photoelectric conversion units 61 is not caused. Moreover, the metal film 69 is provided between the low refractive index wall 68 and the trench 62. Accordingly, formation of color mixture paths is also prevented. As can be understood from these points, sensor characteristics are allowed to improve without processing damage being caused, even in the case of the configurations depicted in FIG. 25, as in the case of the first embodiment.

Note that each of the low refractive index wall 68 and the metal film 69 formed between the imaging pixels adjacent to each other has the same width as the trench 62 as viewed in the direction perpendicular to the optical axis direction in the respective examples depicted in FIG. 25.

Because pupil correction is not performed in this example, the low refractive index wall 68, the metal film 69, and the trench 62 are disposed at the same arrangement position in the direction perpendicular to the optical axis direction (the left-right direction in the figure). Accordingly, reduction of color mixture is achievable. Sensor characteristics are thus allowed to improve also between imaging pixels without processing damage being caused.

Note that each length of the projecting portions of the metal film 69 and the low refractive index wall 68 in the ZAF pixel in the respective examples described with reference to FIGS. 22 to 25 may be varied according to a distance (image height) from the center position of the pixel array unit 21 to the ZAF pixel, i.e., a position of the ZAF pixel in the pixel array unit 21.

Meanwhile, in the respective examples described with reference to FIGS. 22 to 25, pupil correction is not performed. Accordingly, an incident light amount (pixel sensitivity) of each of the ZAF pixels varies according to the distance between the position of the ZAF pixel and the center position (image height center) of the pixel array unit 21, i.e., the image height.

Particularly, pixel sensitivity of each of the ZAF pixels lowers with farness from the center position of the pixel array unit 21, i.e., with nearness to the image height end side.

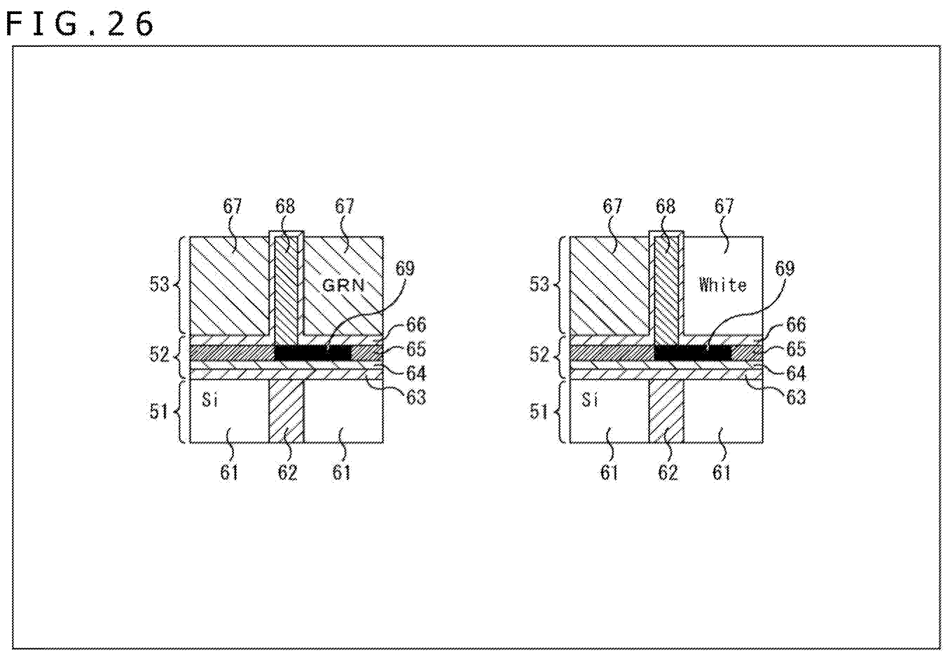

Accordingly, as depicted in FIGS. 26 to 28, for example, the color of the color filter 67 provided on each of the ZAF pixels, i.e., the type of the color filter 67, may be changed according to the position (image height) of the ZAF pixel in the pixel array unit 21.

In this manner, lowering of pixel sensitivity of the ZAF pixels can be reduced. In other words, sensor characteristics are allowed to improve without pupil correction being performed.

Note that parts in FIGS. 26 to 28 identical to the corresponding parts in FIG. 5 are given identical reference signs, and the same explanation of these parts will not be repeated where appropriate.

Each of FIGS. 26 to 28 depicts an enlarged part of the photoelectric conversion layer 51, the oxide film layer 52, and the color filter layer 53 in a cross section of the pixel array unit 21 as viewed in the direction perpendicular to the optical axis direction. Particularly, the configuration between the pixels here is identical to the configuration of the example depicted in the left part of FIG. 22. However, any one of the configurations depicted in FIGS. 22 to 25 may be adopted.

Moreover, according to the respective examples depicted in FIGS. 26 to 28, a left region with respect to the low refractive index wall 68 in the figure corresponds to a region of the imaging pixel, while a right region with respect to the low refractive index wall 68 corresponds to a region of the ZAF pixel.

Depicted in a left part of FIG. 26 is the ZAF pixel located near the center position (image height center) of the pixel array unit 21, such as the position P21 in FIG. 4. In other words, depicted in the left part of the figure is the ZAF pixel disposed within a predetermined region containing the center position of the pixel array unit 21.

The color filter 67 of G (green) is formed for this ZAF pixel, and the color filter 67 of G (green) is also formed for the imaging pixel adjacent to this ZAF pixel.

On the other hand, depicted in a right part of FIG. 26 is the ZAF pixel located near the end (image height end) of the pixel array unit 21, such as the position P22 in FIG. 4. In other words, depicted in the right part of the figure is the ZAF pixel disposed in a region outside the predetermined region containing the center position of the pixel array unit 21 (outside the predetermined region).

The color filter 67 of W (white) is formed for this ZAF pixel, while the color filter 67 of G (green) is formed for the imaging pixel adjacent to this ZAF pixel.

The color filter 67 of W (white) may include any material (member), such as the same material as that of the on-chip lenses 70, the atmosphere, and a vacuum, as long as the material has higher light transmittance than the material of the color filters 67 of other colors, such as R (red), G (green), and B (blue).

The color filter 67 of W (white) having higher transmittance than the color filters 67 of other colors is capable of introducing a larger amount of light into the photoelectric conversion unit 61, thereby improving sensitivity (pixel sensitivity) of the ZAF pixel.

As described above, the ZAF pixels each including the color filter 67 of G (green) are provided at the image height center, while the ZAF pixels each including the color filter 67 of W (white) having higher transmittance than that of G (green) are provided on the image height end side. In this manner, lowering of pixel sensitivity on the image height end side can be reduced. In other words, sensor characteristics are allowed to improve without pupil correction being performed.

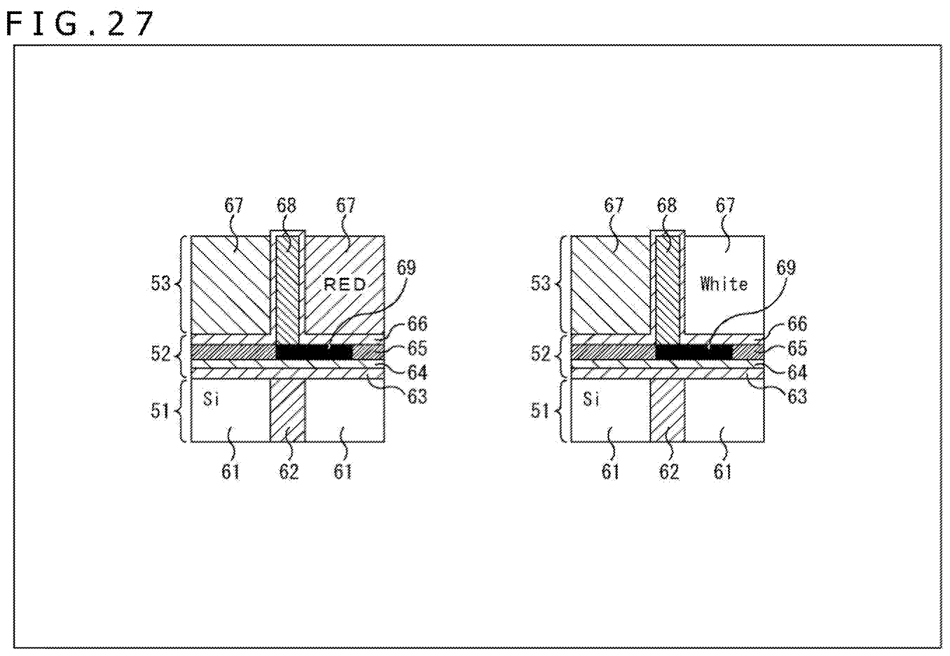

Depicted in a left part of FIG. 27 is the ZAF pixel located near the image height center of the pixel array unit 21, such as the position P21 in FIG. 4. The color filter 67 of R (red) is formed for this ZAF pixel, while the color filter 67 of G (green) is formed for the imaging pixel adjacent to this ZAF pixel.

On the other hand, depicted in a right part of FIG. 27 is the ZAF pixel located near the end (image height end) of the pixel array unit 21, such as the position P22 in FIG. 4. The color filter 67 of W (white) is formed for this ZAF pixel, while the color filter 67 of G (green) is formed for the imaging pixel adjacent to this ZAF pixel.

The color filter 67 of W (white) has higher light transmittance than the color filter 67 of R (red). Accordingly, lowering of pixel sensitivity on the image height end side can be reduced in this example, as in the example depicted in FIG. 26.

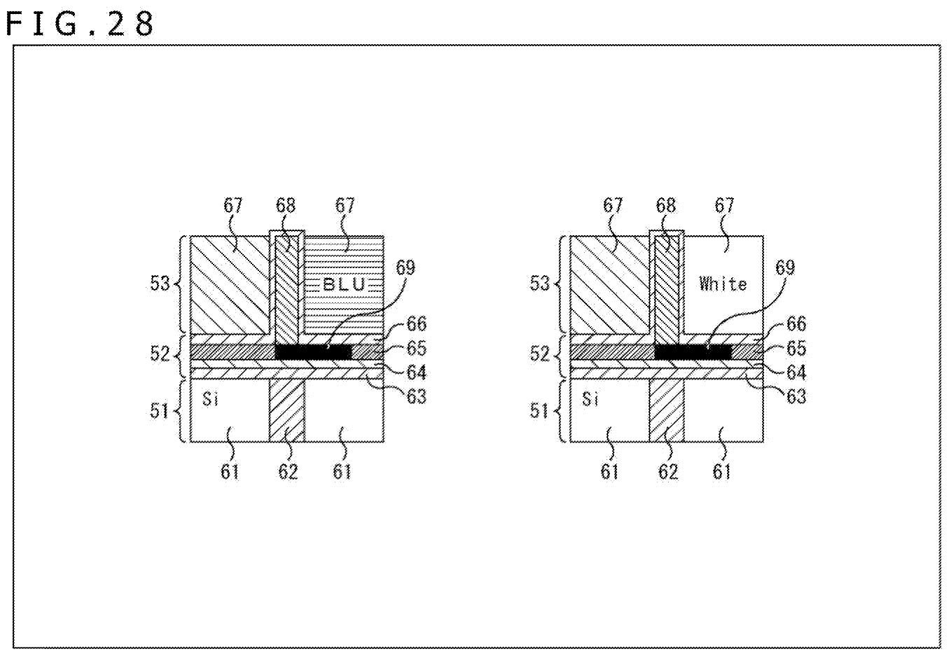

Depicted in a left part of FIG. 28 is the ZAF pixel located near the image height center of the pixel array unit 21, such as the position P21 in FIG. 4. The color filter 67 of B (blue) is formed for this ZAF pixel, while the color filter 67 of G (green) is formed for the imaging pixel adjacent to this ZAF pixel.

On the other hand, depicted in a right part of FIG. 28 is the ZAF pixel located near the end (image height end) of the pixel array unit 21, such as the position P22 in FIG. 4. The color filter 67 of W (white) is formed for this ZAF pixel, while the color filter 67 of G (green) is formed for the imaging pixel adjacent to this ZAF pixel.

The color filter 67 of W (white) has higher light transmittance than the color filter 67 of B (blue). Accordingly, lowering of pixel sensitivity on the image height end side can be reduced in this example, as in the examples depicted in FIG. 26.

Note that which position of the color filter 67 of the ZAF pixel in the pixel array unit 21 may be designated as the position of W (white) in the respective examples depicted in FIGS. 26 to 28 is determined according to the arrangement positions (pixel positions) of the ZAF pixels, a transmittance difference between the color filters 67 of the respective colors, and the like.

For example, any one of the color filters 67 of R (red), G (green), and B (blue) may be provided for each of the ZAF pixels located at a predetermined distance (threshold) or shorter from the center position of the pixel array unit 21, and the color filter 67 of W (white) may be provided for each of the ZAF pixels located at a distance longer than the predetermined distance from the center position of the pixel array unit 21.

Moreover, for measuring distances with use of ZAF pixels, a ZAF pixel whose left half is light-shielded (hereinafter also referred to as a left-shielded ZAF pixel) and a ZAF pixel whose right half is light-shielded (hereinafter also referred to as a right-shielded ZAF pixel) are paired and used for distance measurement, for example.

In this case, the left-shielded ZAF pixel and the right-shielded ZAF pixel are disposed adjacently to each other, or the right-shielded ZAF pixel is disposed near the paired left-shielded ZAF pixel, for example, in the pixel array unit 21.

According to the pair of left-shielded ZAF pixel and right-shielded ZAF pixel described above, an incident light amount, i.e., pixel sensitivity, of each of these ZAF pixels is variable according to a distance (image height) from the center position (image height center) of the pixel array unit 21.

For example, pixel sensitivity is equalized (made uniform) between the left-shielded ZAF pixel and the right-shielded ZAF pixel at the image height center.

Moreover, for example, a left end of a light receiving surface of the pixel array unit 21 when the pixel array unit 21 is viewed in the optical axis direction will also be referred to as an image height left end, and a right end of the light receiving surface of the pixel array unit 21 when the pixel array unit 21 is viewed in the optical axis direction will also be referred to as an image height right end. In this case, a ZAF pixel whose left half, i.e., half region on the image height left end side, is shielded as viewed in the optical axis direction corresponds to the left-shielded ZAF pixel, while a ZAF pixel whose right half is shielded as viewed in the optical axis direction corresponds to the right-shielded ZAF pixel.

For example, in a pair of the ZAF pixels located near the image height left end of the pixel array unit 21, it is known that the left-shielded ZAF pixel has lower pixel sensitivity, more specifically, a lower peak value output for each incident angle of light from the ZAF pixel, than the right-shielded ZAF pixel.

Similarly, in a pair of the ZAF pixels located near the image height right end, the right-shielded ZAF pixel has lower pixel sensitivity than the left-shielded ZAF pixel.

Accordingly, for example, the color filter 67 of W (white) having higher transmittance may be provided for the left-shielded ZAF pixel in the region near the image height left end of the pixel array unit 21, and the color filter 67 of W (white) having higher transmittance may be provided for the right-shielded ZAF pixel in the region near the image height right end.

In other words, for a region located out of a predetermined region (outside the predetermined region) containing the center position of the pixel array unit 21, the color filters 67 of types (colors) different for each may be provided for the left-shielded ZAF pixel and the right-shielded ZAF pixel.

In such a manner, sufficient levels of a sensitivity ratio (pixel sensitivity) and a separation ratio, i.e., a slope of output from the ZAF pixels for each incident angle, of the ZAF pixels can be obtained even in the regions near the image height left end and the image height right end. Accordingly, improvement of sensor characteristics is achievable without pupil correction being performed.

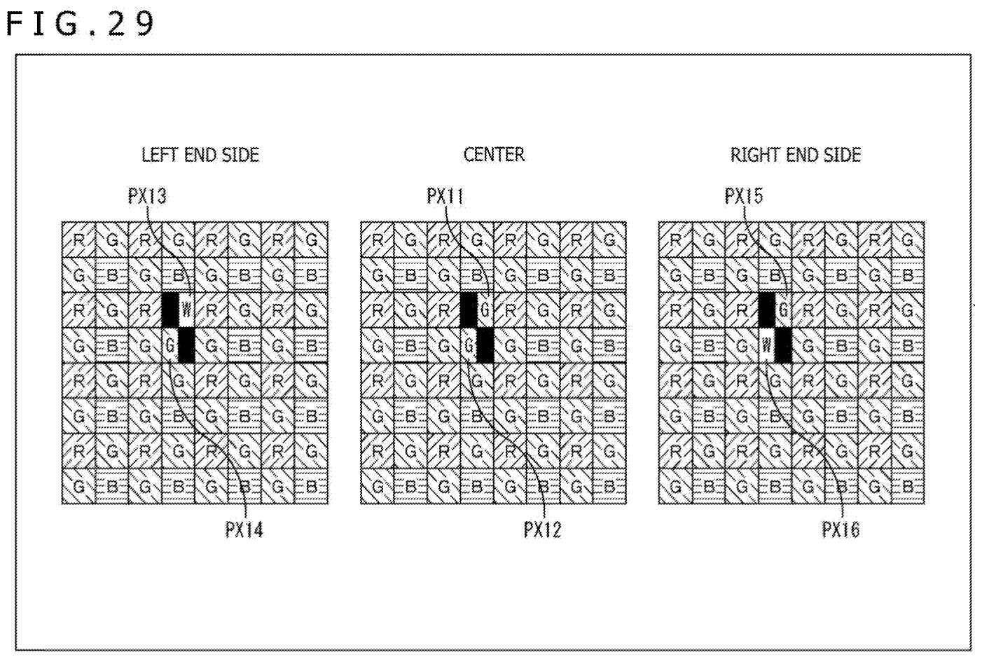

In a case where a color filter 67 of W (white) is designated as the color filter 67 of the ZAF pixel having lower sensitivity in the paired ZAF pixels according to the image height as described above, the colors (types) of the color filters 67 of the ZAF pixels are selectable in manners depicted in FIGS. 29 to 31, for example.

Note that each of FIGS. 29 to 31 is a diagram of a part of the pixel array unit 21 as viewed in the optical axis direction.

Particularly in FIGS. 29 to 31, a region near the center position of the pixel array unit 21 is depicted at a central part of the figure, a region near the image height left end, i.e., near the left end of the pixel array unit 21, is depicted in a left part of the figure, and a region near the image height right end is depicted in a right part of the figure.

In other words, in FIGS. 29 to 31, a predetermined region containing the center position of the pixel array unit 21 is depicted in the central part of the figure, a region located on the left side (image height left end side) with respect to the predetermined region is depicted in the left part of the figure, and a region located on the right side (image height right end side) with respect to the predetermined region is depicted in the right part of the figure.

In addition, in FIGS. 29 to 31, each of squares represents one pixel, and each of characters “R,” “G,” “B,” and “W” indicated inside these pixels represents a color (type) of the color filter 67 provided in the pixel.

For example, according to the example depicted in a central part of FIG. 29, a left-shielded ZAF pixel PX11 and a right-shielded ZAF pixel PX12 adjacent to each other are provided as paired ZAF pixels in a region near the center position (image height center) of the pixel array unit 21.

Sufficient sensitivity is obtainable near the image height center regardless of the position where a light shielding film of the ZAF pixel is formed. Accordingly, the color filter 67 of G (green) is formed for each of the left-shielded ZAF pixel PX11 and the right-shielded ZAF pixel PX12.

Moreover, as depicted in a left part of the figure, a left-shielded ZAF pixel PX13 and a right-shielded ZAF pixel PX14 adjacent to each other are provided as paired ZAF pixels in a region near the image height left end of the pixel array unit 21.

In this example, the color filter 67 of G (green) is provided for the right-shielded ZAF pixel PX14, while the color filter 67 of W (white) is provided for the left-shielded ZAF pixel PX13.

This configuration is adopted because the right-shielded ZAF pixel PX14 near the image height left end can obtain sufficient sensitivity even as a filter of G (green), as in the case of the image height center. In contrast, the left-shielded ZAF pixel PX13 does not have sufficient sensitivity if the color of the color filter 67 is G (green). Accordingly, the color filter 67 of W (white) having higher transmittance is provided for the left-shielded ZAF pixel PX13.

In such a manner, sensitivity of the left-shielded ZAF pixel PX13 can be more raised than in a case where the color filter 67 of G (green) is provided for the left-shielded ZAF pixel PX13. In this case, a sensitivity difference between the pair of the left-shielded ZAF pixel PX13 and the right-shielded ZAF pixel PX14 can also be reduced.

Similarly, as depicted in a right part of the figure, a left-shielded ZAF pixel PX15 and a right-shielded ZAF pixel PX16 adjacent to each other are provided as paired ZAF pixels in a region near the image height right end of the pixel array unit 21. In addition, the color filter 67 of G (green) is provided for the left-shielded ZAF pixel PX15, while the color filter 67 of W (white) is provided for the right-shielded ZAF pixel PX16. In such a manner, sensitivity of the right-shielded ZAF pixel PX16 is allowed to improve.

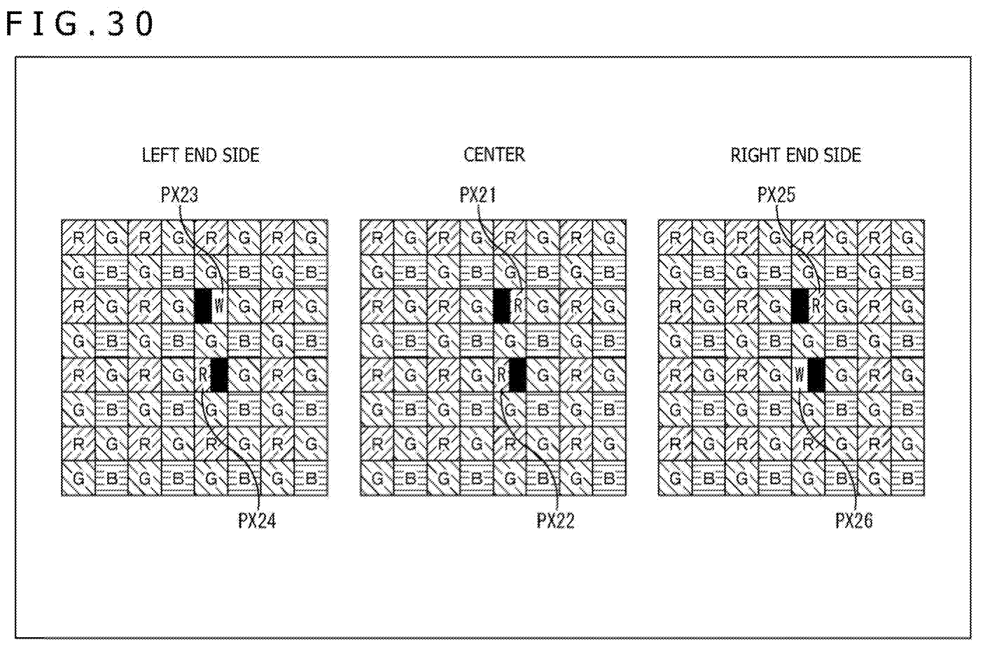

Moreover, according to the example depicted in a central part of FIG. 30, a left-shielded ZAF pixel PX21 and a right-shielded ZAF pixel PX22 are provided as paired ZAF pixels in a region near the center position (image height center) of the pixel array unit 21.

Sufficient sensitivity is obtainable near the image height center regardless of a position where a light shielding film of the ZAF pixel is formed. Accordingly, the color filter 67 of R (red) is formed for each of the left-shielded ZAF pixel PX21 and the right-shielded ZAF pixel PX22.

Moreover, as depicted in a left part of the figure, a left-shielded ZAF pixel PX23 and a right-shielded ZAF pixel PX24 are provided as paired ZAF pixels in a region near the image height left end of the pixel array unit 21.

The color filter 67 of W (white) is provided for the left-shielded ZAF pixel PX23, while the color filter 67 of R (red) is provided for the right-shielded ZAF pixel PX24. In such a manner, as in the example depicted in FIG. 29, lowering of sensitivity of the left-shielded ZAF pixel PX23 near the image height left end can be reduced by the color filter 67 of W (white) having high transmittance.

Similarly, as depicted in a right part of the figure, a left-shielded ZAF pixel PX25 and a right-shielded ZAF pixel PX26 are provided as paired ZAF pixels in a region near the image height right end of the pixel array unit 21. In addition, the color filter 67 of R (red) is provided for the left-shielded ZAF pixel PX25, while the color filter 67 of W (white) is provided for the right-shielded ZAF pixel PX26. In such a manner, sensitivity of the right-shielded ZAF pixel PX26 is allowed to improve.

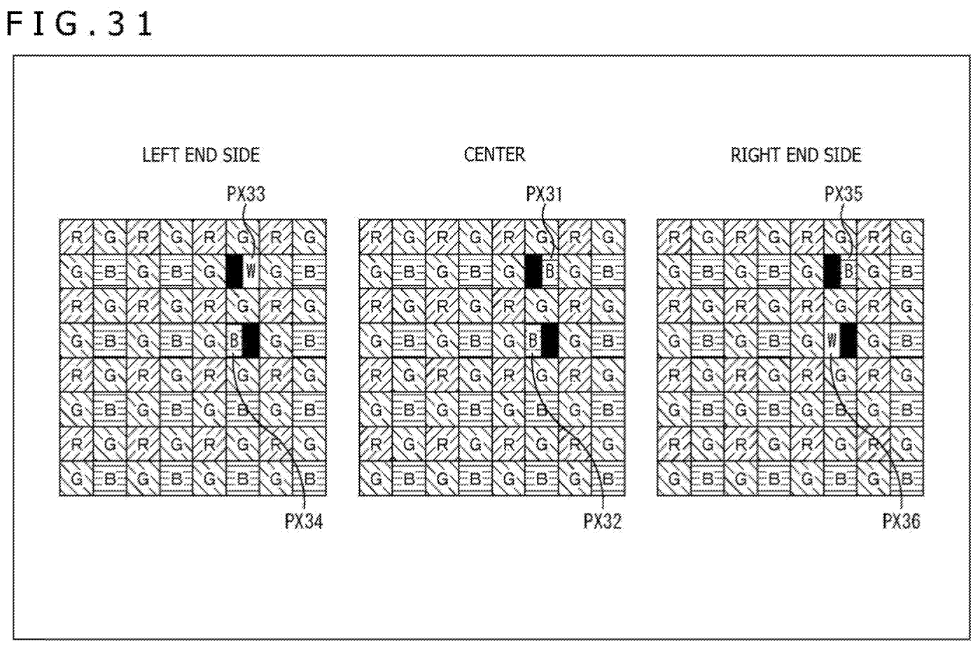

Further, according to the example depicted in a central part of FIG. 31, a left-shielded ZAF pixel PX31 and a right-shielded ZAF pixel PX32 are provided as paired ZAF pixels in a region near the center position (image height center) of the pixel array unit 21.

Sufficient sensitivity is obtainable near the image height center regardless of the position where a light shielding film of the ZAF pixel is formed. Accordingly, the color filter 67 of B (blue) is formed for each of the left-shielded ZAF pixel PX31 and the right-shielded ZAF pixel PX32.

Moreover, as depicted in a left part of the figure, a left-shielded ZAF pixel PX33 and a right-shielded ZAF pixel PX34 are provided as paired ZAF pixels in a region near the image height left end of the pixel array unit 21.

The color filter 67 of W (white) is provided for the left-shielded ZAF pixel PX33, while the color filter 67 of B (blue) is provided for the right-shielded ZAF pixel PX34. In such a manner, as in the example depicted in FIG. 29, lowering of sensitivity of the left-shielded ZAF pixel PX33 near the image height left end can be reduced by the color filter 67 of W (white) having high transmittance.

Similarly, as depicted in a right part of the figure, a left-shielded ZAF pixel PX35 and a right-shielded ZAF pixel PX36 are provided as paired ZAF pixels in a region near the image height right end of the pixel array unit 21. In addition, the color filter 67 of B (blue) is provided for the left-shielded ZAF pixel PX35, while the color filter 67 of W (white) is provided for the right-shielded ZAF pixel PX36. In such a manner, sensitivity of the right-shielded ZAF pixel PX36 is allowed to improve.

As described in the respective examples depicted in FIGS. 29 to 31, the color filter 67 of the same color is provided for both the pair of the left-shielded ZAF pixel and the right-shielded ZAF pixel formed in the region near the center position (image height center) of the pixel array unit 21. In this case, any one of R (red), G (green), and B (blue) is designated as the color of the color filters 67.

On the other hand, for the regions near the image height left end and the image height right end, the color filter 67 of W (white) having higher transmittance is provided for one of the pair of the left-shielded ZAF pixel and the right-shielded ZAF pixel, i.e., for the ZAF pixel having low sensitivity for a structural reason, thus reducing lowering of sensitivity. In this case, the color filter 67 of the other ZAF pixel has a color different from W (white) (a color having lower transmittance than W (white)), such as the same color as the color of the color filters 67 of the ZAF pixels provided in the region near the image height center.

In such a manner, such sensor characteristics as sensitivity (pixel sensitivity) and a separation ratio are allowed to improve without pupil correction being performed.

Note that which region of the pixel array unit 21 is designated as a starting region for providing the color filter 67 of W (white) for the ZAF pixel may be determined according to sensitivity differences between the paired ZAF pixels, levels of sensitivity of the respective ZAF pixels (output peak values), or the like.

For example, when a sensitivity difference between a pair of the left-shielded ZAF pixel and the right-shielded ZAF pixel is a predetermined threshold determined beforehand or larger in a case where the color filters 67 of the same color are provided for these ZAF pixels, the color filter 67 of W (white) is provided for the ZAF pixel having lower sensitivity.

In addition, the color filter 67 of W (white) may be provided for the ZAF pixel which has a predetermined value of sensitivity or lower when this ZAF pixel has the color filter 67 of the same color as that of the different ZAF pixel located near the image height center, for example.

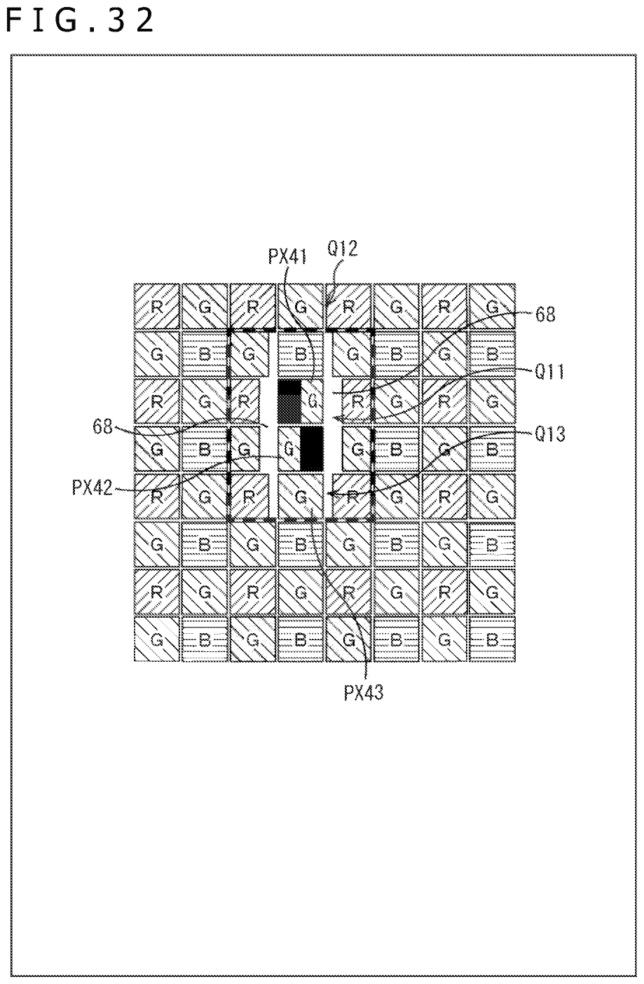

Moreover, as depicted in FIGS. 32 to 34, for example, a portion of the low refractive index wall 68 near the ZAF pixels may be made wider (thicker) than the other portions to further reduce color mixture of the imaging pixels or the ZAF pixels.

Note that each of FIGS. 32 to 34 is a diagram of a part of the pixel array unit 21 as viewed in the optical axis direction.

In addition, in FIGS. 32 to 34, each of squares represents one pixel, and each of characters “R,” “G,” and “B” indicated inside these pixels represents a color (type) of the color filter 67 provided in the pixel. Moreover, parts corresponding to each other in FIGS. 32 to 34 are given identical reference signs, and the same explanation of these parts will not be repeated where appropriate.

For example, according to the example depicted FIG. 32, a left-shielded ZAF pixel PX41 and a right-shielded ZAF pixel PX42 adjacent to each other in the up-down direction in the figure are provided as paired ZAF pixels.

In this example, peripheries of the respective pixels provided on the pixel array unit 21, such as the ZAF pixels including the left-shielded ZAF pixel PX41 and the imaging pixels, are surrounded by the low refractive index wall 68. In other words, the pixels adjacent to each other are separated by the low refractive index wall 68.

According to this example, the low refractive index wall 68 formed between the ZAF pixel and the imaging pixel adjacent to the ZAF pixel in the left-right direction, i.e., located on the left side or the right side of the ZAF pixel (left-right adjacent pixels), has a larger (longer) width (light-shielding protruding amount) than the low refractive index wall 68 formed between the other pixels.

The left-right direction here refers to the horizontal direction in the figure, and corresponds to a direction where a region shielded by a light shielding film and a region not shielded are arranged in the ZAF pixel. Moreover, when a pixel (imaging pixel) not adjacent to the ZAF pixel is referred to as a non-adjacent pixel, the width of the low refractive index wall 68 formed between the other pixels refers to a width of the low refractive index wall 68 formed between non-adjacent pixels.

Further, the low refractive index wall 68 formed between the pixel which is not the ZAF pixel and which is located adjacent to the ZAF pixel in the up-down direction (on the upper side or the lower side) (up-down adjacent pixel) and the pixel adjacent to this pixel in the left-right direction has a width larger than the width of the low refractive index wall 68 formed between the other pixels, but smaller (shorter) than a width of the low refractive index wall 68 formed between the ZAF pixel and the pixel adjacent to this ZAF pixel in the left-right direction.

Specifically, for example, a portion included in the low refractive index wall 68 and indicated by an arrow Q11 corresponds to a portion formed between the left-shielded ZAF pixel PX41 and an imaging pixel adjacent to the left-shielded ZAF pixel PX41 on the right side.

Moreover, a portion included in the low refractive index wall 68 and indicated by an arrow Q12 corresponds to a portion formed between imaging pixels adjacent to each other in the left-right direction, i.e., between non-adjacent pixels. A portion indicated by an arrow Q13 is a portion formed between an imaging pixel PX43 which is not a ZAF pixel and which is adjacent to the right-shielded ZAF pixel PX42 on the lower side in the figure and an imaging pixel adjacent to the imaging pixel PX43 on the right side.

In this case, the portion included in the low refractive index wall 68 and indicated by the arrow Q11 is wider (larger) than the portion indicated by the arrow Q12. Moreover, the portion included in the low refractive index wall 68 and indicated by the arrow Q13 is wider than the portion indicated by the arrow Q12, but narrower than the portion indicated by the arrow Q11.

Such a configuration reduces color mixture caused between the ZAF pixel and the pixel adjacent to the ZAF pixel by reflection of light entering the ZAF pixel on the metal film 69 which functions as a light shielding film formed within the ZAF pixel, and thus achieves improvement of sensor characteristics.

According to this example, the left half or the right half in each of the ZAF pixels is shielded, and color mixture with the pixel adjacent to the ZAF pixel on the left side or the right side is more easily caused. Accordingly, each of the widths of the portions of the low refractive index wall 68 for the adjacent pixels on the left and right sides is increased to effectively reduce color mixture.

Note that each of the widths of the portions included in the low refractive index wall 68 and indicated by the arrow Q11, the arrow Q12, and the arrow Q13 may be varied according to the distance (image height) in the left-right direction from the center position (image height center) of the pixel array unit 21 to the pixel, i.e., the position of the pixel in the pixel array unit 21.

For example, color mixture is more easily caused with nearness to the image height left end or the image height right end. Accordingly, the width of the low refractive index wall 68 formed between the ZAF pixel and the pixel adjacent to the ZAF pixel on the left side or the right side may be increased as the ZAF pixel is located at a longer distance in the left-right direction from the image height center.

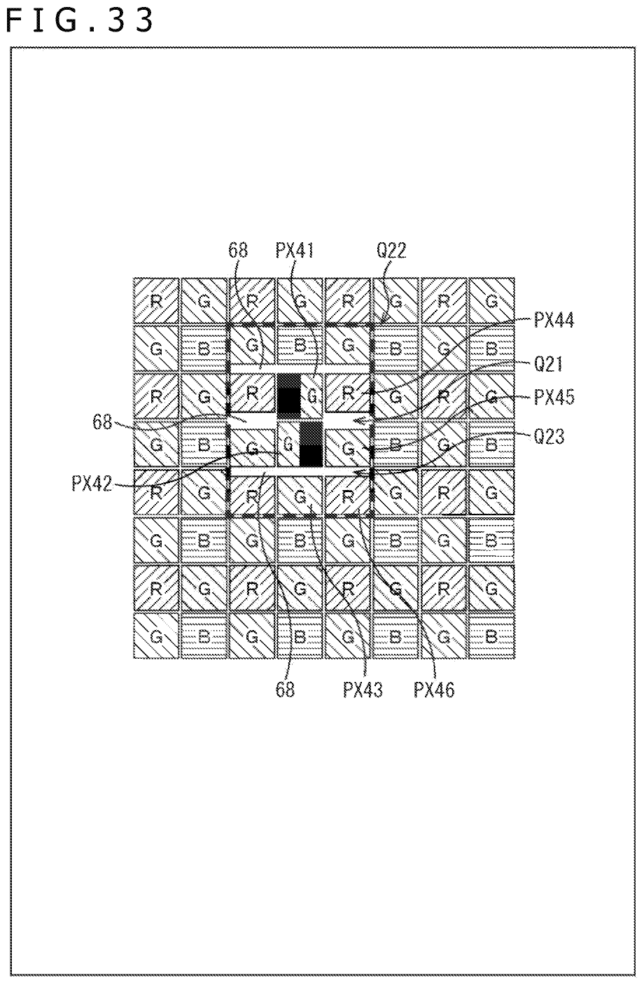

Moreover, while described with reference to FIG. 32 is the example which varies the width of the low refractive index wall 68 formed between the pixels adjacent to each other in the left-right direction, the width of the low refractive index wall 68 formed between the pixels adjacent to each other in the up-down direction may be varied as depicted in FIG. 33, for example.

In FIG. 33, assuming that an imaging pixel adjacent to a ZAF pixel in the left-right direction (the horizontal direction in the figure) is referred to as a left-right adjacent pixel, a portion of the low refractive index wall 68 between left-right adjacent pixels adjacent to each other in the up-down direction (the vertical direction in the figure) has a larger width than the low refractive index wall 68 formed between the other pixels (non-adjacent pixels).

Further, the low refractive index wall 68 between a left-right adjacent pixel or a ZAF pixel and an imaging pixel which is neither a left-right adjacent pixel nor a ZAF pixel and is adjacent to this left-right adjacent pixel or ZAF pixel in the up-down direction (upper side or lower side) has a larger width than the low refractive index wall 68 formed between the other pixels (non-adjacent pixels), but a smaller (shorter) width than the low refractive index wall 68 formed between left-right adjacent pixels.

Specifically, for example, a portion included in the low refractive index wall 68 and indicated by an arrow Q21 corresponds to a portion formed between a left-right adjacent pixel PX44 which is an imaging pixel adjacent to the left-shielded ZAF pixel PX41 on the right side and a left-right adjacent pixel PX45 which is an imaging pixel adjacent to the right-shielded ZAF pixel PX42 on the right side. In other words, the portion indicated by the arrow Q21 corresponds to a portion of the low refractive index wall 68 between the left-right adjacent pixels adjacent to each other in the up-down direction.

Moreover, a portion included in the low refractive index wall 68 and indicated by an arrow Q22 corresponds to a portion formed between imaging pixels adjacent to each other in the up-down direction (between non-adjacent pixels). A portion indicated by an arrow Q23 is a portion between a left-right adjacent pixel PX45 and an imaging pixel PX46 which is neither a ZAF pixel nor a left-right adjacent pixel and is adjacent to the left-right adjacent pixel PX45 on the lower side in the figure. For example, a width of the portion included in the low refractive index wall 68 and indicated by the arrow Q22 may be equalized with the width of the portion indicated by the arrow Q12 depicted in FIG. 32.

In this example, the portion included in the low refractive index wall 68 and indicated by the arrow Q21 is wider than the portion indicated by the arrow Q22.

The portion included in the low refractive index wall 68 and indicated by the arrow Q23 is wider (thicker) than the portion indicated by the arrow Q22, but narrower (thinner) than the portion indicated by the arrow Q21.

Further, a width of a portion included in the low refractive index wall 68 and formed between the right-shielded ZAF pixel PX42 and the imaging pixel PX43 which is not a ZAF pixel and is adjacent to the right-shielded ZAF pixel PX42 in the up-down direction is also equalized with the width of the portion indicated by the arrow Q23. Note that a width of a portion included in the low refractive index wall 68 and formed between the left-shielded ZAF pixel PX41 and the right-shielded pixel PX42 adjacent to each other in the up-down direction is equalized with the width of the portion indicated by the arrow Q22 in this example.

As in the example depicted in FIG. 32, such a configuration also reduces color mixture caused between the ZAF pixel and the pixel adjacent to the ZAF pixel and caused by reflection of light entering the ZAF pixel on the metal film 69 which functions as a light shielding film formed within the ZAF pixel, and thus achieves improvement of sensor characteristics.

Note that each of the widths of the portions included in the low refractive index wall 68 and indicated by the arrow Q21, the arrow Q22, and the arrow Q23 may be varied according to the distance in the left-right direction from the center position (image height center) of the pixel array unit 21 to the pixel, i.e., the image height.

For example, as in the case of FIG. 32, the width of the low refractive index wall 68 formed between the ZAF pixel or the left-right adjacent pixel and the pixel adjacent to the ZAF pixel or the left-right adjacent pixel in the up-down direction may be increased as the ZAF pixel or the left-right adjacent pixel is located at a longer distance in the left-right direction from the image height center.

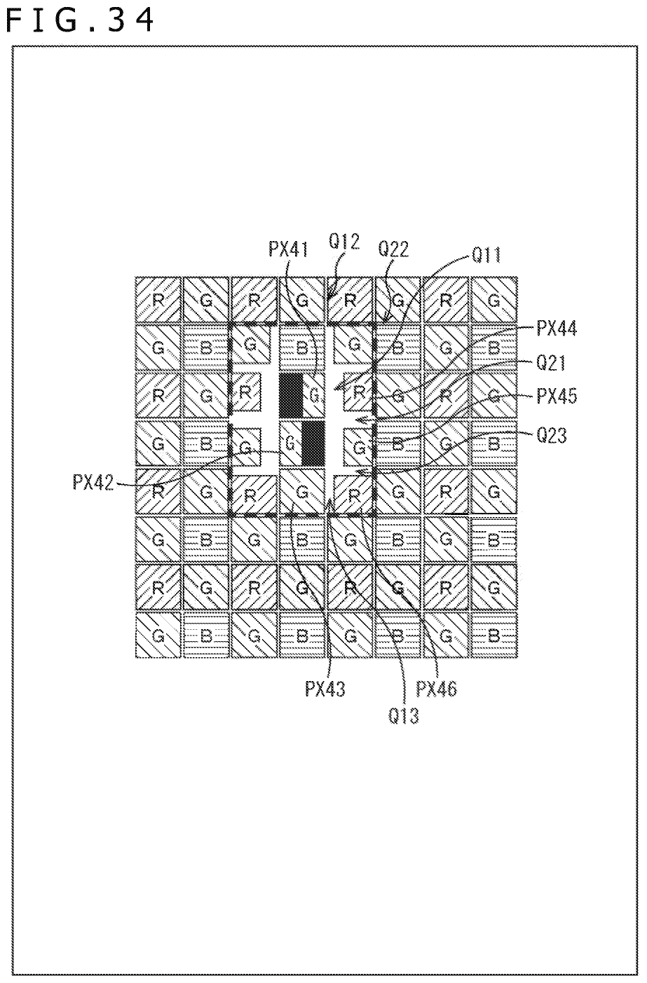

Moreover, as depicted in FIG. 34, for example, the widths of the low refractive index wall 68 formed between the pixels adjacent to each other in the left-right direction and between the pixels adjacent to each other in the up-down direction may be varied by combining the example depicted in FIG. 32 and the example depicted in FIG. 33.

In the example of FIG. 34, the portion included in the low refractive index wall 68 and indicated by the arrow Q11 is wider than the portion indicated by the arrow Q12, as in the case of FIG. 32. Moreover, the portion included in the low refractive index wall 68 and indicated by the arrow Q13 is wider than the portion indicated by the arrow Q12, but narrower than the portion indicated by the arrow Q11.

Moreover, in the example of FIG. 34, the portion included in the low refractive index wall 68 and indicated by the arrow Q21 is wider than the portion indicated by the arrow Q22, as in the case of FIG. 33. In this case, for example, the width of the portion indicated by the arrow Q21 is equalized with the width of the portion indicated by the arrow Q11.

Further, the portion included in the low refractive index wall 68 and indicated by the arrow Q23 is wider than the portion indicated by the arrow Q22, but narrower than the portion indicated by the arrow Q21. In this case, for example, the width of the portion indicated by the arrow Q23 is equalized with the width of the portion indicated by the arrow Q13.

A width of a portion included in the low refractive index wall 68 and formed between the right-shielded ZAF pixel PX42 and the imaging pixel PX43 adjacent to each other in the up-down direction is equalized with the width of the portion indicated by the arrow Q22. In addition, a width of a portion included in the low refractive index wall 68 and formed between the left-shielded ZAF pixel PX41 and the right-shielded pixel PX42 adjacent to each other in the up-down direction is equalized with the width of the portion indicated by the arrow Q22.

Such a configuration can also reduce color mixture between pixels adjacent to each other, and improve sensor characteristics. Note that widths of portions of the low refractive index wall 68 between pixels may also be varied according to the image height in the example depicted in FIG. 34, as in the cases depicted in FIGS. 32 and 33.

### Third Embodiment

### Different Configuration Example of Pixel Array Unit

Meanwhile, according to the configuration adopted in the first embodiment described above, the oxide film and the like are formed between the low refractive index wall 68 and the trench 62 to reduce processing damage caused by pupil correction.

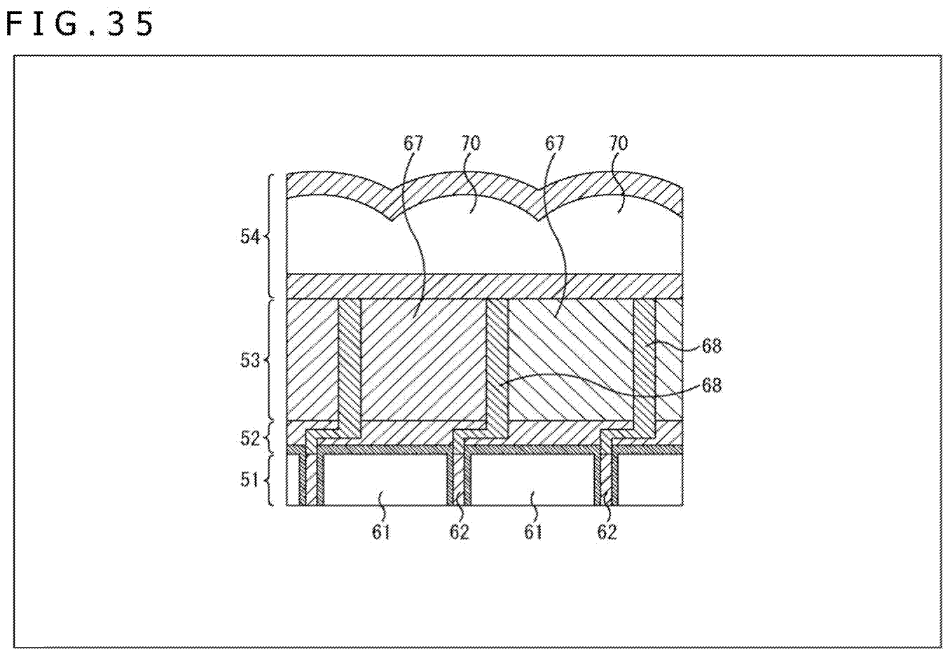

However, configurations other than this configuration may be adopted. For example, as depicted in FIG. 35, the low refractive index wall 68 may be bent within the oxide film layer 52 according to a correction amount of pupil correction to directly connect the low refractive index wall 68 to the trench 62. In such a manner, reduction of color mixture is similarly achievable while pupil correction on the image height end side is handled.

Note that FIG. 35 depicts a cross section of the pixel array unit 21 as viewed in the direction perpendicular to the optical axis direction. Moreover, parts in FIG. 35 identical to the corresponding parts in FIG. 5 are given identical reference signs, and the same explanation of these parts will not be repeated where appropriate.

According to the example depicted in FIG. 35, the low refractive index wall 68 penetrates the whole of the color filter layer 53 and the oxide film layer 52, and is embedded up to a position immediately above the trench 62 formed between pixels adjacent to each other.

Specifically, the low refractive index wall 68 includes a portion which penetrates the entire color filter layer 53 and is embedded up to an intermediate position in the oxide film layer 52 to constitute a section elongated in the optical axis direction, a portion which is formed inside the oxide film layer 52 to constitute a section elongated in the direction perpendicular to the optical axis direction, and a portion which is embedded up to a position immediately above the trench 62 from the inside of the oxide film layer 52 to constitute a section elongated in the optical axis direction.

Accordingly, the low refractive index wall 68 has an overall structure (shape) bent in the direction perpendicular to the optical axis direction inside the oxide film layer 52 and directly connected to the trench 62.

Such a configuration of the low refractive index wall 68 directly connected to the trench 62 neither causes processing damage to the photoelectric conversion units 61, nor forms color mixture paths between the low refractive index wall 68 and the trench 62. Accordingly, sensor characteristics are allowed to improve without processing damage being caused.

The low refractive index wall 68 will be further detailed here.

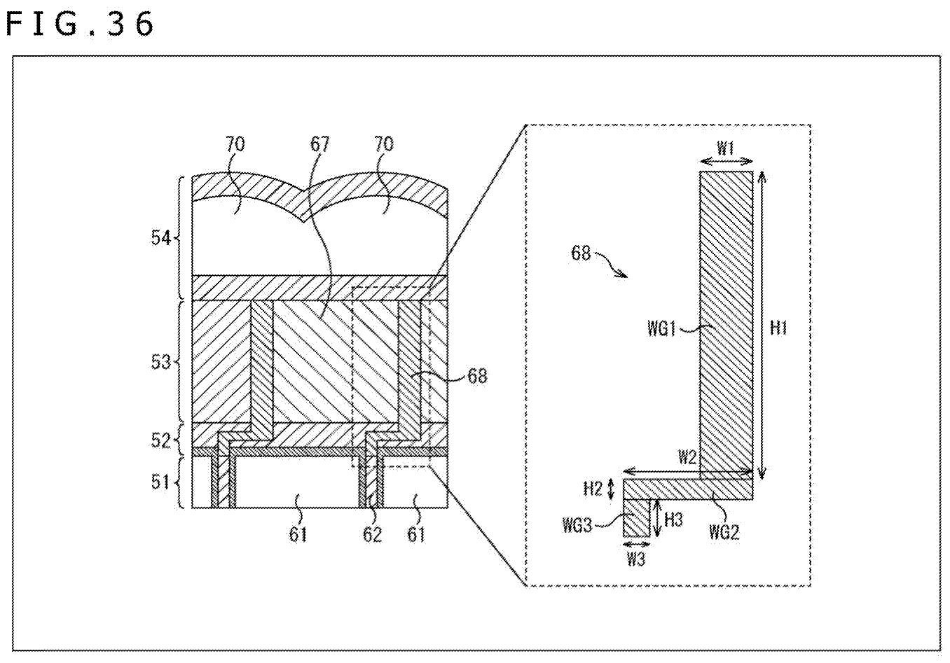

FIG. 36 is a diagram depicting an enlarged part of the low refractive index wall 68 in FIG. 35.

According to this example, the low refractive index wall 68 includes a waveguide portion WG1, a waveguide portion WG2, and a waveguide portion WG3.

Each of the waveguide portion WG1, the waveguide portion WG2, and the waveguide portion WG3 thus formed includes an insulator material having a lower refractive index than that of the color filter 67.

Specifically, for example, each of the waveguide portion WG1 to the waveguide portion WG3 includes SiN, SiO₂, SiON, a styrene-based resin material, an acryl-based resin material, a styrene-acryl copolymerization-based resin material, a siloxane-based resin material, the atmosphere, or a vacuum. In this example, each of the waveguide portion WG1 to the waveguide portion WG3 includes the same material.

The low refractive index wall 68 thus configured is also regarded to include the waveguide portion WG1 functioning as one low refractive index wall penetrating the color filter layer 53, the waveguide portion WG3 formed immediately above the trench 62 in the oxide film layer 52 and functioning as another low refractive index wall, and the waveguide portion WG2 formed in the oxide film layer 52 and functioning as a connection portion connecting the waveguide portion WG1 and the waveguide portion WG3.

Hereinafter, a length of the waveguide portion WG1 in the optical axis direction will be referred to as a height H1, while a width of the waveguide portion WG1 in the direction perpendicular to the optical axis direction will be referred to as a horizontal width W1.

Similarly, a length of the waveguide portion WG2 in the optical axis direction will be referred to as a height H2, a width of the waveguide portion WG2 in the direction perpendicular to the optical axis direction will be referred to as a horizontal width W2, a length of the waveguide portion WG3 in the optical axis direction will be referred to as a height H3, and a width of the waveguide portion WG3 in the direction perpendicular to the optical axis direction will be referred to as a horizontal width W3.

The waveguide portion WG1 is so provided as to penetrate an area from the micro-lens layer 54 side end of the color filter layer 53 to an intermediate position within the oxide film layer 52. Accordingly, the waveguide portion WG1 has a shape elongated in the optical axis direction.

Moreover, the waveguide portion WG3 is provided from an intermediate position within the oxide film layer 52 up to a position immediately above the trench 62, and has a shape elongated in the optical axis direction.

Further, the waveguide portion WG2 is formed at one or a plurality of oxide film portions within the oxide film layer 52, and has a shape elongated in the direction perpendicular to the optical axis direction.

In this example, the waveguide portion WG1 and the waveguide portion WG3 each elongated in the optical axis direction are connected to each other via the waveguide portion WG2 elongated in the direction perpendicular to the optical axis direction.

Specifically, the waveguide portion WG1 and the waveguide portion WG2 are connected to each other such that a lower side end (lower end) of the waveguide portion WG1 in the figure and an upper side surface (upper surface) of the waveguide portion WG2 in the figure come into contact with each other and that right ends of the waveguide portion WG1 and the waveguide portion WG2 in the figure are aligned with each other. Accordingly, the end (lower end) of the waveguide portion WG1 is connected to one end of the waveguide portion WG2.

Similarly, the waveguide portion WG3 and the waveguide portion WG2 are connected to each other such that an upper side end (upper end) of the waveguide portion WG3 in the figure and a lower side surface (lower surface) of the waveguide portion WG2 in the figure come into contact with each other and that left ends of the waveguide portion WG3 and the waveguide portion WG2 in the figure are aligned with each other. Accordingly, the end (upper end) of the waveguide portion WG3 is connected to the other end of the waveguide portion WG2.

The height H1 and the horizontal width W1 of the waveguide portion WG1, the height H2 and the horizontal width W2 of the waveguide portion WG2, and the height H3 and the horizontal width W3 of the waveguide portion WG3 each constituting the low refractive index wall 68 as described above are individually varied according to an incident angle of light entering each pixel, a pixel arrangement, or the like.

Specifically, for example, pupil correction is performed for the on-chip lens 70 and the color filter 67 in the pixel array unit 21 in reference to a correction amount corresponding to a distance from the center position (image height), i.e., an incident angle of light entering each pixel.

Accordingly, the on-chip lens 70, the color filter 67, and the waveguide portion WG1 are shifted toward the image height center from the photoelectric conversion unit 61, the trench 62, and the waveguide portion WG3 each disposed at a fixed position, by the correction amount of pupil correction, i.e., a distance corresponding to the incident light angle.

As a result, the distance between the waveguide portion WG1 and the waveguide portion WG3, i.e., the horizontal distance in the figure, is also variable according to the correction amount of pupil correction. Accordingly, the horizontal width W2 of the waveguide portion WG2 is similarly variable according to this variation. Specifically, the correction amount of pupil correction increases with farness from the center position of the pixel array unit 21, i.e., with nearness to the image height end, for example. Accordingly, the horizontal width W2 of the waveguide portion WG2 also becomes larger according to this increase.

As described above, processing damage and color mixture paths are also avoidable by connecting the waveguide portion WG1 formed between the color filters 67 of the respective pixels and the waveguide portion WG3 formed immediately above the trench 62 via the waveguide portion WG2 formed inside the oxide film layer 52. Accordingly, sensor characteristics are allowed to improve without processing damage being caused, as in the case of the first embodiment.

### Modification of Third Embodiment

### Different Configuration Example of Pixel Array Unit

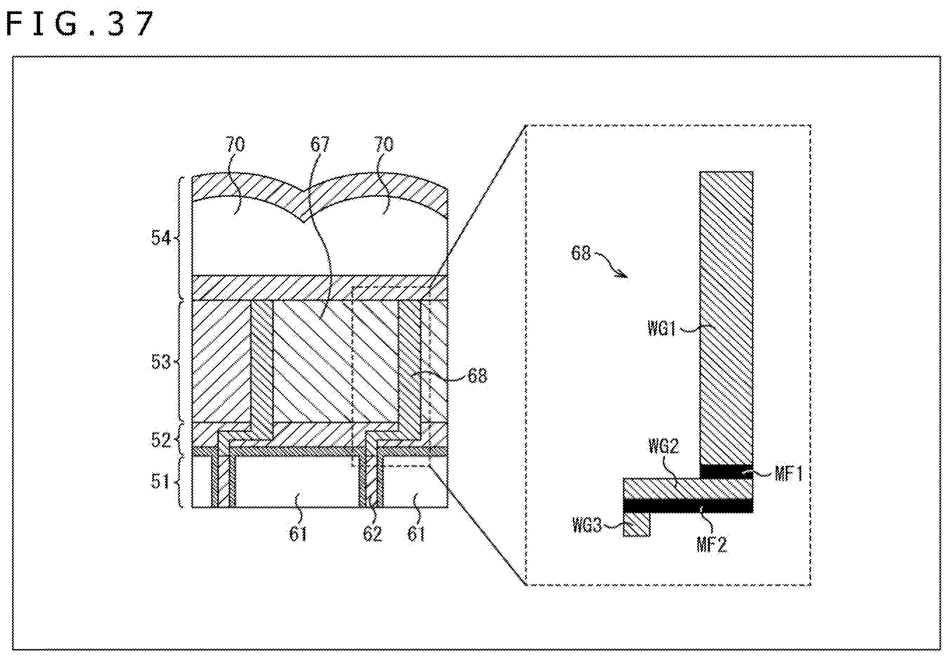

Note that the configuration and the shape of the low refractive index wall 68 which includes the waveguide portion WG1, the waveguide portion WG2, and the waveguide portion WG3 are not limited to those of the example depicted in FIG. 36, and may be any configuration and shape such as those in the examples depicted in FIGS. 37 to 41.

Each of FIGS. 37 to 41 is a diagram depicting an enlarged portion of the low refractive index wall 68 in a cross section of the pixel array unit 21 as viewed in the direction perpendicular to the optical axis direction. Note that parts in FIGS. 37 to 41 identical to the corresponding parts in FIG. 36 or in FIGS. 37 to 41 are given identical reference signs, and the same explanation of these parts will not be repeated where appropriate.

According to the example depicted in FIG. 37, the low refractive index wall 68 includes the waveguide portions WG1 to WG3 and metal films MF1 and MF2. For example, each of the metal films MF1 and MF2 includes TiN, Ti, or the like, and functions as an absorber which absorbs light entering from the outside.

In the low refractive index wall 68, the metal film MF1 and the metal film MF2 are formed on an upper surface and a lower surface of the waveguide portion WG2 in the figure, respectively.

Specifically, the metal film MF1 having the same horizontal width as the horizontal width W1 of the waveguide portion WG1 is formed between the lower end of the waveguide portion WG1 and the upper surface of the waveguide portion WG2. Moreover, the metal film MF2 having the same horizontal width as the horizontal width W2 of the waveguide portion WG2 is formed between the upper end of the waveguide portion WG3 and the lower surface of the waveguide portion WG2.

While the example including the metal film MF1 and the metal film MF2 has been described here, only one of the metal films MF1 and MF2 may be formed. Moreover, the height and the horizontal width of each of the metal films MF1 and MF2 may be individually varied in an appropriate manner.

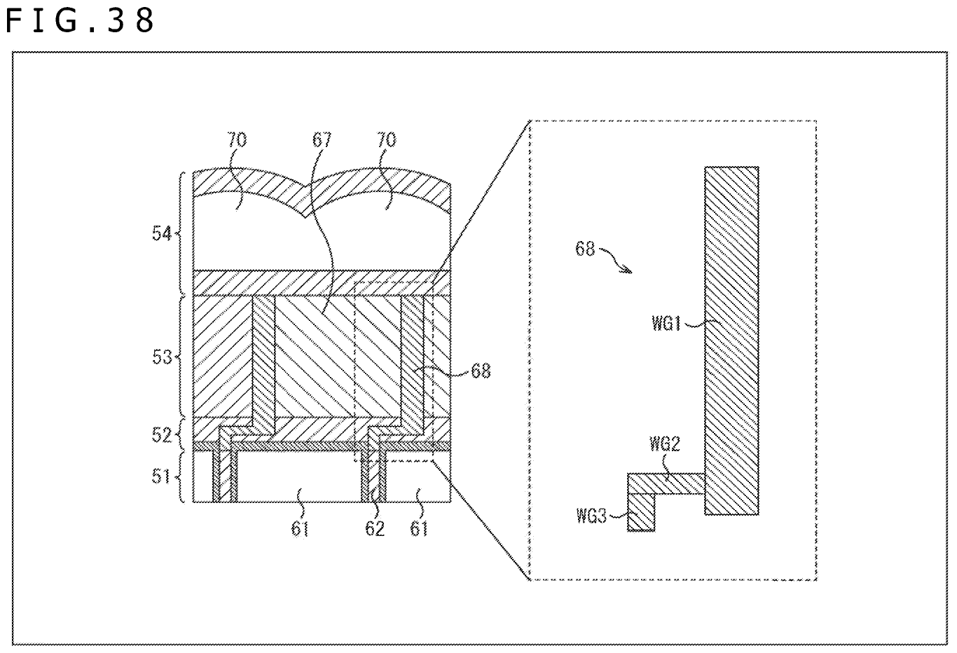

According to the example depicted in FIG. 38, the low refractive index wall 68 includes the waveguide portion WG1 to the waveguide portion WG3, as in the case depicted in FIG. 36. However, the waveguide portion WG1 is so provided as to penetrate the waveguide portion WG2.

Specifically, according to this example, the lower side end (lower end) of the waveguide portion WG1 in the figure is located below the waveguide portion WG2 within the oxide film layer 52, i.e., on the lower side (photoelectric conversion layer 51 side) in the figure with respect to the waveguide portion WG2. In other words, the waveguide portion WG2 is formed at (connected to) a position between the upper end and the lower end of the waveguide portion WG1.

In this case, the waveguide portion WG1 penetrates the waveguide portion WG2. However, an oxide film constituting the oxide film layer 52 is formed between the lower end of the waveguide portion WG1 and the photoelectric conversion layer 51 (photoelectric conversion unit 61). Accordingly, the waveguide portion WG1 does not come into contact with the photoelectric conversion unit 61. In other words, no processing damage is caused.

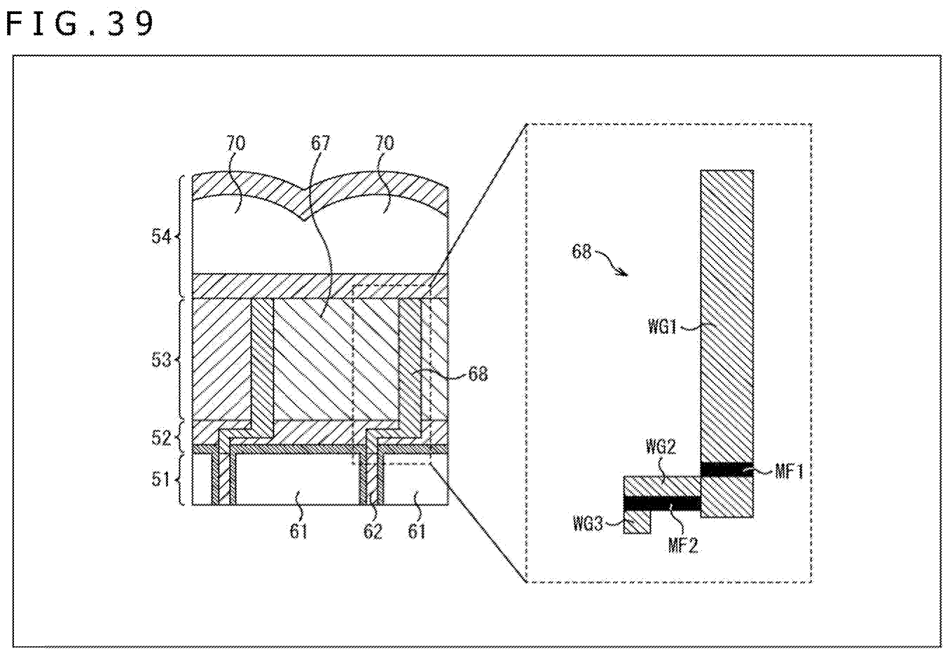

FIG. 39 depicts an example combining the example depicted in FIG. 37 and the example depicted in FIG. 38, i.e., an example where the metal film MF1 and the metal film MF2 are formed on the upper surface and the lower surface of the waveguide portion WG2, respectively, in the configuration depicted in FIG. 38.

In FIG. 39, the metal film MF1 having the same horizontal width as the horizontal width W1 of the waveguide portion WG1 is embedded in a portion inside the waveguide portion WG1 and immediately above the upper side surface (upper surface) of the waveguide portion WG2 in the figure.

Moreover, the metal film MF2 is provided between the waveguide portion WG3 and the waveguide portion WG2. The horizontal width of the metal film MF2 is a width from the left end position of the waveguide portion WG3 (waveguide portion WG2) to the left end position of the waveguide portion WG1.

Note that only either the metal film MF1 or the metal film MF2 may be formed in this example, as in the above-described case. Moreover, the height and the horizontal width of each of the metal films MF1 and MF2 may be individually varied in an appropriate manner.

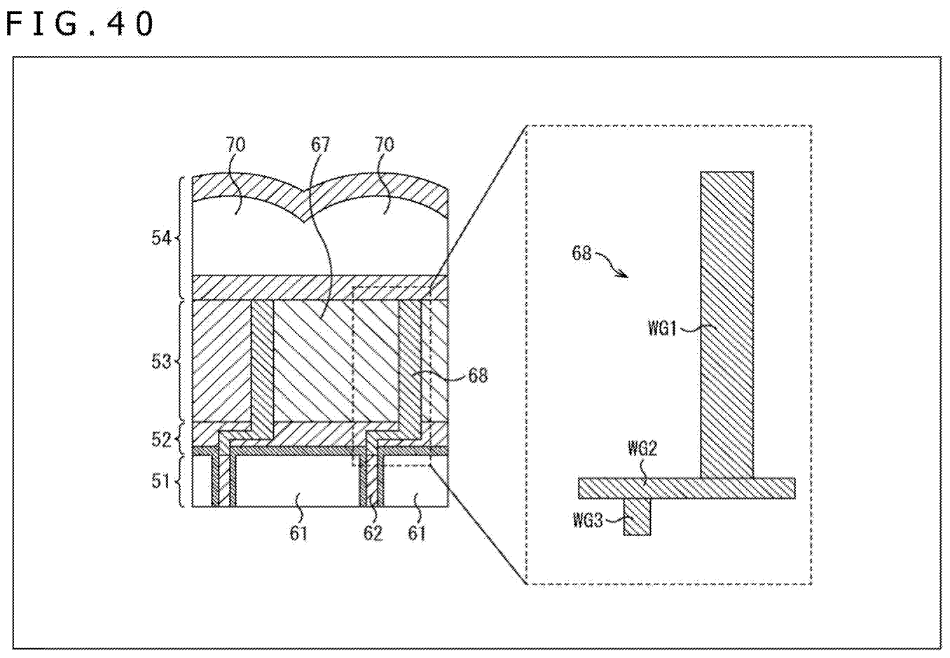

FIG. 40 depicts an example of a structure where the waveguide portion WG2 in the example depicted in FIG. 36 is elongated (extended) in the width direction (left-right direction) such that the horizontal width of the waveguide portion WG2 becomes longer than the distance between the ends of the waveguide portion WG1 and the waveguide portion WG3 in the width direction.

In this example, arrangement positions, shapes, and lengths (sizes) of the height and the horizontal width of the waveguide portion WG1 and the waveguide portion WG3 are the same as those of the case in FIG. 36, but the horizontal width W2 of the waveguide portion WG2 is larger than that of the example of FIG. 36.

Particularly, the left end position of the waveguide portion WG2 in the figure is located on the left side (outside) of the left end position of the waveguide portion WG3, while the right end position of the waveguide portion WG2 in the figure is located on the right side (outside) of the right end position of the waveguide portion WG1.

In other words, the lower end of the waveguide portion WG1 is connected to a position that is included in the upper surface of the waveguide portion WG2 and that is located between the left end and the right end of the waveguide portion WG2, while the upper end of the waveguide portion WG3 is connected to a position that is included in the lower surface of the waveguide portion WG2 and that is located between the left end and the right end of the waveguide portion WG2.

According to this example, each of the waveguide portion WG1 and the waveguide portion WG3 is connected to a position between the left end and the right end of the waveguide portion WG2. Accordingly, the horizontal width W2 of the waveguide portion WG2 between any pixels may be a fixed and uniform width regardless of the positions of the pixels on the pixel array unit 21, i.e., for any correction amount of pupil correction.

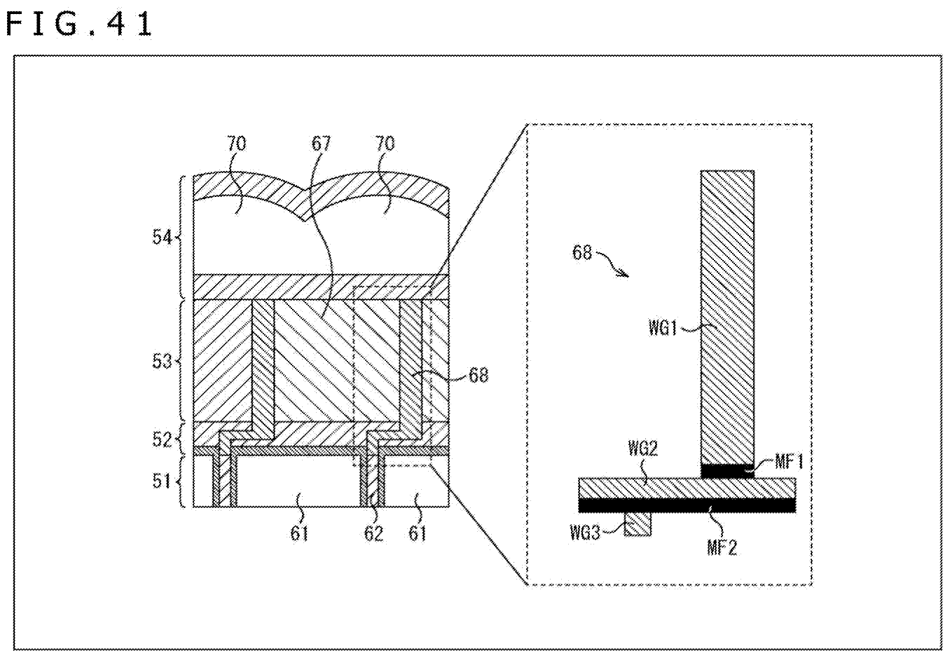

FIG. 41 depicts an example where the metal film MF1 and the metal film MF2 are further formed on the upper surface and the lower surface of the waveguide portion WG2, respectively, in the configuration depicted in FIG. 40.

Accordingly, in the example depicted in FIG. 41, the low refractive index wall 68 includes the waveguide portions WG1 to WG3 and the metal films MF1 and MF2.

In the low refractive index wall 68, the metal film MF1 having the same horizontal width as the horizontal width W1 of the waveguide portion WG1 is formed between the waveguide portion WG1 and the waveguide portion WG2. Moreover, the metal film MF2 having the same horizontal width as the horizontal width W2 of the waveguide portion WG2 is formed between the waveguide portion WG3 and the waveguide portion WG2.

Note that only either the metal film MF1 or the metal film MF2 described above may be formed. Moreover, the height and the horizontal width of each of the metal films MF1 and MF2 may be individually varied in an appropriate manner.

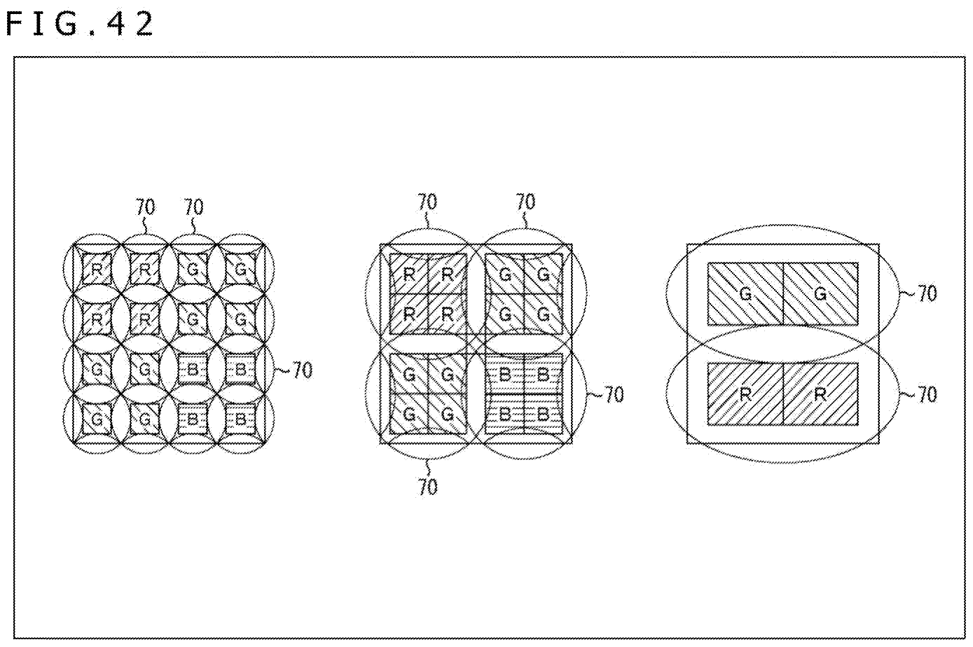

Further, in the respective examples described above with reference to FIGS. 36 to 41, one on-chip lens 70 may be provided for each pixel, or one on-chip lens 70 may be provided for each set of a plurality of pixels adjacent to each other, as depicted in FIG. 42, for example.

FIG. 42 is a schematic diagram of a part of the pixel array unit 21 viewed in the optical axis direction. Note that each of squares represents one pixel, and each of characters “R,” “G,” and “B” indicated inside these pixels represents a color (type) of the color filter 67 provided in the pixel in FIG. 42. Moreover, each circle or ellipse in FIG. 42 represents one on-chip lens 70. The reference sign is given to only some of the on-chip lenses 70 for easy visual recognition of the figure.

For example, depicted in a left part of the figure is an example of a 1×1 pixel configuration.

Specifically, one on-chip lens 70 is provided for each pixel included in the pixel array unit 21 in this example.

In addition, depicted in a central part of the figure is a configuration where one on-chip lens 70 is shared by 2×2 pixels, i.e., 4 pixels.

In this example, four pixels each including the color filter 67 of the same color are formed adjacently to each other, and one on-chip lens 70 having a circular shape is provided for these four pixels.

Depicted in a right part of the figure is a configuration where one on-chip lens 70 is shared by 2×1 pixels, i.e., 2 pixels.

In this example, two pixels each including the color filter 67 of the same color are formed adjacently to each other in the horizontal direction (left-right direction), and one on-chip lens 70 having an elliptic shape is provided for these two pixels.

### Fourth Embodiment

### Different Configuration Example of Pixel Array Unit

Meanwhile, according to the third embodiment described with reference to FIG. 35 and other figures, the low refractive index wall 68 is bent within the oxide film layer 52 according to a correction amount of pupil correction to directly connect the low refractive index wall 68 to the trench 62.

In such an example, the low refractive index wall 68 is bent within the oxide film of the oxide film layer 52 depending on the forming position of the waveguide portion WG2 which is included in the waveguide portions constituting the low refractive index wall 68 and functions as a connecting portion. However, such a manner of processing is not easily performed. Specifically, manufacture of the pixel array unit 21 is not easy and raises costs.

Moreover, if adopted is such a structure where the low refractive index wall 68 and the color filter 67 are arranged in direct contact with each other, the material of the color filter 67 (hereinafter also referred to as a CF (Color Filter) material) may be diffused into the low refractive index wall 68. In this case, spectral characteristics and sensitivity may be deteriorated.

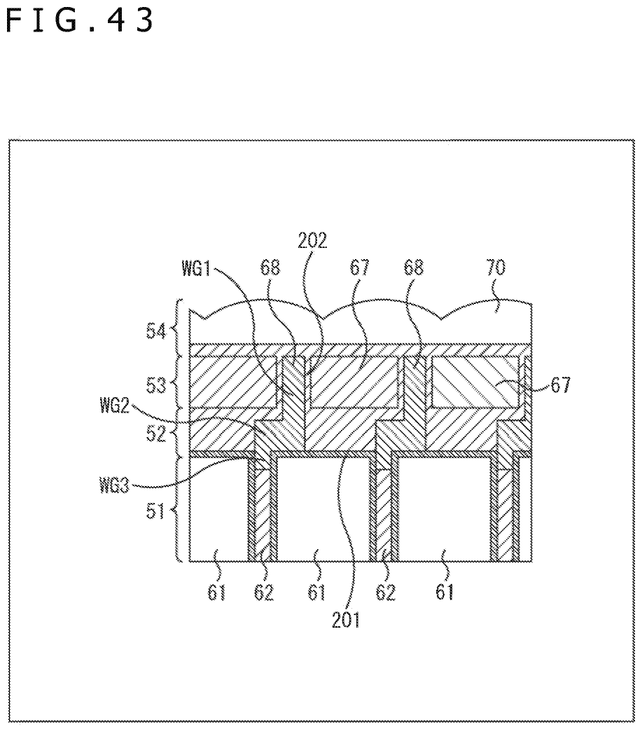

Accordingly, for example, the pixel array unit 21 may have a configuration depicted in FIG. 43 to decrease manufacturing costs and reduce deterioration of spectral characteristics and sensitivity.

Note that FIG. 43 depicts a cross section of the pixel array unit 21 as viewed in the direction perpendicular to the optical axis direction. Moreover, parts in FIG. 43 identical to the corresponding parts in FIG. 35 or 36 are given identical reference signs, and the same explanation of these parts will not be repeated where appropriate.

According to the example depicted in FIG. 43, the on-chip lenses 70 and the color filters 67 are shifted from the photoelectric conversion units 61 and the trench 62 according to a correction amount of pupil correction.

Moreover, each of the photoelectric conversion units 61 is covered with an oxide film 201 functioning as an anti-reflection film. A portion included in the oxide film 201 and located immediately above the photoelectric conversion unit 61 constitutes, with another oxide film, the oxide film layer 52.

The low refractive index wall 68 includes the waveguide portion WG1 functioning as one low refractive index wall, the waveguide portion WG3 functioning as another low refractive index wall, and the waveguide portion WG2 functioning as a connection portion connecting the waveguide portion WG1 and the waveguide portion WG3. Each of the waveguide portion WG1 to the waveguide portion WG3 described above includes the same material.

The waveguide portion WG1 is so formed as to penetrate the entire color filter layer 53, and to be embedded up to an intermediate position in the oxide film layer 52. The waveguide portion WG1 functions as a CF wall separating the color filters 67.

Moreover, a portion corresponding to the waveguide portion WG1 of the low refractive index wall 68 is covered with an oxide film 202 functioning as a protection film. In other words, the oxide film 202 is formed between the portion corresponding to the waveguide portion WG1 of the refractive index wall 68 and the color filter 67 in the color filter layer 53.

Similarly, a portion corresponding to the waveguide portion WG2 of the low refractive index wall 68 is also covered with an oxide film including a material similar to the material of the oxide film 202. Accordingly, a portion of the surface of the low refractive index wall 68 other than a portion in contact with the trench 62 is covered with an oxide film. In other words, substantially all of the low refractive index wall 68 is covered with a protection film.

As described above, the waveguide portion WG1 is covered with the oxide film 202 to prevent direct contact between the waveguide portion WG1 and the color filter 67. This configuration can reduce diffusion of the CF material to the waveguide portion WG1 (low refractive index wall 68). In other words, this configuration can protect the low refractive index wall 68. In such a manner, reduction of deterioration of spectral characteristics and sensitivity is achievable.

Note that a protection film including SiN or the like may be formed in place of the oxide film 202 for protection of the low refractive index wall 68.

The waveguide portion WG3 is formed on a portion extending from a position immediately above the trench 62 within the photoelectric conversion layer 51 to the on-chip lens 70 side end of the oxide film 201 within the oxide film layer 52.

The waveguide portion WG2 is formed between the waveguide portion WG1 and the waveguide portion WG3 in a portion included in the oxide film layer 52 and located immediately above the oxide film 201.

Particularly, the waveguide portion WG2 is so formed as to project by a correction amount of pupil correction toward a pixel region, i.e., the inside of the photoelectric conversion unit 61 (horizontal direction), along the photoelectric conversion layer 51, i.e., the oxide film 201 provided immediately above the photoelectric conversion unit 61.

The waveguide portion WG1 is connected to the upper surface of the waveguide portion WG2, while the waveguide portion WG3 is connected to the lower surface of the waveguide portion WG2. Moreover, the right end position of the waveguide portion WG2 in the figure is aligned with the right end position of the waveguide portion WG1 in the figure, while the left end position of the waveguide portion WG2 in the figure is aligned with the left end position of the waveguide portion WG3 in the figure.

In this example, the low refractive index wall 68 is so formed as to come into contact with the trench 62 provided for pixel separation and project above the oxide film 201 in the horizontal direction toward the photoelectric conversion unit 61 by the correction amount of pupil correction. Moreover, the low refractive index wall 68 penetrates the color filter layer 53, and also functions as a CF wall.

In this case, direct contact between the low refractive index wall 68 and the photoelectric conversion unit 61 is avoided, and no color mixture path is formed between the low refractive index wall 68 and the trench 62. Accordingly, sensor characteristics are allowed to improve without processing damage being caused during formation of the low refractive index wall 68.

Further, such a structure does not require processing for bending the low refractive index wall 68 inside the oxide film in the oxide film layer 52. Accordingly, easy manufacture of the pixel array unit 21 and reduction of manufacturing costs are achievable.

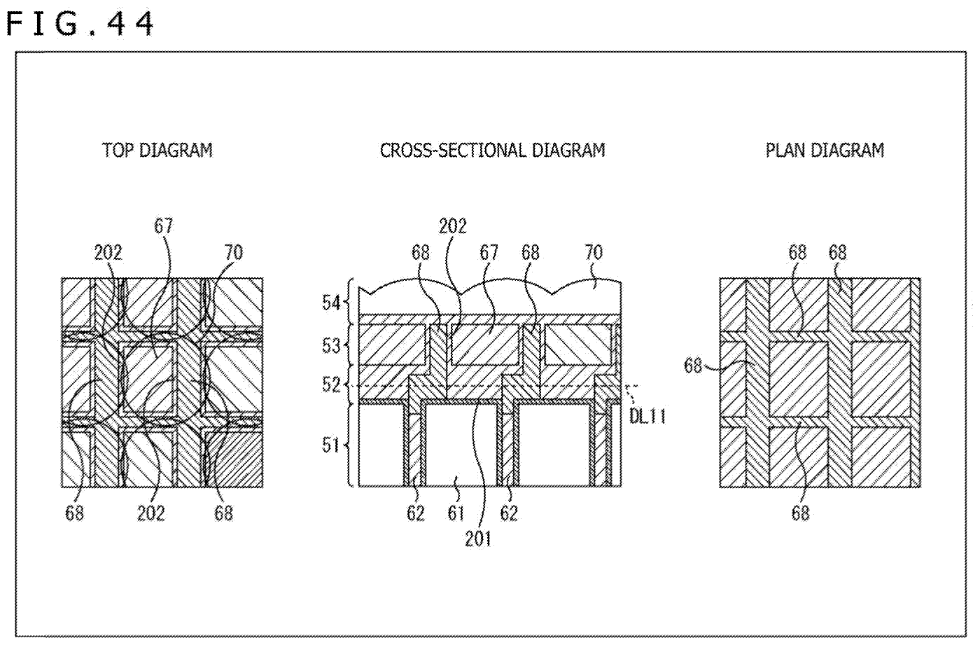

FIG. 44 depicts a top diagram, a cross-sectional diagram, and a plan diagram of a part of the pixel array unit 21 having the configuration depicted in FIG. 43. Note that parts in FIG. 44 identical to the corresponding parts in FIG. 43 are given identical reference signs, and the same explanation of these parts will not be repeated where appropriate.

Depicted in a left part of FIG. 44 is a top diagram of a part of the pixel array unit 21 viewed in the optical axis direction.

In this example, one on-chip lens 70 is provided for each pixel. Moreover, the oxide film 202 is provided between the color filters 67 and the low refractive index wall 68 in the color filter layer 53.

Depicted in a central part of FIG. 44 is a cross-sectional diagram of a part of the pixel array unit 21. This cross-sectional diagram is the same figure as that in FIG. 43.

Note that the low refractive index wall 68 may be so formed as to come into direct contact with the color filters 67 with no protection film provided. However, the oxide film 202 provided in this example to function as a protection film for the low refractive index wall 68 can reduce such damage as diffusion (soak) of the CF material into the low refractive index wall 68.

Depicted in a right part of FIG. 44 is a plan diagram of an area taken along a dotted line DL11 in the cross-sectional diagram depicted in the central part of the figure. Specifically, depicted in the right part is a plan diagram of a part of the pixel array unit 21 within the oxide film layer 52 as viewed in the optical axis direction.

According to this example, as obvious from the figure, the low refractive index wall 68, more specifically, the waveguide portion WG2 of the low refractive index wall 68, is embedded in the oxide film constituting the oxide film layer 52, and a horizontal width of the waveguide portion WG2 (low refractive index wall 68) in the figure is larger by a correction amount of pupil correction.

### Modification of Fourth Embodiment

### Different Configuration Example of Pixel Array Unit

Note that each of the configurations of the low refractive index wall 68 and an area around the low refractive index wall 68 is not limited to the example depicted in FIG. 43, and may be any configuration as long as easy manufacture and reduction of manufacturing costs are achievable.

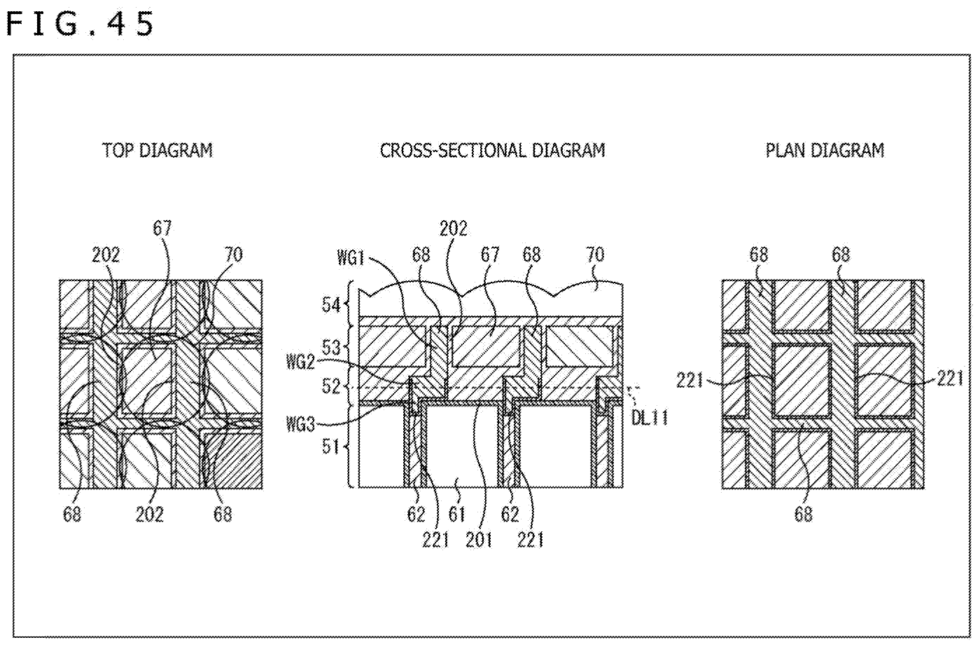

A different configuration example of the area around the low refractive index wall 68 will hereinafter be described with reference to FIGS. 45 to 50. Note that parts in FIGS. 45 to 50 identical to the corresponding parts in FIG. 44 are given identical reference signs, and the same explanation of these parts will not be repeated where appropriate. Moreover, parts corresponding to each other in FIGS. 45 to 50 are given identical reference signs, and the same explanation of these parts will not be repeated where appropriate.

Further, a left part, a central part, and a right part of each of FIGS. 45 to 47, 49, and 50 are a top diagram, a cross-sectional diagram, and a plan diagram of a part of the pixel array unit 21, as in the case of FIG. 44.

According to the example depicted in FIG. 45, an upper part of the low refractive index wall 68 is covered with the oxide film 202 functioning as a protection film, while a lower part of the low refractive index wall 68 is covered with a protection film 221 including a material different from the material of the oxide film 202. Accordingly, the upper part and the lower part of the low refractive index wall 68 are covered with protection films of types different from each other.

Specifically, a portion corresponding to a side surface and a bottom surface (lower surface) of the waveguide portion WG2 and a portion corresponding to the entire surface of the waveguide portion WG3 in the low refractive index wall 68 are covered with the protection film 221. For example, the protection film 221 includes a material having high sealability, such as SiN and AlO.

For example, it is obvious that the low refractive index wall 68 is surrounded by the protection film 221 in the plan diagram depicted in the right part of the figure.

The protection film 221 thus provided can protect the low refractive index wall 68 from H₂O and H₂ coming from a lower structure such as the photoelectric conversion layer 51, i.e., the lower side of the low refractive index wall 68.

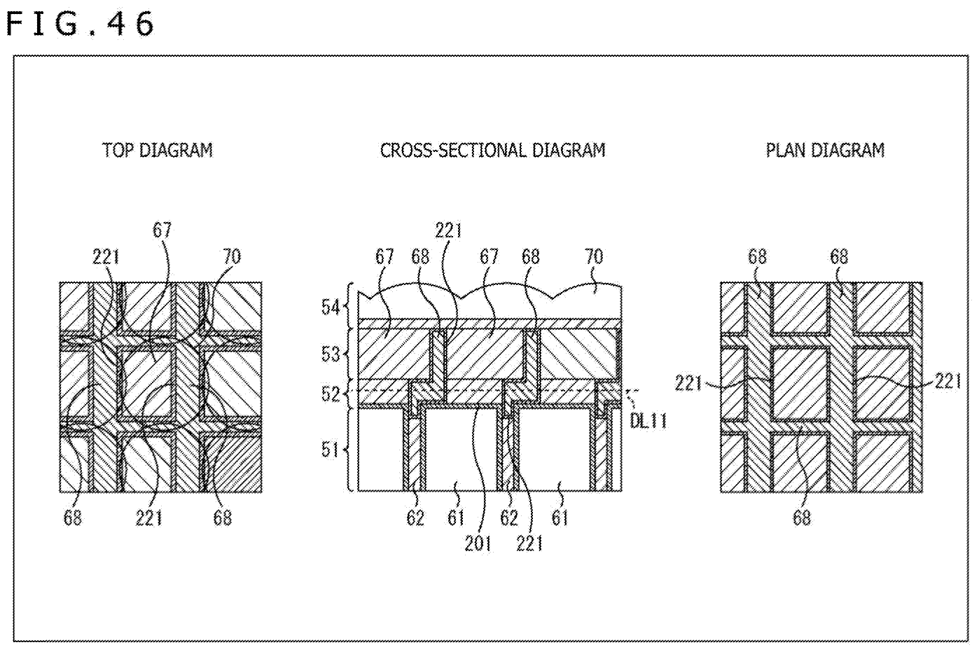

According to the example depicted in FIG. 46, the whole of the low refractive index wall 68, i.e., an entire circumference of the low refractive index wall 68, is covered with the protection film 221 including SiN, AlO, or the like having high sealability. Accordingly, the protection film 221 is provided between the color filters 67 and the low refractive index wall 68 in this example, preventing direct contact between the low refractive index wall 68 and the color filters 67.

The configuration which covers the entire low refractive index wall 68 with the protection film 221 having high sealability as described above can protect the low refractive index wall 68 from the surrounding structure and H₂O and H₂ contained in the atmosphere. In such a manner, yields and reliability of the pixel array unit 21 are allowed to improve.

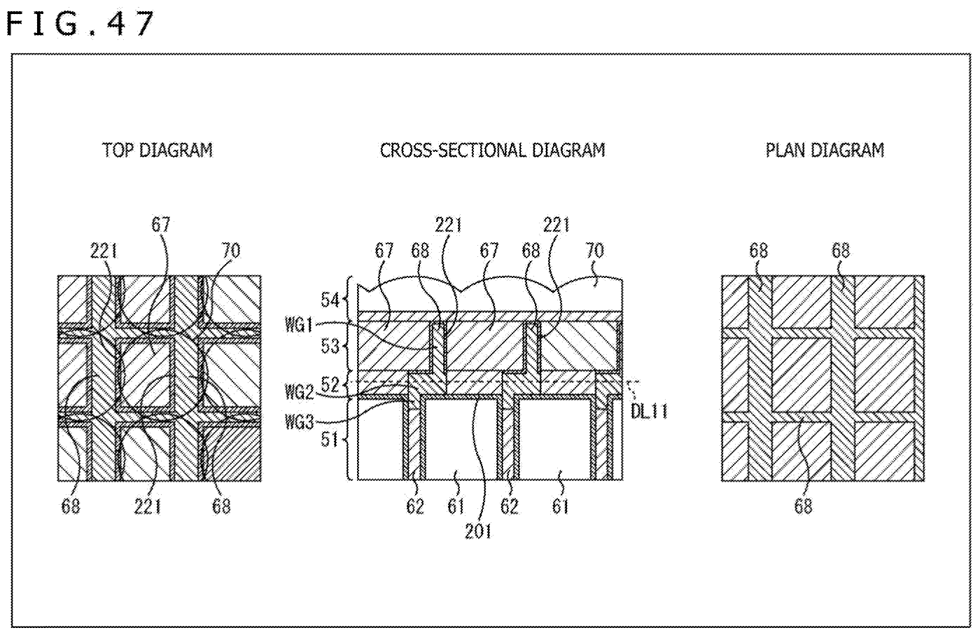

According to the example depicted in FIG. 47, the upper part of the low refractive index wall 68 is covered with the protection film 221.

Specifically, a part corresponding to the entire surface of the waveguide portion WG1 and a part corresponding to the upper surface of the waveguide portion WG2 in the low refractive index wall 68 are covered with the protection film 221. In other words, a portion included in the low refractive index wall 68 and adjacent to (in contact with) the color filters 67 is covered with the protection film 221.

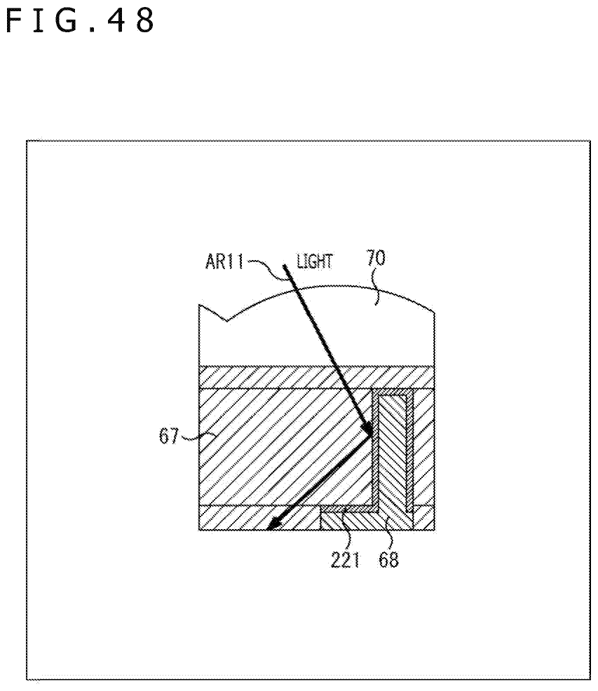

According to this example, a reflection effect by the low refractive index wall 68 can be raised by controlling a refractive index of the protection film 211 in line with a refractive index of each of the color filters 67, as depicted in FIG. 48.

FIG. 48 is a diagram depicting an enlarged part of the color filter 67 and the low refractive index wall 68 in the cross-sectional diagram depicted in the central part of FIG. 47.

This example adopts such a structure where the color filter 67, the protection film 221, and the low refractive index wall 68 are arranged in the horizontal direction in the figure.

For example, as indicated by an arrow AR11, light entering the on-chip lens 70 from the outside reflects on a portion within the color filter 67 at a boundary between the color filter 67 and the protection film 221, and enters the unillustrated photoelectric conversion unit 61.

In this case, a high reflection effect is providable if the protection film 221 includes a material meeting the following relation RE1 or RE2.

### (Relation RE1)

Refractive index of color filter 67≈ refractive index of protection film 221>> refractive index of low refractive index wall 68

(Relation RE2) Refractive index of color filter 67>> refractive index of protection film 221≈ refractive index of low refractive index wall 68

Selected as the material constituting the protection film 221 according to relation RE1 is such a material which has a refractive index substantially equal to the refractive index of the color filter 67 but considerably higher than the refractive index of the low refractive index wall 68.

Moreover, selected as the material constituting the protection film 221 according to relation RE2 is such a material which has a refractive index considerably lower than the refractive index of the color filter 67 but substantially equal to the refractive index of the low refractive index wall 68.

According to the foregoing respective examples depicted in FIGS. 45 to 47, a part or the whole of the low refractive index wall 68, i.e., a part or the whole of the waveguide portion WG1, the waveguide portion WG2, and the waveguide portion WG3 constituting the low refractive index wall 68, is covered with the protection film.

Particularly in the respective examples depicted in FIGS. 45 to 47, the protection film is provided between the low refractive index wall 68 and the color filters 67, as in the example depicted in FIG. 44. Accordingly, such damage as diffusion of the CF material into the low refractive index wall 68 can be reduced.

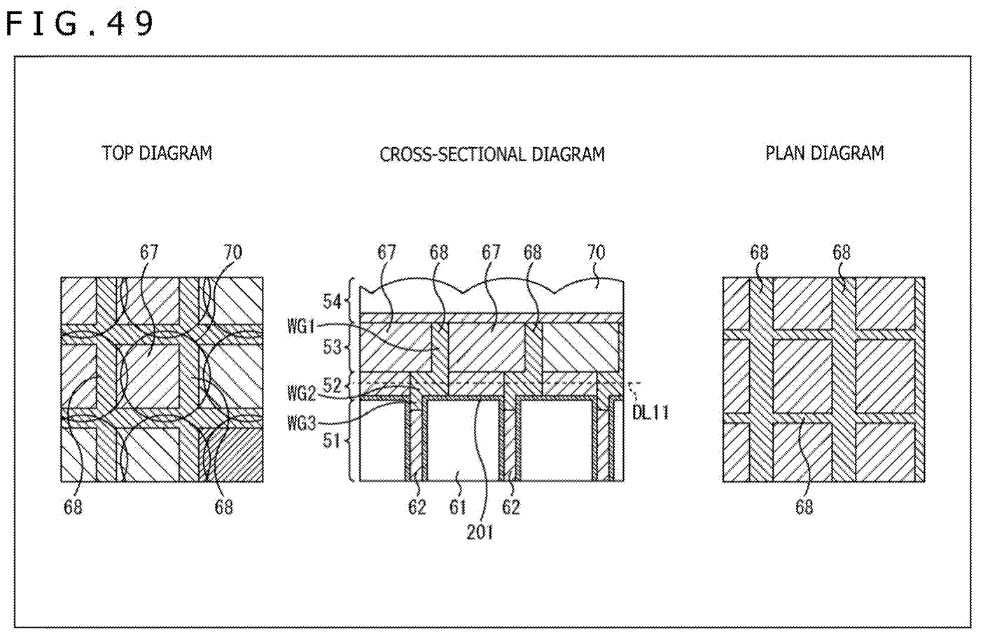

An example depicted in FIG. 49 adopts a configuration where no protection film is provided on a portion above the low refractive index wall 68, particularly between the low refractive index wall 68 and the color filters 67.

Accordingly, a side surface portion of the waveguide portion WG1 and an upper surface portion of the waveguide portion WG2 constituting the low refractive index wall 68 come into direct contact with the color filters 67.

In comparison with the foregoing respective examples depicted in FIGS. 44 to 47, such a configuration can reduce manufacturing steps by elimination of the step of forming the protection film for protecting the low refractive index wall 68, and thus can reduce (decrease) costs.

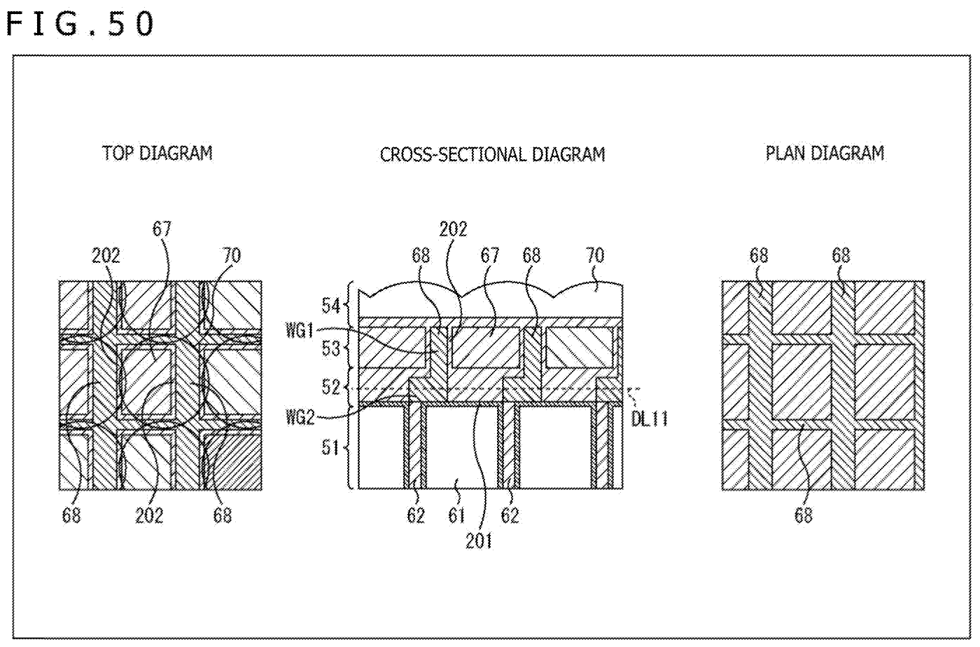

An example depicted in FIG. 50 adopts such a configuration where the lower part of the low refractive index wall 68 is not embedded in a portion between pixels inside the photoelectric conversion layer 51.

Specifically, according to this example, the low refractive index wall 68 includes the waveguide portion WG1 and the waveguide portion WG2, but does not include the waveguide portion WG3.

Moreover, the trench 62 is provided up to a portion corresponding to the oxide film 201 in the oxide film layer 52. The waveguide portion WG2 of the low refractive index wall 68 is disposed immediately above the trench 62. In other words, the trench 62 is provided in such a position as to come into contact with the left end of the lower surface of the waveguide portion WG2.

According to this example, the waveguide portion WG2 is provided along the oxide film 201 that is included in the oxide film layer 52 and that is formed immediately above the photoelectric conversion layer 51 (photoelectric conversion unit 61), to constitute a connection portion for connecting the trench 62 and the waveguide portion WG1.

Further, the oxide film 202 functioning as a protection film is also formed between the low refractive index wall 68 and the color filters 67 in this example, as in the example depicted in FIG. 44. In this manner, such damage as diffusion of the CF material to the low refractive index wall 68 can be reduced.

According to the respective examples described above with reference to FIGS. 45 to 50, manufacture is easy, and reduction of manufacturing costs is achievable, as in the example depicted in FIG. 44.

Meanwhile, in the respective examples described with reference to FIGS. 44 to 50, the portion corresponding to the waveguide portion WG2 of the low refractive index wall 68 in an area where pupil correction is performed in the pixel array unit 21 may have a different width and the like from those in an area where pupil correction is not performed.

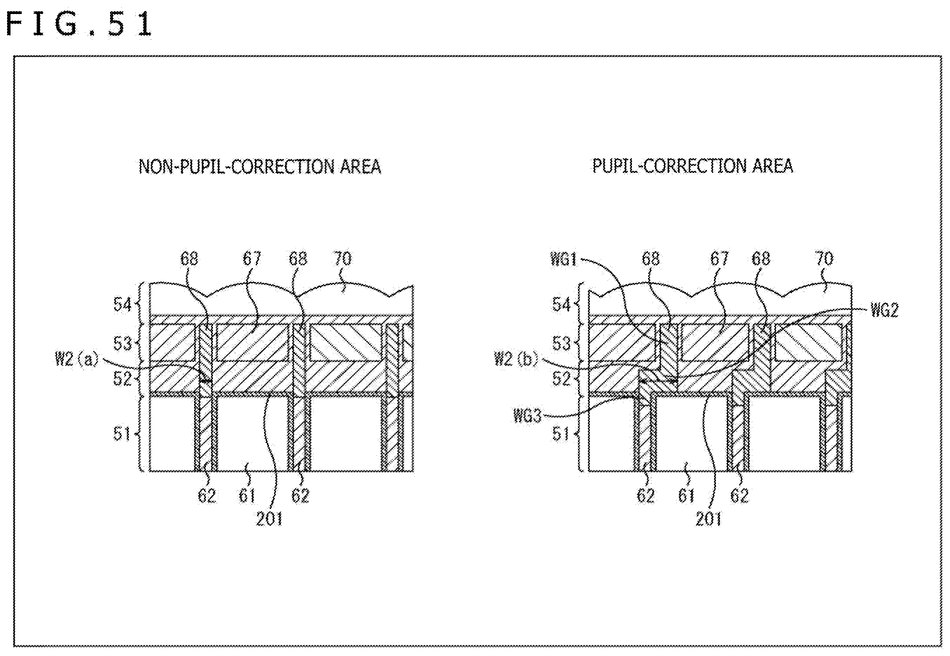

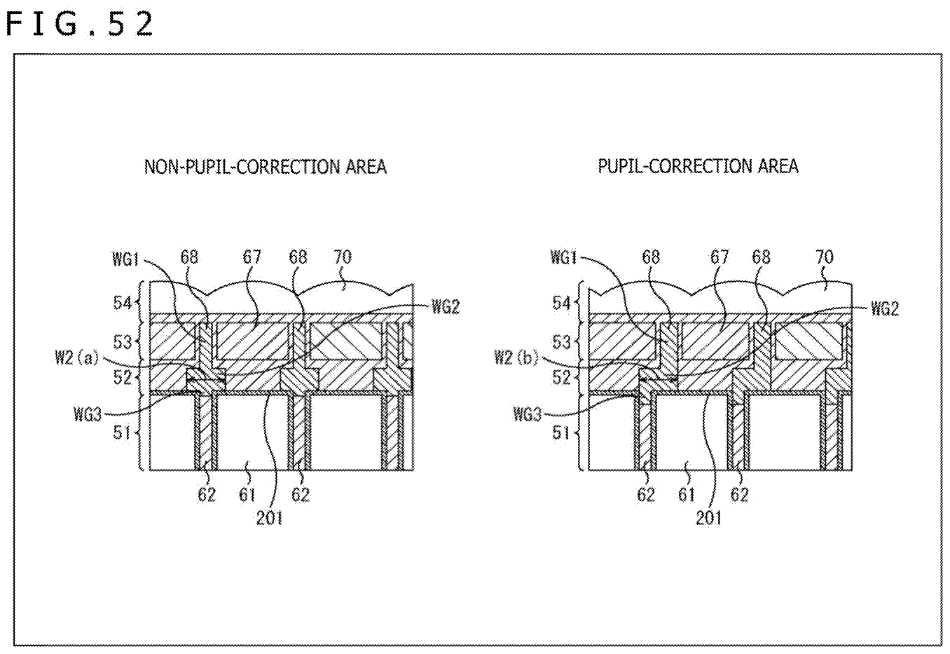

In such a case, examples depicted in FIGS. 51 and 52 are adoptable as an example of the shape of the low refractive index wall 68, for example. Note that parts in FIGS. 51 and 52 identical to the corresponding parts in FIG. 43 are given identical reference signs, and the same explanation of these parts will not be repeated where appropriate. In addition, reference signs of some parts are not given in FIGS. 51 and 52 for easy recognition of the figures.

Depicted in a left part of FIG. 51 is a cross-sectional diagram of an area where pupil correction is not performed in the pixel array unit 21.

In this case, no pupil correction is carried out, i.e., a correction amount of pupil correction is set to 0. Accordingly, a horizontal arrangement position in the figure and a horizontal width in the figure of each of the waveguide portions WG1 to WG3 constituting the low refractive index wall 68 are equalized.

Particularly, the horizontal position and width of the low refractive index wall 68 in the figure here are equalized with the horizontal position and width of the trench 62 in the figure.

The horizontal width of the low refractive index wall 68 (waveguide portion WG2) at the position where no pupil correction is performed in the figure will hereinafter also be referred to as a horizontal width W2(a). The horizontal width W2(a) here corresponds to the horizontal width W2 of the waveguide portion WG2 in the direction perpendicular to the optical axis direction as described with reference to FIG. 36.

Meanwhile, depicted in a right part of the figure is a cross-sectional diagram of an area where pupil correction is performed in the pixel array unit 21.

In this case, the waveguide portion WG1 constituting the low refractive index wall 68 is connected to the right end of the waveguide portion WG2, while the waveguide portion WG3 is connected to the left end of the waveguide portion WG2. Specifically, the waveguide portion WG3 is provided immediately above the trench 62, while the waveguide portion WG1 is disposed at a position shifted in the horizontal direction in the figure with respect to the waveguide portion WG3 (trench 62) by a distance corresponding to a correction amount of pupil correction. In addition, the waveguide portion WG2 is so formed as to connect the waveguide portion WG1 and the waveguide portion WG3 thus disposed.

The horizontal width of the waveguide portion WG2 at the position where pupil correction is performed in the figure will hereinafter also be referred to as a horizontal width W2 (b). The horizontal width W2 (b) here corresponds to the horizontal width W2 of the waveguide portion WG2 in the direction perpendicular to the optical axis direction as described with reference to FIG. 36.

According to this example, the width W2(a) of the waveguide portion WG2 at the position where no pupil correction is performed is made smaller than the width W2 (b) of the waveguide portion WG2 at the position where pupil correction is performed. In other words, the width W2(a) is different from the width W2 (b), i.e., W2 (a)<W2 (b).

In such a manner, an opening area of each pixel can be widened at the position where no pupil correction is performed, by reducing (decreasing) the horizontal width of the low refractive index wall 68 from the oxide film 201 to the color filter 67, i.e., the horizontal width of the waveguide portion WG2. Accordingly, sensor characteristics are allowed to improve.

Depicted in a left part of FIG. 52 is a cross-sectional diagram of an area where no pupil correction is performed in the pixel array unit 21.

In this case, no pupil correction is carried out, i.e., a correction amount of pupil correction is set to 0. Accordingly, a horizontal arrangement position of each of the waveguide portions WG1 to WG3 constituting the low refractive index wall 68 in the figure is aligned with a horizontal arrangement position of the trench 62 in the figure.

Moreover, the horizontal width of each of the waveguide portion WG1 and the waveguide portion WG3 in the figure is equalized with the horizontal positional width of the trench 62, but the horizontal width W2(a) of the waveguide portion WG2 in the figure is larger (longer) than the horizontal width of each of the waveguide portion WG1 and the waveguide portion WG3.

Accordingly, the low refractive index wall 68 is shaped such that the waveguide portion WG1 and the waveguide portion WG3 are connected to central portions of the upper surface and the lower surface of the waveguide portion WG2, respectively.

Meanwhile, depicted in a right part of the figure is a cross-sectional diagram of an area where pupil correction is performed in the pixel array unit 21.

In this example, the low refractive index wall 68 in the area where pupil correction is performed has the same shape as the shape of the low refractive index wall 68 in the area where pupil correction is performed that is depicted in FIG. 51. The waveguide portion WG2 in this case has the horizontal width W2(b) in the figure.

According to the example depicted in FIG. 52, the width W2(a) of the waveguide portion WG2 at the position where no pupil correction is performed and the width W2 (b) of the waveguide portion WG2 at the position where pupil correction is performed are equalized with each other (W2 (a)=W2 (b)). In other words, the horizontal width of the waveguide portion WG2 is constantly fixed for any correction amount of pupil correction.

Accordingly, the connection position between the waveguide portion WG1 and the waveguide portion WG2 is slightly moved (shifted) from the center to the right end of the upper surface of the waveguide portion WG2 according to a correction amount of pupil correction. Similarly, the connection position between the waveguide portion WG3 and the waveguide portion WG2 is slightly moved from the center to the left end of the lower surface of the waveguide portion WG2 according to the correction amount of pupil correction.

In addition, more specifically, the arrangement position of the waveguide portion WG3 is kept fixed. Accordingly, the arrangement positions of the waveguide portion WG1 and the waveguide portion WG2 are shifted according to the correction amount of pupil correction.

As described above, a difference in the volume of the embedded portion of the low refractive index wall 68 which is produced between the area where pupil correction is performed and the area where no pupil correction is performed can be reduced by fixing the horizontal width of the waveguide portion WG2 regardless of whether or not pupil correction is performed (a value of a correction amount). In such a manner, variations in a film thickness during formation (application) of the low refractive index wall 68 are allowed to decrease, and the portion of the low refractive index wall 68 and the portion of the oxide film layer 52 can be easily flattened.

### Example of Application to Electronic Apparatus

Note that the present technology is not limited to application to a solid-state imaging device. Specifically, the present technology is applicable to electronic apparatuses in general each including a solid-state imaging device as an image pickup unit (photoelectric conversion unit), such as an imaging device including a digital still camera and a video camera, a portable terminal device having an imaging function, and a copying machine including a solid-state imaging device as an image reading unit. The solid-state imaging device may have a one-chip form, or a module-shaped form having an imaging function as a package collectively including an imaging unit and a signal processing unit or an optical system.

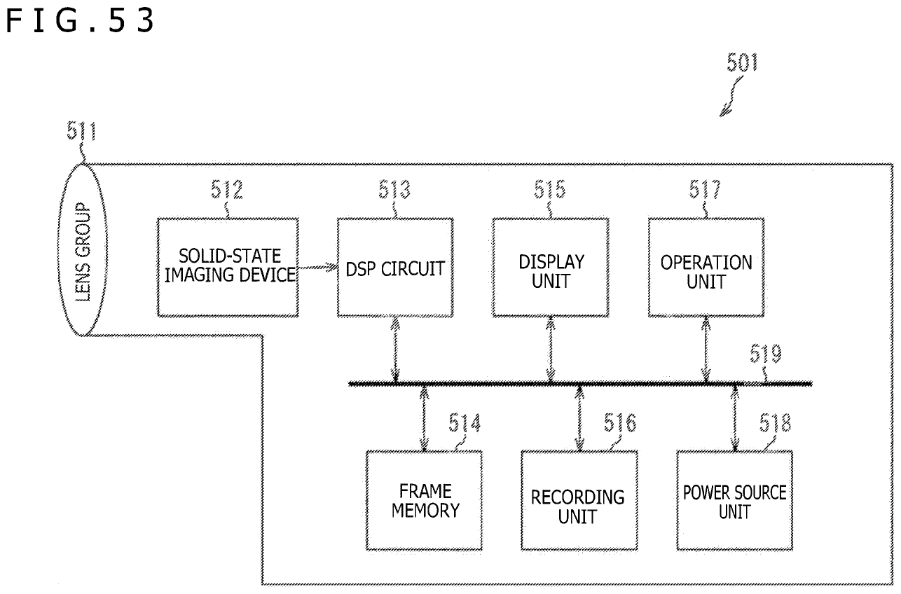

FIG. 53 is a block diagram depicting a configuration example of an imaging device as an electronic apparatus to which the present technology is applied.

An imaging device 501 in FIG. 53 includes an optical unit 511 including a lens group and the like, a solid-state imaging device (imaging device) 512 adopting the configuration of the CMOS image sensor 11 in FIG. 1, and a DSP (Digital Signal Processor) circuit 513 which is a camera signal processing circuit.

The imaging device 501 further includes a frame memory 514, a display unit 515, a recording unit 516, an operation unit 517, and a power source unit 518. The DSP circuit 513, the frame memory 514, the display unit 515, the recording unit 516, the operation unit 517, and the power source unit 518 are connected to one another via a bus line 519.

The optical unit 511 captures incident light (image light) coming from a subject, and forms an image of the incident light on an imaging surface of the solid-state imaging device 512. The solid-state imaging device 512 converts light quantities of the incident light formed on the imaging surface by the optical unit 511 into electric signals for each pixel, and outputs the electric signals as pixel signals.

For example, the display unit 515 includes a thin display such as an LCD (Liquid Crystal Display) and an organic EL (Electro Luminescence) display, and displays moving images or still images captured by the solid-state imaging device 512. The recording unit 516 records the moving images or the still images captured by the solid-state imaging device 512 in a recording medium such as a hard disk and a semiconductor memory.

The operation unit 517 issues operation commands associated with various functions of the imaging device 501 under operation by a user. The power source unit 518 appropriately supplies various types of power sources corresponding to operation power sources for the DSP circuit 513, the frame memory 514, the display unit 515, the recording unit 516, and the operation unit 517 to these supply targets.

### Use Example of Image Sensor

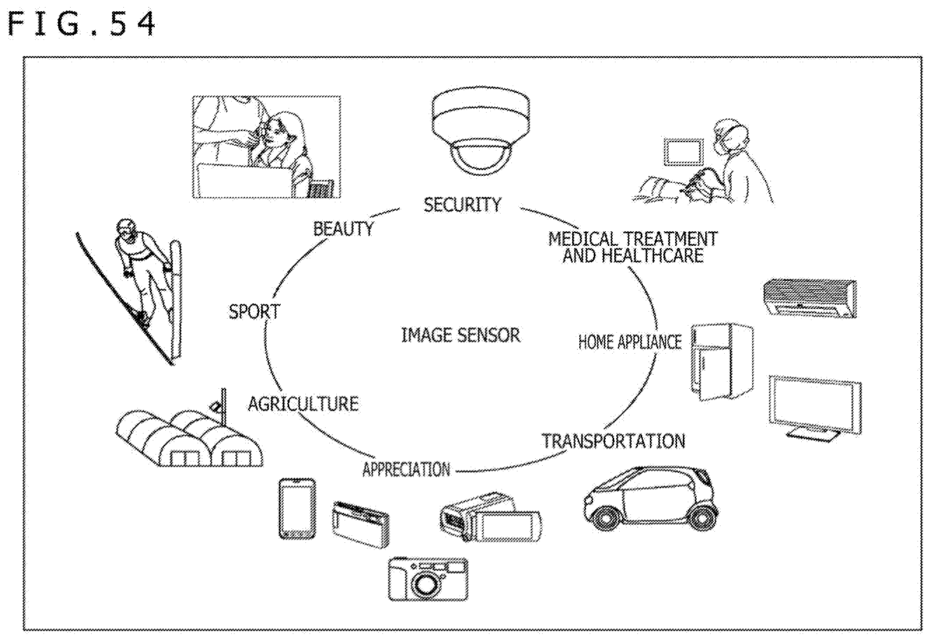

FIG. 54 is a diagram depicting use examples of the CMOS image sensor 11 described above.

For example, the CMOS image sensor 11 described above is available in various cases associated with sensing of such light as visible light, infrared light, ultraviolet light, and X-rays as will be described below.
A device for capturing images provided for appreciation, such as a digital camera and a portable device equipped with a camera function
A device provided for transportation, such as an in-vehicle sensor for capturing images before and behind, surroundings, and an interior of a car, a monitoring camera for monitoring running vehicles and roads, and a distance measuring sensor for measuring a distance between vehicles and the like, each for the purposes of safety driving such as an automatic stop, recognition of a state of a driver, and others
A device provided for home appliances, such as a television set, a refrigerator, and an air conditioner, for capturing an image of a gesture of a user and performing a device operation according to the gesture
A device provided for medical treatment and healthcare, such as an endoscope and a device performing angiogram by received infrared light
A device provided for security, such as a monitoring camera for crime prevention and a camera for person recognition
A device provided for beauty, such as a skin measuring device for capturing an image of skin and a microscope for capturing an image of scalp
A device provided for sports, such as an action camera for sports and a wearable camera
A device provided for agriculture, such as a camera for monitoring states of fields and crops

### Example of Application to Mobile Body

As described above, the technology according to the present disclosure (present technology) is applicable to various products. For example, the technology according to the present disclosure may be implemented as a device mounted on any type of mobile bodies such as a car, an electric car, a hybrid electric car, a motorcycle, a bicycle, a personal mobility, an airplane, a drone, a vessel, and a robot.

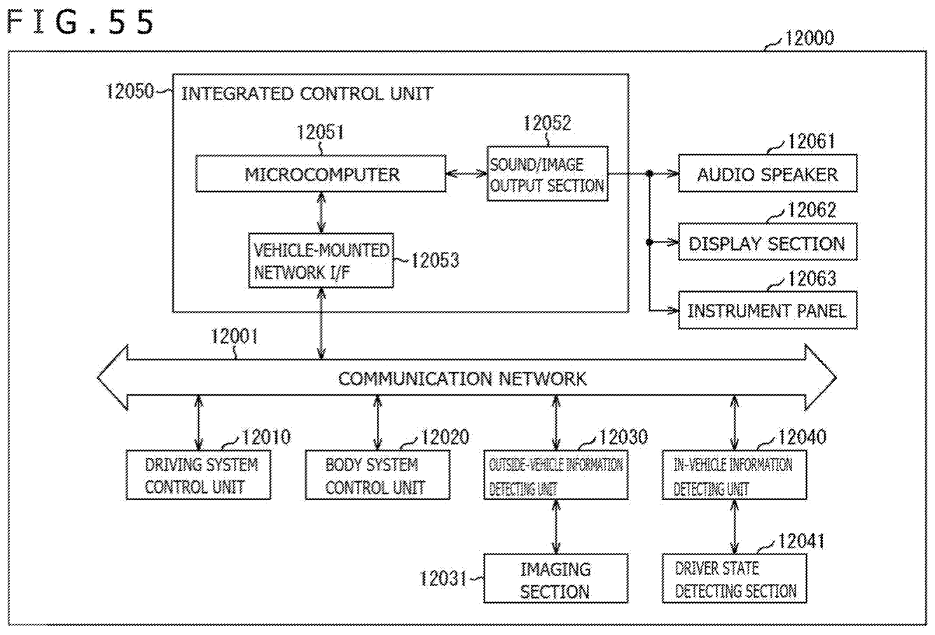

FIG. 55 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 55, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 55, an audio speaker 12061, a display section 12062, and an instrument panel 12063 are illustrated as the output device. The display section 12062 may, for example, include at least one of an on-board display and a head-up display.

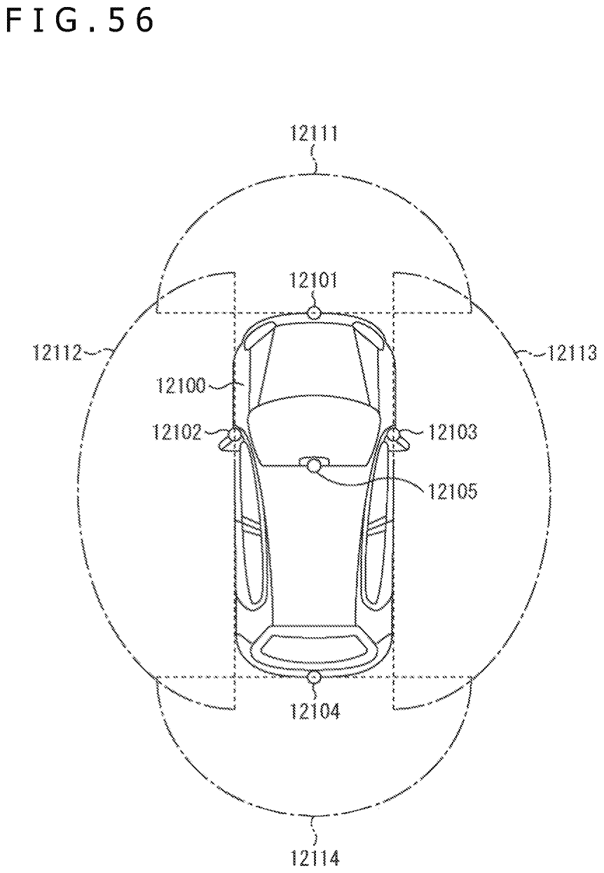

FIG. 56 is a diagram depicting an example of the installation position of the imaging section 12031.

In FIG. 56, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 56 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

The example of the vehicle control system to which the technology according to the present disclosure is applicable has been described above. The technology according to the present disclosure is applicable to the imaging section 12031 and the like in the configuration described above. Specifically, for example, the CMOS image sensor 11 depicted in FIG. 1 is applicable to the imaging section 12031. In such a manner, sensor characteristics are allowed to improve without processing damage being caused.

Note that the present technology is applicable to not only a solid-state imaging device which detects a distribution of incident amounts of visible light and captures an image of this distribution, but also a solid-state imaging device or the like which captures an image of a distribution of incident amounts of infrared rays, X-rays, particles, or others.

Moreover, the present technology is applicable to not only a solid-state imaging device, but also semiconductor devices in general each having a different type of semiconductor integrated circuit.

Embodiments according to the present technology are not limited to the embodiments described above, and may be modified in various manners without departing from the scope of the subject matters of the present technology.

For example, an embodiment combining all or a part of the plurality of embodiments described above may be adopted.

Further, advantageous effects to be produced are not limited to the advantageous effects presented in the present description only by way of example. Advantageous effects other than those described in the present description may be offered.

In addition, the present technology may also have the following configurations.

(1)

A solid-state imaging device including:
a pixel array unit that includes a plurality of pixels, in which
the pixel array unit includes
a color filter layer that includes color filters,
a photoelectric conversion layer that includes photoelectric conversion units,
an oxide film layer formed between the color filter layer and the photoelectric conversion layer, and
a low refractive index wall that includes a material having a lower refractive index than that of the color filters and that is formed between pixels from an end of the color filter layer on a side opposite to the oxide film layer to an intermediate position in the oxide film layer.
   (2)

The solid-state imaging device according to (1), in which the color filters of the pixels and the low refractive index wall adjacent to the pixels are shifted from the photoelectric conversion units by a distance corresponding to an incident angle of light entering the pixels.

(3)

The solid-state imaging device according to (2), further including:
a metal film formed in the oxide film layer, in which
the metal film is present without clearance between the low refractive index wall and a trench formed between the pixels adjacent to each other within the photoelectric conversion layer, as viewed in a direction perpendicular to a surface of the pixel array unit.
   (4)

The solid-state imaging device according to (3), in which the metal film is formed immediately below the low refractive index wall.

(5)

The solid-state imaging device according to (4), in which an oxide film is formed between the metal film in the oxide film layer and the photoelectric conversion layer.

(6)

The solid-state imaging device according to (4), in which a different metal film is formed immediately above the trench.

(7)

The solid-state imaging device according to (6), in which the metal film and the different metal film are connected to each other.

(8)

The solid-state imaging device according to (3), in which the metal film is provided adjacently to a side surface of the low refractive index wall.

(9)

The solid-state imaging device according to (3), in which a part of the metal film is embedded in the low refractive index wall.

(10)

The solid-state imaging device according to (2), in which a metal film is formed immediately below the low refractive index wall, and an oxide film is formed between the metal film in the oxide film layer and the photoelectric conversion layer.

(11)

The solid-state imaging device according to (10), in which the metal film has a larger width than the low refractive index wall.

(12)

The solid-state imaging device according to (10), in which the metal film has a smaller width than the low refractive index wall.

(13)

The solid-state imaging device according to any one of (10) through (12), further including:
a trench included in the photoelectric conversion layer and formed between the pixels adjacent to each other, in which
a different metal film is formed immediately above the trench.
   (14)

The solid-state imaging device according to (2), further including:
a trench included in the photoelectric conversion layer and formed between the pixels adjacent to each other, in which
a metal film is formed immediately above the trench.
   (15)

The solid-state imaging device according to any one of (3) through (14), in which the metal film includes Ti, W, Cu, Al, an oxide film of Ti, an oxide film of W, an oxide film of Cu, or an oxide film of Al.

(16)

The solid-state imaging device according to (1), in which the plurality of pixels include a distance measuring pixel.

(17)

The solid-state imaging device according to (16), in which
a metal film is formed immediately below the low refractive index wall in the oxide film layer, and
an oxide film is formed between the metal film in the oxide film layer and the photoelectric conversion layer.
   (18)

The solid-state imaging device according to (17), in which the metal film projects toward an inside of the distance measuring pixel, and functions as a light shielding film of the distance measuring pixel.

(19)

The solid-state imaging device according to (18), in which a length of a portion that is included in the metal film and that is projecting toward the inside of the distance measuring pixel varies according to a position of the distance measuring pixel in the pixel array unit.

(20)

The solid-state imaging device according to (16), in which the low refractive index wall projects toward an inside of the distance measuring pixel, and functions as a light shielding film of the distance measuring pixel.

(21)

The solid-state imaging device according to (20), in which a part or all of a portion included in the low refractive index wall and provided in the oxide film layer projects toward the inside of the distance measuring pixel.

(22)

The solid-state imaging device according to (20) or (21), in which a length of a portion that is included in the low refractive index wall and that is projecting toward the inside of the distance measuring pixel varies according to a position of the distance measuring pixel in the pixel array unit.

(23)

The solid-state imaging device according to any one of (20) through (22), in which
a metal film is formed in the oxide film layer and immediately below the low refractive index wall, and
an oxide film is formed between the metal film in the oxide film layer and the photoelectric conversion layer.
   (24)

The solid-state imaging device according to any one of (16) through (23), in which the distance measuring pixel includes a corresponding one of the color filters of a type different for each position of the distance measuring pixel in the pixel array unit.

(25)

The solid-state imaging device according to (24), in which
the distance measuring pixel within a predetermined region containing a center of the pixel array unit includes the color filter of red, green, or blue, and
the distance measuring pixel located outside the predetermined region of the pixel array unit includes the color filter of white.
   (26)

The solid-state imaging device according to any one of (16) through (23), in which
a left-shielded pixel that has a left light-shielded part and a right-shielded pixel that has a right light-shielded part, as both viewed in a direction perpendicular to a surface of the pixel array unit, are provided as the distance measuring pixels, and
the left-shielded pixel and the right-shielded pixel located outside a predetermined region containing a center of the pixel array unit have the color filters of types different for each.
   (27)

The solid-state imaging device according to (26), in which
the left-shielded pixel and the right-shielded pixel, both included in the distance measuring pixels located within a region on a left side of the predetermined region of the pixel array unit, have a corresponding one of the color filters of white and a corresponding one of the color filters of red, green, or blue, respectively, and
the right-shielded pixel and the left-shielded pixel, both included in the distance measuring pixels located within a region on a right side of the predetermined region of the pixel array unit, have the color filter of white and the color filter of red, green, or blue, respectively.
   (28)

The solid-state imaging device according to any one of (16) through (27), in which the low refractive index wall formed between the pixels has a width variable according to positions of the pixels in the pixel array unit.

(29)

The solid-state imaging device according to (28), in which a first width of the low refractive index wall formed between the distance measuring pixel and a left-right adjacent pixel adjacent to the distance measuring pixel on a left side or a right side is larger than a second width of the low refractive index wall formed between non-adjacent pixels not adjacent to the distance measuring pixel.

(30)

The solid-state imaging device according to (29), in which a third width of the low refractive index wall formed between an up-down adjacent pixel adjacent to the distance measuring pixel on an upper side or a lower side and the pixel adjacent to the up-down adjacent pixel on the left side or the right side is smaller than the first width but larger than the second width.

(31)

The solid-state imaging device according to any one of (28) through (30), in which, on an assumption that a corresponding one of the pixels that is adjacent to the distance measuring pixel on a left side or a right side is a left-right adjacent pixel, a fourth width of the low refractive index wall formed between the left-right adjacent pixels adjacent to each other on an upper side and a lower side is larger than a second width of the low refractive index wall formed between non-adjacent pixels not adjacent to the distance measuring pixel.

(32)

The solid-state imaging device according to (31), in which a fifth width of the low refractive index wall formed between the distance measuring pixel or the left-right adjacent pixel and the pixel that is not the distance measuring pixel and that is adjacent to the distance measuring pixel or the left-right adjacent pixel on the upper side or the lower side is smaller than the fourth width but larger than the second width.

(33)

The solid-state imaging device according to (1), further including:
a trench included in the photoelectric conversion layer and formed between the pixels adjacent to each other;
a different low refractive index wall formed in the oxide film layer and located immediately above the trench; and
a connection portion formed in the oxide film layer and connecting the low refractive index wall and the different low refractive index wall.
   (34)

The solid-state imaging device according to (33), in which each of the low refractive index wall, the different low refractive index wall, and the connection portion includes an identical material.

(35)

The solid-state imaging device according to (33) or (34), in which the color filters of the pixels and the low refractive index wall adjacent to the pixels are shifted from the photoelectric conversion units, the trench, and the different low refractive index wall by a distance corresponding to an incident angle of light entering the pixels.

(36)

The solid-state imaging device according to (35), in which the connection portion has a width variable according to the distance.

(37)

The solid-state imaging device according to any one of (33) through (36), in which one end of the connection portion is connected to a lower end of the low refractive index wall, and the other end of the connection portion is connected to an upper end of the different low refractive index wall.

(38)

The solid-state imaging device according to any one of (33) through (36), in which the low refractive index wall penetrates the connection portion, and a lower end of the low refractive index wall is located below the connection portion.

(39)

The solid-state imaging device according to any one of (33) through (36), in which
a lower end of the low refractive index wall is connected to a position that is included in an upper surface of the connection portion and that is located between a left end and a right end of the connection portion, and
an upper end of the different low refractive index wall is connected to a position that is included in a lower surface of the connection portion and that is located between the left end and the right end of the connection portion.
   (40)

The solid-state imaging device according to any one of (33) through (39), in which a metal film is formed on at least either an upper surface or a lower surface of the connection portion.

(41)

The solid-state imaging device according to any one of (33) through (40), in which an on-chip lens is provided for each of the pixels.

(42)

The solid-state imaging device according to any one of (33) through (40), in which one on-chip lens is provided for a plurality of the pixels adjacent to each other.

(43)

The solid-state imaging device according to any one of (33) through (39), in which the connection portion is formed along an oxide film provided immediately above the photoelectric conversion layer.

(44)

The solid-state imaging device according to any one of (33) through (39), further including:
a protection film formed between the low refractive index wall and the color filters.
   (45)

The solid-state imaging device according to (44), in which the low refractive index wall, the different low refractive index wall, and a part or all of the connection portion are covered with the protection film.

(46)

The solid-state imaging device according to (44) or (45), in which the protection film is an oxide film.

(47)

The solid-state imaging device according to (44) or (45), in which the protection film includes SiN or AlO.

(48)

The solid-state imaging device according to any one of (44) through (47), in which the protection film has a refractive index substantially equal to a refractive index of the color filters, but higher than a refractive index of the low refractive index wall.

(49)

The solid-state imaging device according to any one of (44) through (47), in which the protection film has a refractive index lower than a refractive index of the color filters, but substantially equal to a refractive index of the low refractive index wall.

(50)

The solid-state imaging device according to (1), further including:
a trench included in the photoelectric conversion layer and formed between the pixels adjacent to each other; and
a connection portion that is formed along an oxide film that is included in the oxide film layer and that is provided immediately above the photoelectric conversion layer, and connects the trench and the low refractive index wall.
   (51)

The solid-state imaging device according to any one of (1) through (50), in which the low refractive index wall includes SiN, SiO₂, SiON, a styrene-based resin material, an acryl-based resin material, a styrene-acryl copolymerization-based resin material, a siloxane-based resin material, the atmosphere, or a vacuum.

(52)

An electronic apparatus including:
a solid-state imaging element that includes a pixel array unit, the pixel array unit including
   a plurality of pixels,
   a color filter layer that includes color filters,
   a photoelectric conversion layer that includes photoelectric conversion units,
   an oxide film layer formed between the color filter layer and the photoelectric conversion layer, and
   a low refractive index wall that includes a material having a lower refractive index than that of the color filters and that is formed between pixels from an end of the color filter layer on a side opposite to the oxide film layer to an intermediate position in the oxide film layer.

### REFERENCE SIGNS LIST

11: CMOS image sensor
21: Pixel array unit
51: Photoelectric conversion layer
52: Oxide film layer
53: Color filter layer
54: Micro-lens layer
61: Photoelectric conversion unit
62: Trench
64: Oxide film
65: Oxide film
66: Oxide film
67: Color filter
68: Low refractive index wall
69: Metal film
101: Metal film

1. A solid-state imaging device comprising:
a pixel array unit that includes a plurality of pixels, wherein
the pixel array unit includes
a color filter layer that includes color filters,
a photoelectric conversion layer that includes photoelectric conversion units,
an oxide film layer formed between the color filter layer and the photoelectric conversion layer, and
a low refractive index wall that includes a material having a lower refractive index than that of the color filters and that is formed between pixels from an end of the color filter layer on a side opposite to the oxide film layer to an intermediate position in the oxide film layer.

2. The solid-state imaging device according to claim 1, wherein the color filters of the pixels and the low refractive index wall adjacent to the pixels are shifted from the photoelectric conversion units by a distance corresponding to an incident angle of light entering the pixels.

3. The solid-state imaging device according to claim 2, further comprising:
a metal film formed in the oxide film layer, wherein
the metal film is present without clearance between the low refractive index wall and a trench formed between the pixels adjacent to each other within the photoelectric conversion layer, as viewed in a direction perpendicular to a surface of the pixel array unit.

4. The solid-state imaging device according to claim 3, wherein the metal film is formed immediately below the low refractive index wall.

5. The solid-state imaging device according to claim 4, wherein an oxide film is formed between the metal film in the oxide film layer and the photoelectric conversion layer.

6. The solid-state imaging device according to claim 4, wherein a different metal film is formed immediately above the trench.

7. The solid-state imaging device according to claim 6, wherein the metal film and the different metal film are connected to each other.

8. The solid-state imaging device according to claim 3, wherein the metal film is provided adjacently to a side surface of the low refractive index wall.

9. The solid-state imaging device according to claim 3, wherein a part of the metal film is embedded in the low refractive index wall.

10. The solid-state imaging device according to claim 2, wherein
a metal film is formed immediately below the low refractive index wall, and
an oxide film is formed between the metal film in the oxide film layer and the photoelectric conversion layer.

11. The solid-state imaging device according to claim 10, wherein the metal film has a larger width than the low refractive index wall.

12. The solid-state imaging device according to claim 10, wherein the metal film has a smaller width than the low refractive index wall.

13. The solid-state imaging device according to claim 10, further comprising:
a trench included in the photoelectric conversion layer and formed between the pixels adjacent to each other, wherein
a different metal film is formed immediately above the trench.

14. The solid-state imaging device according to claim 2, further comprising:
a trench included in the photoelectric conversion layer and formed between the pixels adjacent to each other, wherein
a metal film is formed immediately above the trench.

15. The solid-state imaging device according to claim 3, wherein the metal film includes Ti, W, Cu, Al, an oxide film of Ti, an oxide film of W, an oxide film of Cu, or an oxide film of Al.

16. The solid-state imaging device according to claim 1, wherein the plurality of pixels include a distance measuring pixel.

17. The solid-state imaging device according to claim 16, wherein
a metal film is formed immediately below the low refractive index wall in the oxide film layer, and
an oxide film is formed between the metal film in the oxide film layer and the photoelectric conversion layer.

18. The solid-state imaging device according to claim 17, wherein the metal film projects toward an inside of the distance measuring pixel, and functions as a light shielding film of the distance measuring pixel.

19. The solid-state imaging device according to claim 18, wherein a length of a portion that is included in the metal film and that is projecting toward the inside of the distance measuring pixel varies according to a position of the distance measuring pixel in the pixel array unit.

20. The solid-state imaging device according to claim 16, wherein the low refractive index wall projects toward an inside of the distance measuring pixel, and functions as a light shielding film of the distance measuring pixel.

21. The solid-state imaging device according to claim 20, wherein a part or all of a portion included in the low refractive index wall and provided in the oxide film layer projects toward the inside of the distance measuring pixel.

22. The solid-state imaging device according to claim 20, wherein a length of a portion that is included in the low refractive index wall and that is projecting toward the inside of the distance measuring pixel varies according to a position of the distance measuring pixel in the pixel array unit.

23. The solid-state imaging device according to claim 20, wherein
a metal film is formed in the oxide film layer and immediately below the low refractive index wall, and
an oxide film is formed between the metal film in the oxide film layer and the photoelectric conversion layer.

24. The solid-state imaging device according to claim 16, wherein the distance measuring pixel includes a corresponding one of the color filters of a type different for each position of the distance measuring pixel in the pixel array unit.

25. The solid-state imaging device according to claim 24, wherein
the distance measuring pixel within a predetermined region containing a center of the pixel array unit includes the color filter of red, green, or blue, and
the distance measuring pixel located outside the predetermined region of the pixel array unit includes the color filter of white.

26. The solid-state imaging device according to claim 16, wherein
a left-shielded pixel that has a left light-shielded part and a right-shielded pixel that has a right light-shielded part, as both viewed in a direction perpendicular to a surface of the pixel array unit, are provided as the distance measuring pixels, and
the left-shielded pixel and the right-shielded pixel located outside a predetermined region containing a center of the pixel array unit have the color filters of types different for each.

27. The solid-state imaging device according to claim 26, wherein
the left-shielded pixel and the right-shielded pixel, both included in the distance measuring pixels located within a region on a left side of the predetermined region of the pixel array unit, have a corresponding one of the color filters of white and a corresponding one of the color filters of red, green, or blue, respectively, and
the right-shielded pixel and the left-shielded pixel, both included in the distance measuring pixels located within a region on a right side of the predetermined region of the pixel array unit, have the color filter of white and the color filter of red, green, or blue, respectively.

28. The solid-state imaging device according to claim 16, wherein the low refractive index wall formed between the pixels has a width variable according to positions of the pixels in the pixel array unit.

29. The solid-state imaging device according to claim 28, wherein a first width of the low refractive index wall formed between the distance measuring pixel and a left-right adjacent pixel adjacent to the distance measuring pixel on a left side or a right side is larger than a second width of the low refractive index wall formed between non-adjacent pixels not adjacent to the distance measuring pixel.

30. The solid-state imaging device according to claim 29, wherein a third width of the low refractive index wall formed between an up-down adjacent pixel adjacent to the distance measuring pixel on an upper side or a lower side and the pixel adjacent to the up-down adjacent pixel on the left side or the right side is smaller than the first width but larger than the second width.

31. The solid-state imaging device according to claim 28, wherein, on an assumption that a corresponding one of the pixels that is adjacent to the distance measuring pixel on a left side or a right side is a left-right adjacent pixel, a fourth width of the low refractive index wall formed between the left-right adjacent pixels adjacent to each other on an upper side and a lower side is larger than a second width of the low refractive index wall formed between non-adjacent pixels not adjacent to the distance measuring pixel.

32. The solid-state imaging device according to claim 31, wherein a fifth width of the low refractive index wall formed between the distance measuring pixel or the left-right adjacent pixel and the pixel that is not the distance measuring pixel and that is adjacent to the distance measuring pixel or the left-right adjacent pixel on the upper side or the lower side is smaller than the fourth width but larger than the second width.

33. The solid-state imaging device according to claim 1, further comprising:
a trench included in the photoelectric conversion layer and formed between the pixels adjacent to each other;
a different low refractive index wall formed in the oxide film layer and located immediately above the trench; and
a connection portion formed in the oxide film layer and connecting the low refractive index wall and the different low refractive index wall.

34. The solid-state imaging device according to claim 33, wherein each of the low refractive index wall, the different low refractive index wall, and the connection portion includes an identical material.

35. The solid-state imaging device according to claim 33, wherein the color filters of the pixels and the low refractive index wall adjacent to the pixels are shifted from the photoelectric conversion units, the trench, and the different low refractive index wall by a distance corresponding to an incident angle of light entering the pixels.

36. The solid-state imaging device according to claim 35, wherein the connection portion has a width variable according to the distance.

37. The solid-state imaging device according to claim 33, wherein one end of the connection portion is connected to a lower end of the low refractive index wall, and the other end of the connection portion is connected to an upper end of the different low refractive index wall.

38. The solid-state imaging device according to claim 33, wherein the low refractive index wall penetrates the connection portion, and a lower end of the low refractive index wall is located below the connection portion.

39. The solid-state imaging device according to claim 33, wherein
a lower end of the low refractive index wall is connected to a position that is included in an upper surface of the connection portion and that is located between a left end and a right end of the connection portion, and
an upper end of the different low refractive index wall is connected to a position that is included in a lower surface of the connection portion and that is located between the left end and the right end of the connection portion.

40. The solid-state imaging device according to claim 33, wherein a metal film is formed on at least either an upper surface or a lower surface of the connection portion.

41. The solid-state imaging device according to claim 33, wherein an on-chip lens is provided for each of the pixels.

42. The solid-state imaging device according to claim 33, wherein one on-chip lens is provided for a plurality of the pixels adjacent to each other.

43. The solid-state imaging device according to claim 33, wherein the connection portion is formed along an oxide film provided immediately above the photoelectric conversion layer.

44. The solid-state imaging device according to claim 33, further comprising:
a protection film formed between the low refractive index wall and the color filters.

45. The solid-state imaging device according to claim 44, wherein the low refractive index wall, the different low refractive index wall, and a part or all of the connection portion are covered with the protection film.

46. The solid-state imaging device according to claim 44, wherein the protection film is an oxide film.

47. The solid-state imaging device according to claim 44, wherein the protection film includes SiN or AlO.

48. The solid-state imaging device according to claim 44, wherein the protection film has a refractive index substantially equal to a refractive index of the color filters, but higher than a refractive index of the low refractive index wall.

49. The solid-state imaging device according to claim 44, wherein the protection film has a refractive index lower than a refractive index of the color filters, but substantially equal to a refractive index of the low refractive index wall.

50. The solid-state imaging device according to claim 1, further comprising:
a trench included in the photoelectric conversion layer and formed between the pixels adjacent to each other; and
a connection portion that is formed along an oxide film that is included in the oxide film layer and that is provided immediately above the photoelectric conversion layer, and connects the trench and the low refractive index wall.

51. The solid-state imaging device according to claim 1, wherein the low refractive index wall includes SiN, SiO₂, SiON, a styrene-based resin material, an acryl-based resin material, a styrene-acryl copolymerization-based resin material, a siloxane-based resin material, the atmosphere, or a vacuum.

52. An electronic apparatus comprising:
a solid-state imaging element that includes a pixel array unit, the pixel array unit including a plurality of pixels,
a color filter layer that includes color filters,
a photoelectric conversion layer that includes photoelectric conversion units,
an oxide film layer formed between the color filter layer and the photoelectric conversion layer, and
a low refractive index wall that includes a material having a lower refractive index than that of the color filters and that is formed between pixels from an end of the color filter layer on a side opposite to the oxide film layer to an intermediate position in the oxide film layer.
